(19) United States
(12) Patent Application Publication
(10) Pub. No.: US 2021/0018836 A1
(43) Pub. Date: Jan. 21, 2021

(54) PHOTORESIST COMPOSITION FOR THICK FILM AND METHOD OF FORMING THICK FILM PHOTORESIST PATTERN

(71) Applicant: TOKYO OHKA KOGYO CO., LTD., Kawasaki-shi (JP)

(72) Inventors: Dae-cheol Yu, Kawasaki-shi (JP); Eun-Sol Jo, Kawasaki-shi (JP); Yoshiaki Ohno, Kawasaki-shi (JP)

(21) Appl. No.: 16/928,666

(22) Filed: Jul. 14, 2020

(30) Foreign Application Priority Data
Jul. 19, 2019 (KR) 10-2019-0087833

(51) Int. Cl. G03F 7/004; G03F 7/038; G03F 7/039

(52) U.S. Cl. CPC G03F 7/0045; G03F 7/162; G03F 7/039; G03F 7/038

(57) ABSTRACT

A thick film photoresist composition for forming a thick film photoresist layer on a support, the photoresist composition including: a resin which exhibits changed solubility in a developing solution by the action of acid, an acid generator which generates acid by exposure, an additive, and a solvent, the additive including a compound having at least one polar group selected from the group consisting of a hydroxy group, an amino group, a mercapto group, a carboxy group and a sulfonic acid group, and the amount of the additive, relative to 100 parts by weight of the solvent being 5 to 30 parts by weight.

### TECHNICAL FIELD

The present invention relates to a photoresist composition for thick film and a method of forming a thick film photoresist pattern.

Priority is claimed on Korean Patent Application No. 10-2019-0087833, filed Jul. 19, 2019, the content of which is incorporated herein by reference.

### DESCRIPTION OF RELATED ART

A technique of forming a fine pattern on a support and processing the lower layer of the pattern by using this as a mask (pattern forming technique) is widely adopted in the manufacture of semiconductor elements and liquid crystal display elements. These types of fine patterns are usually formed from an organic material, and are formed using a lithography method or a nanoimprint method or the like. For example, in the lithography method, a photoresist film is formed on a support using a photoresist material containing a base material component such as a resin. Then, selective exposure is performed on the photoresist film by using an exposure device such as an ArF exposure device, an electron beam drawing device, an EUV exposure device, or the like. Then, a development treatment is conducted, so as to perform a step of forming a photoresist pattern having a predetermined shape on the photoresist film. Then, a semiconductor element or the like is manufactured through a step of processing the support by etching using the photoresist pattern as a mask.

As a photoresist composition, a composition including a resin component that exhibits a changed solubility in a developing solution under the action of acid and an acid-generator component that generates acid upon exposure is generally used. For example, in the case where an alkali developing solution is used as a developing solution (alkali developing process), a resin component which exhibits increased solubility in an alkali developing solution under action of acid is used.

Various types of additives are being sought in order to further improve the performance of photoresists. For example, referring to Patent Literature 1, it is disclosed that a photoresist composition may include additives such as a surfactant, a dissolution inhibitor, a plasticizer, a stabilizer, and/or a colorant.

On the other hand, a photoresist for a thick film refers to a photoresist capable of forming a film having a film thickness of about 5 μm or more on a support. Generally, in the case of a photoresist, the smaller the content of the residual solvent in the photoresist film, the more the adhesion between the photoresist film and the support tends to improve. However, in the case of a thick film photoresist, the amount of residual solvent in the photoresist film becomes high due to the large film thickness, which causes a problem of poor adhesion between the photoresist film and the support.

Further, in the lithography method, after the photoresist pattern is measured, an etching step is proceeded, but if the adhesion between the photoresist film and the support is insufficient, the photoresist pattern may be lifted off the support when the photoresist pattern measurement step or the etching step is performed.

In order to solve such a problem, there have been attempts to change the type of resin, solvent or surfactant of the photoresist composition. However, such a conventional thick film photoresist composition has a problem that it is not possible to sufficiently satisfy the requirement to solve the problem that the photoresist pattern falls off from the support.

### DOCUMENTS OF RELATED ART

### Patent Literature

[Patent Literature 1] Japanese Patent No. 5906076

### SUMMARY OF THE INVENTION

The present invention takes the above circumstances into consideration, with an object of providing a thick film photoresist composition capable of forming a thick film photoresist pattern in which the adhesion of the thick film photoresist layer to the support is improved, the occurrence of cracks is suppressed, and the falling of the pattern from the support is suppressed; and a method of forming a thick film photoresist pattern.

As a result of intensive studies, the present inventors have found that, when the thick film photoresist composition contains a specific additive, the amount of residual solvent in the thick film photoresist layer may be reduced to solve the above problems. The inventors have completed the present invention based on this finding.

A first aspect of the present invention is a thick film photoresist composition for forming a thick film photoresist layer on a support, the photoresist composition including: a resin (A) which exhibits changed solubility in a developing solution by the action of acid, an acid generator (B) which generates acid by exposure, an additive (E), and a solvent (S), the additive (E) including a compound having at least one polar group selected from the group consisting of a hydroxy group, an amino group, a mercapto group, a carboxy group and a sulfonic acid group, and the amount of the additive (E), relative to 100 parts by weight of the solvent (S) being 5 to 30 parts by weight.

A second aspect of the present invention is a method of forming a thick film photoresist pattern, including: using a thick film photoresist composition of the first aspect to form a thick film photoresist layer on a substrate; exposing the thick film photoresist layer; and developing the thick film photoresist layer to form a thick film photoresist pattern.

According to the present invention, there are provided a thick film photoresist composition capable of forming a thick film photoresist pattern in which the adhesion of the thick film photoresist layer to the support is improved, the occurrence of cracks is suppressed, and the falling of the pattern from the support is suppressed; and a method of forming a thick film photoresist pattern.

### BRIEF DESCRIPTION OF THE DRAWINGS

FIG. 1 is a drawing showing the results of a thick film photoresist pattern formed using the thick film photoresist composition of Comparative Example 1 after a tape test.

FIG. 2 is a drawing showing the results of a thick film photoresist pattern formed using the thick film photoresist composition of Comparative Example 2 after a tape test.

FIG. 3 is a drawing showing the results of a thick film photoresist pattern formed using the thick film photoresist composition of Example 1 after a tape test.

FIG. 4 is a drawing showing the results of a thick film photoresist pattern formed using the thick film photoresist composition of Example 2 after a tape test.

FIG. 5 is a drawing showing the results of a thick film photoresist pattern formed using the thick film photoresist composition of Example 3 after a tape test.

FIG. 6 is a drawing showing the results of a thick film photoresist pattern formed using the thick film photoresist composition of Example 4 after a tape test.

FIG. 7 is a drawing showing the results of a thick film photoresist pattern formed using the thick film photoresist composition of Example 5 after a tape test.

### DETAILED DESCRIPTION OF THE INVENTION

In the present description and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic, divalent saturated hydrocarbon, unless otherwise specified.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

A “fluorinated alkyl group” or a “fluorinated alkylene group” is a group in which part or all of the hydrogen atoms of an alkyl group or an alkylene group have been substituted with a fluorine atom.

The term “structural unit” refers to a monomer unit that contributes to the formation of a polymeric compound (resin, polymer, copolymer).

A “structural unit derived from an acrylate ester” refers to a structural unit that is formed by the cleavage of the ethylenic double bond of an acrylate ester.

An “acrylate ester” refers to a compound in which the terminal hydrogen atom of the carboxy group of acrylic acid (CH₂═CH—COOH) has been substituted with an organic group.

The acrylate ester may have the hydrogen atom bonded to the carbon atom on the α-position substituted with a substituent. The substituent (R^{α0}) that substitutes the hydrogen atom bonded to the carbon atom on the α-position is an atom other than hydrogen or a group, and examples thereof include an alkyl group of 1 to 5 carbon atoms and a halogenated alkyl group of 1 to 5 carbon atoms. Further, an acrylate ester having the hydrogen atom bonded to the carbon atom on the α-position substituted with a substituent (R^{α0}) in which the substituent has been substituted with a substituent containing an ester bond (e.g., an itaconic acid diester), or an acrylic acid having the hydrogen atom bonded to the carbon atom on the α-position substituted with a substituent (R^{α0}) in which the substituent has been substituted with a hydroxyalkyl group or a group in which the hydroxy group within a hydroxyalkyl group has been modified (e.g., α-hydroxyalkyl acrylate ester) can be mentioned as an acrylate ester having the hydrogen atom bonded to the carbon atom on the α-position substituted with a substituent. A carbon atom on the α-position of an acrylate ester refers to the carbon atom bonded to the carbonyl group, unless specified otherwise.

Hereafter, an acrylate ester having the hydrogen atom bonded to the carbon atom on the α-position substituted with a substituent is sometimes referred to as “α-substituted acrylate ester”. Further, acrylate esters and α-substituted acrylate esters are collectively referred to as “(α-substituted) acrylate ester”.

A “structural unit derived from hydroxystyrene or a hydroxystyrene derivative” refers to a structural unit that is formed by the cleavage of the ethylenic double bond of hydroxystyrene or a hydroxystyrene derivative.

The term “hydroxystyrene derivative” includes compounds in which the hydrogen atom at the α-position of hydroxystyrene has been substituted with another substituent such as an alkyl group or a halogenated alkyl group; and derivatives thereof. Examples of the derivatives thereof include hydroxystyrene in which the hydrogen atom of the hydroxy group has been substituted with an organic group and may have the hydrogen atom on the α-position substituted with a substituent; and hydroxystyrene which has a substituent other than a hydroxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

As the substituent which substitutes the hydrogen atom on the α-position of hydroxystyrene, the same substituents as those described above for the substituent on the α-position of the aforementioned α-substituted acrylate ester can be mentioned.

A “structural unit derived from vinylbenzoic acid or a vinylbenzoic acid derivative” refers to a structural unit that is formed by the cleavage of the ethylenic double bond of vinylbenzoic acid or a vinylbenzoic acid derivative.

The term “vinylbenzoic acid derivative” includes compounds in which the hydrogen atom at the α-position of vinylbenzoic acid has been substituted with another substituent such as an alkyl group or a halogenated alkyl group; and derivatives thereof. Examples of the derivatives thereof include benzoic acid in which the hydrogen atom of the carboxy group has been substituted with an organic group and may have the hydrogen atom on the α-position substituted with a substituent; and benzoic acid which has a substituent other than a hydroxy group and a carboxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

The term “styrene derivative” includes compounds in which the hydrogen atom at the α-position of styrene has been substituted with another substituent such as an alkyl group or a halogenated alkyl group; and compounds in which a hydrogen atom on the phenyl group of styrene has been substituted with a substituent such as a lower alkyl group having 1 to 5 carbon atoms.

A “structural unit derived from styrene” or “structural unit derived from a styrene derivative” refers to a structural unit that is formed by the cleavage of the ethylenic double bond of styrene or a styrene derivative.

As the alkyl group as a substituent on the α-position, a linear or branched alkyl group is preferable, and specific examples include alkyl groups of 1 to 5 carbon atoms, such as a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group as the substituent on the α-position include groups in which part or all of the hydrogen atoms of the aforementioned “alkyl group as the substituent on the α-position” are substituted with halogen atoms. Examples of the halogen atom include a fluorine atom, a chlorine atom, a bromine atom and an iodine atom, and a fluorine atom is particularly desirable.

Specific examples of the hydroxyalkyl group as the substituent on the α-position include groups in which part or all of the hydrogen atoms of the aforementioned “alkyl group as the substituent on the α-position” are substituted with a hydroxy group. The number of hydroxy groups within the hydroxyalkyl group is preferably 1 to 5, and most preferably 1.

The expression “may have a substituent” means that a case where a hydrogen atom (—H) is substituted with a monovalent group, or a case where a methylene (—CH₂—) group is substituted with a divalent group.

The term “exposure” is used as a general concept that includes irradiation with any form of radiation.

<<Thick Film Photoresist Composition>>

A first aspect of the present invention is a thick film photoresist composition for forming a thick film photoresist layer on a support (hereafter, sometimes referred to simply as “photoresist composition”), the photoresist composition including: a resin (A) which exhibits changed solubility in a developing solution by the action of acid, an acid generator (B) which generates acid by exposure, an additive (E), and a solvent (S), the additive (E) including a compound having at least one polar group selected from the group consisting of a hydroxy group, an amino group, a mercapto group, a carboxy group and a sulfonic acid group, and the amount of the additive (E), relative to 100 parts by weight of the solvent (S) being 5 to 30 parts by weight.

When a photoresist film is formed using the photoresist composition according to the present embodiment, and the resist film is selectively exposed, acid is generated at exposed portions of the photoresist film, and the solubility of the component (A) in a developing solution is changed by the action of the acid. On the other hand, at unexposed portions of the photoresist film, the solubility of the component (A) in a developing solution is unchanged. As a result, difference is generated between the exposed portions of the photoresist film and the unexposed portions of the photoresist film in terms of solubility in a developing solution. Therefore, by subjecting the photoresist film to development, the exposed portions of the photoresist film are dissolved and removed to form a positive-tone photoresist pattern in the case of a positive photoresist, whereas the unexposed portions of the photoresist film are dissolved and removed to form a negative-tone photoresist pattern in the case of a negative photoresist.

In the present specification, a photoresist composition which forms a positive photoresist pattern by dissolving and removing the exposed portions of the photoresist film is called a positive photoresist composition, and a photoresist composition which forms a negative photoresist pattern by dissolving and removing the unexposed portions of the photoresist film is called a negative photoresist composition.

The photoresist composition of the present embodiment may be either a positive photoresist composition or a negative photoresist composition.

<Resin (A)>

In the present embodiment, the photoresist composition contains a resin (A) (hereafter, referred to as “component (A)”) which exhibits changed solubility in a developing solution. In the present embodiment, the component (A) may be dissolved in a solvent (S) described later, and is not particularly limited as long as it is a resin usable in a photolithography process. In particular, a resin which exhibits changed solubility in a developing solution under action of acid is preferable. When a resin which exhibits changed solubility in a developing solution under action of acid is blended in the photoresist composition together with an acid generator (B) described later, by selectively exposing a film formed from the photoresist composition, the exposed portion or the unexposed portion in the film may be selectively rendered soluble in an alkali. In this case, a pattern having a desired shape can be formed by bringing the exposed film into contact with an alkaline developing solution to remove the exposed portion or the unexposed portion.

In the present embodiment, the component (A) of the photoresist composition preferably contains at least one resin selected from the group consisting of a resin (A1), a resin (A2) and a resin (A3) described later.

[Resin (A1)]

In the present embodiment, the component (A) of the photoresist composition preferably contains a resin (A1) (hereafter, sometimes referred to as “component (A1)”) having a structural unit derived from hydroxystyrene. By using the component (A1), a pattern with high resolution may be formed. Further, since fine processing may be performed when forming a thick film, a pattern with a high aspect ratio may be formed, and resistance to dry etching and the like may be improved.

In particular, the component (A1) preferably used for KrF excimer laser, in view of the effects of the present invention, preferably includes a structural unit (a1) derived from hydroxystyrene and a structural unit (a2) having an acid dissociable, dissolution inhibiting group, and more preferably includes the structural unit (a1), the structural unit (a2) and a structural unit (a3) derived from styrene. The component (A1) is preferably a copolymer.

(Structural Unit (a1))

The structural unit (a1) is a structural unit derived from hydroxystyrene.

In the structural unit (a1), the “structural unit derived from hydroxystyrene” includes a structural unit formed by cleavage of the ethylenic double bond of hydroxystyrene and a hydroxystyrene derivative (monomer) as described above.

Here, as described above, the “hydroxystyrene derivative” maintains at least the benzene ring and the hydroxyl group bonded thereto, and includes, for example, a compound in which a hydrogen atom bonded to the α-position of hydroxystyrene is substituted with another substituent such as a halogen atom, a lower alkyl group having 1 to 5 carbon atoms, a halogenated alkyl group; a compound in which the benzene ring of hydroxystyrene having a hydroxy group bonded further has a lower alkyl group having 1 to 5 carbon atoms bonded to the benzene ring; and a compound in which 1 to 2 hydroxy groups are further bonded to the benzene ring having this hydroxyl group bonded (in this case, the total number of hydroxy groups is 2 to 3).

Examples of halogen atoms include a chlorine atom, a fluorine atom and a bromine atom, and a fluorine atom is preferable.

Here, the α-position of hydroxystyrene refers to the carbon atom having the benzene ring bonded thereto, unless specified otherwise.

Preferable examples of the structural unit (a1) include a structural unit (a11) represented by general formula (a1-1) shown below.

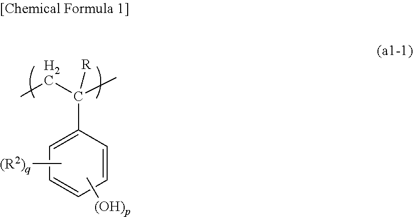

In the formula, R represents a hydrogen atom, an alkyl group, a halogen atom or a halogenated alkyl group; R² represents a lower alkyl group having 1 to 5 carbon atoms; p represents an integer of 1 to 3; and q represents 0 or an integer of 1 to 2.

The alkyl group for R is preferably a lower alkyl group, i.e., an alkyl group having 1 to 5 carbon atoms. Further, a linear or branched alkyl group is preferable, and examples thereof include a methyl group, an ethyl group, a propyl group, an isopropyl group, an n-butyl group, an isobutyl group, a tert-butyl group, a pentyl group, an isopentyl group, and a neopentyl group. Among these examples, a methyl group is industrially preferable.

Examples of halogen atoms include fluorine atoms, chlorine atoms, bromine atoms and iodine atoms, and fluorine atoms are particularly desirable.

As a halogenated alkyl group, a halogenated lower alkyl group is preferable, i.e., a group in which part or all of the hydrogen atoms of the aforementioned alkyl group of 1 to 5 carbon atoms have been substituted with halogen atom(s). Among these examples, it is preferable that all hydrogen atoms are fluorinated.

As the halogenated lower alkyl group, a linear or branched fluorinated lower alkyl group is preferable, a trifluoromethyl group, a hexafluoroethyl group, a heptafluoropropyl group or a nonafluorobutyl group is more preferable, and a trifluoromethyl group (—CF₃) is most preferable.

As R, a hydrogen atom or a methyl group is preferable, and a hydrogen atom is more preferable.

The lower alkyl group having 1 to 5 carbon atoms represented by R² is the same as defined for the lower alkyl group represented by R.

q represents 0 or an integer of 1 to 2. Among these, q is preferably 0 or 1, and most preferably 0 from industrial viewpoint.

Regarding the substitution position of R², in the case where q is 1, the substitution position may be any of o-position, m-position and p-position, and in the case where q is 2, arbitrary substitution positions may be combined.

p represents an integer of 1 to 3, and is preferably 1.

Regarding the substitution position, in the case where q is 1, the substitution position may be any of o-position, m-position and p-position, and in view of availability at a low cost, p-position is preferable. In the case where p is 2 or 3, arbitrary substitution positions may be combined.

The structural unit (a1) may use either one type of structural unit, or a mixture of two or more types.

The amount of the structural unit (a1) within the component (A1) based on the combined total of all structural units constituting the component (A1) is preferably 20 to 80 mol %, more preferably 25 to 70 mol %, still more preferably 30 to 65 mol %, and most preferably 45 to 65 mol %. When the amount is within the above-mentioned range, a satisfactory alkali solubility may be obtained when blended in a photoresist composition, and a good balance may be achieved with the other structural units.

(Structural Unit (a2))

The structural unit (a2) is a structural unit containing an acid dissociable, dissolution inhibiting group.

Preferable examples of the structural unit (a2) include a structural unit (a21) represented by general formula (a2-1) shown below, and a structural unit (a22) represented by general formula (a2-2) shown below.

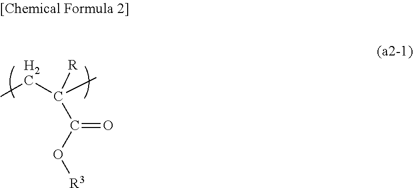

In the formula, R represents a hydrogen atom, an alkyl group, a halogen atom or a halogenated alkyl group; and R³ represents an acid dissociable, dissolution inhibiting group.

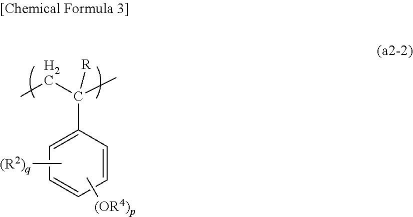

In the formula, R represents a hydrogen atom, an alkyl group, a halogen atom or a halogenated alkyl group; R² represents a lower alkyl group having 1 to 5 carbon atoms; p represents an integer of 1 to 3; q represents 0 or an integer of 1 to 2; and R⁴ represents an acid dissociable, dissolution inhibiting group.

In general formulae (a2-1) and (a2-2), R³ and R⁴ each independently represents an acid dissociable, dissolution inhibiting group.

The acid dissociable, dissolution inhibiting group may be selected from the multitude of groups that have been proposed for the resins of photoresist compositions designed for use with KrF excimer lasers, ArF excimer lasers, and the like. Specific examples thereof include a chain, tertiary alkoxycarbonyl group, a chain, tertiary alkoxycarbonylalkyl group, and a chain or cyclic tertiary alkyl group.

The chain-like, tertiary alkoxycarbonyl group preferably has 4 to 10 carbon atoms, and more preferably 4 to 8 carbon atoms. Specific examples of the chain-like, tertiary alkoxycarbonyl group include a tert-butoxycarbonyl group and a tert-amyloxycarbonyl group.

The chain-like, tertiary alkoxycarbonylalkyl group preferably has 4 to 10 carbon atoms, and more preferably 4 to 8 carbon atoms. Specific examples of the chain-like, tertiary alkoxycarbonylalkyl group include a tert-butoxycarbonylmethyl group and a tert-amyloxycarbonylmethyl group.

The chain-like, tertiary alkyl group preferably has 4 to 10 carbon atoms, and more preferably 4 to 8 carbon atoms. Specific examples of the chain-like, tertiary alkyl group include a tert-butyl group and a tert-amylyl group.

The cyclic tertiary alkyl group is a monocyclic or polycyclic monovalent saturated hydrocarbon group containing a tertiary carbon atom on the ring. Specific examples of the cyclic tertiary alkyl group include a 1-methylcyclopentyl group, a 1-ethylcyclopentyl group, a 1-methylcyclohexyl group, a 1-ethylcyclohexyl group, a 2-methyl-2-adamantyl group, and a 2-ethyl-2-adamantyl group.

By containing the above-mentioned chain-like tertiary alkoxycarbonyl group, chain-like tertiary alkoxycarbonylalkyl group, or chain-like or cyclic tertiary alkyl group as the acid dissociable, dissolution inhibiting group, heat resistance may be improved.

Among these acid dissociable, dissolution inhibiting groups, a chain-like tertiary alkyl group is particularly preferable from the viewpoint of resolution, and among them, a tert-butyl group is more preferable.

In the present embodiment, as the acid dissociable, dissolution inhibiting group, a group represented by general formula (I) shown below may also be given as a preferable example.

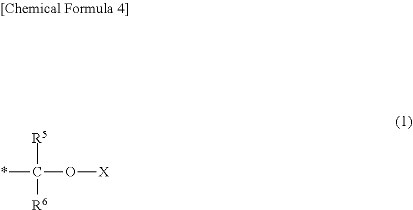

In the formula, X represents an aliphatic cyclic group, an aromatic hydrocarbon group or a lower alkyl group; R⁵ represents a hydrogen atom or a lower alkyl group; or alternatively, X and R⁵ independently represents an alkylene group having 1 to 5 carbon atoms, and a terminal of X is bonded to a terminal of R⁵; R⁶ represents a hydrogen atom or a lower alkyl group; and * indicates the bonding site.

In the present description and claims, as described above, the term “aliphatic” is a relative concept used in relation to the term “aromatic”, and defines a group or compound that has no aromaticity.

An “aliphatic cyclic group” refers to a monocyclic group or polycyclic group that has no aromaticity, and may be either saturated or unsaturated, but is preferably saturated.

The aliphatic cyclic group represented by X is a monovalent aliphatic cyclic group. The aliphatic cyclic group may be selected, for example, from the multitude of groups that have been proposed for conventional KrF photoresists and ArF photoresists.

Specific examples of the aliphatic cyclic group include an aliphatic monocyclic group of 5 to 7 carbon atoms and an aliphatic polycyclic group of 7 to 16 carbon atoms.

As the aliphatic monocyclic group of 5 to 7 carbon atoms, a group in which one hydrogen atom has been removed from a monocycloalkane can be mentioned, and specific examples include a group in which one hydrogen atom has been removed from cyclopentane or cyclohexane.

As the aliphatic polycyclic group of 7 to 16 carbon atoms, a group in which one hydrogen atom has been removed from a polycycloalkane can be mentioned, and specific examples include a group in which one hydrogen atom has been removed from a polycycloalkane such as adamantane, norbornane, isobornane, tricyclodecane or tetracyclododecane. Of these, an adamantyl group, a norbornyl group and a tetracyclododecyl group is preferred industrially, and an adamantyl group is particularly desirable.

As the aromatic cyclic hydrocarbon group for X, aromatic polycyclic groups of 10 to 16 carbon atoms can be mentioned. Examples of such aromatic cyclic groups include groups in which one hydrogen atom has been removed from naphthalene, anthracene, phenanthrene or pyrene. Specific examples include a 1-naphthyl group, a 2-naphthyl group, a 1-anthracenyl group, a 2-anthracenyl group, a 1-phenanthryl group, a 2-phenanthryl group, a 3-phenanthryl group and a 1-pyrenyl group, and a 2-naphthyl group is preferred industrially.

The lower alkyl group represented by X is the same as defined for the lower alkyl group represented by R in the aforementioned formula (a1-1).

As X, a lower alkyl group is preferable, a methyl group or an ethyl group is more preferable, and an ethyl group is most preferable.

The lower alkyl group represented by R⁵ is the same as defined for the lower alkyl group represented by R in the aforementioned formula (a1-1). In terms of industry, a methyl group or an ethyl group is preferable, and a methyl group is particularly desirable.

R⁶ represents a lower alkyl group or a hydrogen atom. The lower alkyl group represented by R⁶ is the same as defined for the lower alkyl group represented by R⁵. From industrial viewpoint, R⁶ is preferably a hydrogen atom.

Alternatively, in general formula (I), X and R⁵ each independently represents an alkylene group having 1 to 5 carbon atoms, and a terminal of X is bonded to a terminal of R⁵.

In such a case, in general formula (I), R⁵, X, the oxygen atom to which X is bonded, and the carbon atom to which the oxygen atom and R⁵ is bonded forms a cyclic group.

Such a cyclic group is preferably a 4- to 7-membered ring, and more preferably a 4- to 6-membered ring. Specific examples of the cyclic group include tetrahydropyranyl group and tetrahydrofuranyl group.

As an acid dissociable dissolution inhibiting group represented by general formula (I), in terms of the effects of the present invention, a group in which R⁶ represents a hydrogen atom is preferable.

Specific examples of groups in which X represents an alkyl group, i.e., 1-alkoxyalkyl groups include a 1-methoxyethyl group, a 1-ethoxyethyl group, a 1-isopropoxyethyl group, a 1-n-butoxyethyl group, a 1-tert-butoxyethyl group, a methoxymethyl group, an ethoxymethyl group, an isopropoxymethyl group, an n-butoxymethyl group and a tert-butoxymethyl group.

Further, examples of groups in which X represents an aliphatic cyclic group include a 1-cyclohexyloxyethyl group, a (2-adamantyl)oxymethyl group, and a 1-(1-adamantyl)oxyethyl group which is represented by formula (II-a) shown below.

As an example of a group in which X represents an aromatic cyclic hydrocarbon group, a 1-(2-naphthyl)oxyethyl group which is represented by formula (II-b) shown below can be mentioned.

Among these examples, a 1-ethoxyethyl group is preferable.

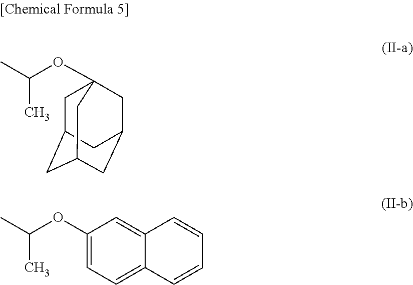

In the present embodiment, as the acid dissociable dissolution inhibiting group, at least one member selected from the group consisting of a chain tertiary alkoxycarbonyl group, a chain alkoxycarbonylalkyl group, a chain or cyclic tertiary alkyl group, and a group represented by the aforementioned general formula (I) is preferably used.

Among these examples, a group represented by the aforementioned general formula (I) is more preferable, and a resin containing as a main component a group represented by the aforementioned general formula (I) is most preferable.

Here, the term “containing as a main component” means 50 mol % or more of the acid dissociable dissolution inhibiting groups contained in the component (A1), preferably 70 mol % or more, and more preferably 80 mol % or more.

In the structural units (a21) and (a22), R is the same as defined for R in the aforementioned general formula (a1-1).

R² in the structural unit (a22) is the same as defined for R² in the aforementioned general formula (a1-1).

In the structural unit (a22), p and q are the same as defined for p and q in the aforementioned general formula (a1-1).

The structural unit (a2) may use either one type of structural unit, or a mixture of two or more types.

The amount of the structural unit (a2) within the component (A1) based on the combined total of all structural units constituting the component (A1) is preferably 5 to 70 mol %, more preferably 5 to 65 mol %, still more preferably 5 to 60 mol %, and most preferably 5 to 55 mol %. When the amount of the structural unit (a2) is at least as large as the lower limit of the above-mentioned range, a good pattern may be obtained using a photoresist composition prepared from the component (A1). On the other hand, when the amount of the structural unit (a2) is no more than the upper limit of the above-mentioned range, a good balance can be achieved with the other structural units.

Further, in the case where the structural unit (a2) is the structural unit (a21), the amount of the structural unit (a21) within the component (A1) based on the combined total of all structural units constituting the component (A1) is preferably 5 to 70 mol %, more preferably 5 to 50 mol %, still more preferably 10 to 45 mol %, and most preferably 10 to 35 mol %. When the amount of the structural unit (a21) is at least as large as the lower limit of the above-mentioned range, a good pattern may be obtained using a photoresist composition prepared from the component (A1). On the other hand, when the amount of the structural unit (a21) is no more than the upper limit of the above-mentioned range, a good balance can be achieved with the other structural units.

Further, in the case where the structural unit (a2) is the structural unit (a22), the amount of the structural unit (a22) within the component (A1) based on the combined total of all structural units constituting the component (A1) is preferably 5 to 70 mol %, more preferably 10 to 65 mol %, still more preferably 20 to 60 mol %, and most preferably 30 to 55 mol %. When the amount of the structural unit (a22) is at least as large as the lower limit of the above-mentioned range, a good pattern may be obtained using a photoresist composition prepared from the component (A1). On the other hand, when the amount of the structural unit (a22) is no more than the upper limit of the above-mentioned range, a good balance can be achieved with the other structural units.

(Structural Unit (a3))

The component (A1) may contain a structural unit (a3) derived from styrene. By including the structural unit (a3), the heat resistance of the photoresist composition may be improved.

In the structural unit (a3), the “structural unit derived from styrene” includes a structural unit in which the ethylenic double bond of styrene or a styrene derivative (excluding hydroxystyrene) is cleaved.

The term “styrene derivative” includes compounds in which the hydrogen atom at the α-position of styrene has been substituted with another substituent such as an alkyl group or a halogenated alkyl group; and derivatives thereof; and a compound in which the hydrogen atom(s) on the phenyl group of styrene has been substituted with a substituent such as a lower alkyl group having 1 to 5 carbon atoms.

Examples of halogen atoms include a chlorine atom, a fluorine atom and a bromine atom, and a fluorine atom is preferable.

Here, the α-position of styrene refers to the carbon atom having the benzene ring bonded thereto, unless specified otherwise.

Preferable examples of the structural unit (a3) include a structural unit (a31) represented by general formula (a3-1) shown below.

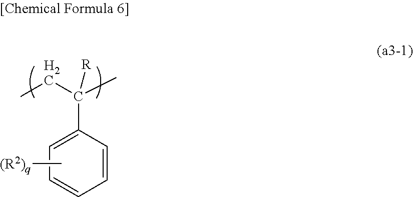

In the formula, R represents a hydrogen atom, an alkyl group, a halogen atom or a halogenated alkyl group; R² represents a lower alkyl group having 1 to 5 carbon atoms; and q represents 0 or an integer of 1 to 2.

R and R² are the same as defined for R and R² in the aforementioned general formula (a1-1).

q represents 0 or an integer of 1 to 2. Among these, q is preferably 0 or 1, and most preferably 0 from industrial viewpoint.

Regarding the bonding position of R², in the case where q is 1, the bonding position may be any of o-position, m-position and p-position, and in the case where q is 2, arbitrary substitution positions may be combined.

The structural unit (a3) may use either one type of structural unit, or a mixture of two or more types.

When the component (A1) includes the structural unit (a3), the amount of the structural unit (a3) based on the combined total of all structural units constituting the component (A1) is preferably 1 to 25 mol %, more preferably 5 to 25 mol %, and most preferably 5 to 20 mol %. When the amount of the structural unit (a3) is within the above-mentioned range, the heat resistance of the photoresist composition may be improved, and a good balance may be achieved with the other structural units.

The component (A1) may also have a structural unit other than the above-mentioned structural units (a1) and (a2), and preferably (a3), as long as the effects of the present invention are not impaired.

As such a structural unit, any other structural unit which cannot be classified as one of the above essential structural units (a1) and (a2), and preferable optional structural unit (a3) may be used without any particular limitation, and any of the multitude of conventional structural units used within photoresist resins for KrF excimer lasers or ArF excimer lasers can be used.

As the component (A1), a copolymer (All-1-1) consisting of a combination of the following structural units is particularly desirable.

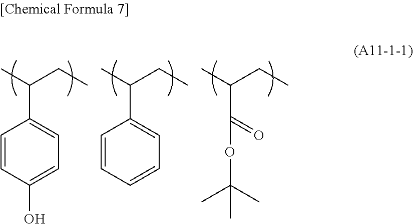

The component (A1) can be obtained, for example, by a conventional radical polymerization or the like of the monomers corresponding with each of the structural units, using a radical polymerization initiator such as azobisisobutyronitrile (AIBN).

Furthermore, in the component (A1), by using a chain transfer agent such as HS—CH₂—CH₂—CH₂—C(CF₃)₂—OH, a —C(CF₃)₂—OH group can be introduced at the terminals of the component (A1). Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

The weight average molecular weight (Mw) (the polystyrene equivalent value determined by gel permeation chromatography) of the component (A1) is not particularly limited, but is preferably 2,000 to 50,000, more preferably 3,000 to 30,000, and most preferably 4,000 to 20,000.

When the weight average molecular weight is at least as large as the lower limit of the above-mentioned range, a satisfactory solubility of the photoresist composition in a photoresist solvent may be achieved, and the viscosity of the composition may be decreased. On the other hand, when the weight average molecular weight is no more than the upper limit of the above-mentioned range, dry-etching resistance and the cross-sectional shape of the resist pattern becomes satisfactory.

Further, the dispersity (Mw/Mn) is preferably 1.0 to 5.0, more preferably 1.0 to 3.0, and most preferably 1.2 to 2.5.

In the component (A), as the component (A1), one type may be used alone, or two or more types may be used in combination.

Further, in the component (A), a resin component other than the component (A1) may be blended.

In the component (A), the amount of the component (A1) is preferably 70% by weight or more, more preferably 80% by weight or more, and most preferably 100% by weight.

[Resin (A2)]

In the photoresist composition according to the present embodiment, the component (A) may include, as a resin (A2) (hereafter, sometimes referred to as “component (A2)”), a structural unit (a1)′ containing an acid decomposable group that exhibits increased polarity by the action of acid, a structural unit (a2)′ containing a lactone-containing cyclic group, a carbonate-containing cyclic group or an —SO₂— containing cyclic group (provided that the structural units that fall under the definition of structural unit (a1)′ are excluded), a structural unit (a3)′ containing a polar group-containing aliphatic hydrocarbon group (provided that the structural units that fall under the definition of structural units (a1)′ and (a2)′ are excluded), and a structural unit (a4)′ containing an acid non-dissociable aliphatic cyclic group.

(Structural Unit (a1)′)

The structural unit (a1)′ is a structural unit containing an acid decomposable group that exhibits increased polarity by the action of acid.

The term “acid decomposable group” refers to a group in which at least a part of the bond within the structure thereof is cleaved by the action of an acid.

Examples of acid decomposable groups which exhibit increased polarity by the action of an acid include groups which are decomposed by the action of an acid to form a polar group.

Examples of the polar group include a carboxy group, a hydroxy group, an amino group and a sulfonic acid group (—SO₃H). Among these, a sulfonic acid group or a polar group containing —OH in the structure (hereinafter sometimes referred to as “OH-containing polar group”) is preferable, a sulfonic acid group, a carboxy group, or a hydroxy group is preferable, and a carboxy group or a hydroxy group is most preferable.

More specifically, as an example of an acid decomposable group, a group in which the aforementioned polar group has been protected with an acid dissociable group (such as a group in which the hydrogen atom of the OH-containing polar group has been protected with an acid dissociable group) can be given.

Here, the “acid dissociable group” includes:

(i) a group in which the bond between the acid dissociable group and the adjacent atom is cleaved by the action of acid; and

(ii) a group in which one of the bonds is cleaved by the action of acid, and then a decarboxylation reaction occurs, thereby cleaving the bond between the acid dissociable group and the adjacent atom.

It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group exhibiting a higher polarity than that of the acid dissociable group is generated, thereby increasing the polarity. As a result, the polarity of the entire component (A2) is increased. By the increase in the polarity, the solubility in an alkali developing solution changes and, the solubility in an organic developing solution is relatively decreased.

The acid dissociable group is not particularly limited, and any of the groups that have been conventionally proposed as acid dissociable groups for the base resins of photoresists may be used.

Examples of the acid dissociable group for protecting the carboxy group or hydroxy group as a polar group include an acid dissociable group represented by general formula (a1-r-1)′ shown below (hereafter, referred to as “acetal-type acid dissociable group”).

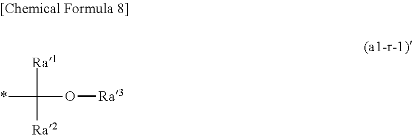

In the formula, Ra′¹ and Ra′² represents a hydrogen atom or an alkyl group; and Ra′³ represents a hydrocarbon group, provided that Ra′³ may be bonded to Ra′¹ or Ra′²; and * indicates the bonding site.

In formula (a1-r-1), as the lower alkyl group for Ra′¹ and Ra′², the same lower alkyl groups as those described above the alkyl groups as the substituent which may be bonded to the carbon atom on the α-position of the aforementioned α-substituted alkylester can be used, although a methyl group or ethyl group is preferable, and a methyl group is particularly desirable.

The hydrocarbon group for Ra′³ is preferably an alkyl group of 1 to 20 carbon atoms, more preferably an alkyl group of 1 to 10 carbon atoms, and still more preferably a linear or branched alkyl group. Specific examples thereof include a methyl group, an ethyl group, a propyl group, an isopropyl group, an n-butyl group, an isobutyl group, a tert-butyl group, a pentyl group, an isopentyl group, a neopentyl group, a 1,1-dimethylethyl group, a 1,1-diethylpropyl group, a 2,2-dimethylpropyl group and a 2,2-dimethylbutyl group.

In the case where Ra′³ represents a cyclic hydrocarbon group, the cyclic hydrocarbon group may be aliphatic or aromatic, and may be polycyclic or monocyclic. As the monocyclic aliphatic hydrocarbon group, a group in which 1 hydrogen atom has been removed from a monocycloalkane is preferable. The monocycloalkane preferably has 3 to 8 carbon atoms, and specific examples thereof include cyclopentane, cyclohexane and cyclooctane. As the polycyclic group, a group in which 1 hydrogen atom has been removed from a polycycloalkane is preferable, and the polycyclic group preferably has 7 to 12 carbon atoms. Examples of the polycycloalkane include adamantane, norbornane, isobornane, tricyclodecane and tetracyclododecane.

In the case where the hydrocarbon group is an aromatic hydrocarbon group, examples of the aromatic ring contained in the aromatic hydrocarbon group include aromatic hydrocarbon rings, such as benzene, biphenyl, fluorene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hydrocarbon group include a group in which one hydrogen atom has been removed from the aforementioned aromatic hydrocarbon ring (aryl group); and a group in which one hydrogen atom of the aryl group has been substituted with an alkylene group (such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atom, more preferably 1 or 2, and most preferably 1.

In the case where Ra′³ is bonded to Ra′¹ or Ra′² to form a ring, the cyclic group is preferably a 4 to 7-membered ring, and more preferably a 4 to 6-membered ring. Specific examples of the cyclic group include tetrahydropyranyl group and tetrahydrofuranyl group.

Examples of the acid dissociable group for protecting the carboxy group as a polar group include the acid dissociable group represented by general formula (a1-r-2)′ shown below (hereafter, with respect to the acid dissociable group represented by the following formula (a1-r-2)′, the acid dissociable group constituted of alkyl groups is referred to as “tertiary ester-type acid dissociable group”).

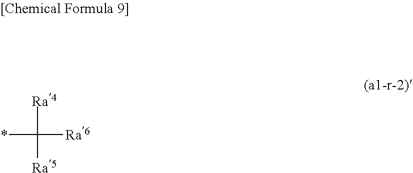

In the formula, Ra′⁴ to Ra′⁶ each independently represents a hydrocarbon group, provided that Ra′⁵ and Ra′⁶ may be mutually bonded to form a ring; and * indicates the bonding site.

As the hydrocarbon group for Ra′⁴ to Ra′⁶, the same groups as those described above for Ra′³ can be mentioned. Ra′⁴ is preferably an alkyl group having from 1 to 5 carbon atoms. In the case where Ra′⁵ and Ra′⁶ are mutually bonded to form a ring, a group represented by general formula (a1-r2-1)′ shown below can be mentioned.

On the other hand, in the case where Ra′⁴ to Ra′⁶ are not mutually bonded and independently represent a hydrocarbon group, the group represented by general formula (a1-r2-2)′ shown below can be mentioned.

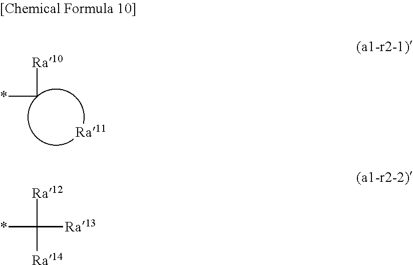

In the formulae, Ra′¹⁰ represents an alkyl group of 1 to 10 carbon atoms; Ra′¹¹ is a group which forms an aliphatic cyclic group together with a carbon atom having Ra′¹⁰ bonded thereto; and Ra′¹² to Ra′¹⁴ each independently represents a hydrocarbon group; and * indicates the bonding site.

In the formula (a1-r2-1)′, as the alkyl group of 1 to 10 carbon atoms for Ra′¹⁰, the same groups as described above for the linear or branched alkyl group for Ra′³ in the formula (a1-r-1)′ are preferable. In the formula (a1-r2-1)′, as the aliphatic cyclic group which is formed by Ra′¹¹, the same groups as those described above for the cyclic alkyl group for Ra′³ in the formula (a1-r-1)′ are preferable.

In the formula (a1-r2-2)′, it is preferable that Ra′¹² and Ra′¹⁴ each independently represents an alkyl group or 1 to 10 carbon atoms, and it is more preferable that the alkyl group is the same group as the described above for the linear or branched alkyl group for Ra′³ in the formula (a1-r-1)′, it is still more preferable that the alkyl group is a linear alkyl group of 1 to 5 carbon atoms, and it is particularly preferable that the alkyl group is a methyl group or an ethyl group.

In the formula (a1-r2-2)′, it is preferable that Ra′¹³ is the same group as described above for the linear, branched or cyclic alkyl group for Ra′³ in the formula (a1-r-1)′. Among these, the same cyclic alkyl group as those describe above for Ra′³ is more preferable.

Specific examples of the formula (a1-r2-1)′ are shown below. * indicates a bonding site.

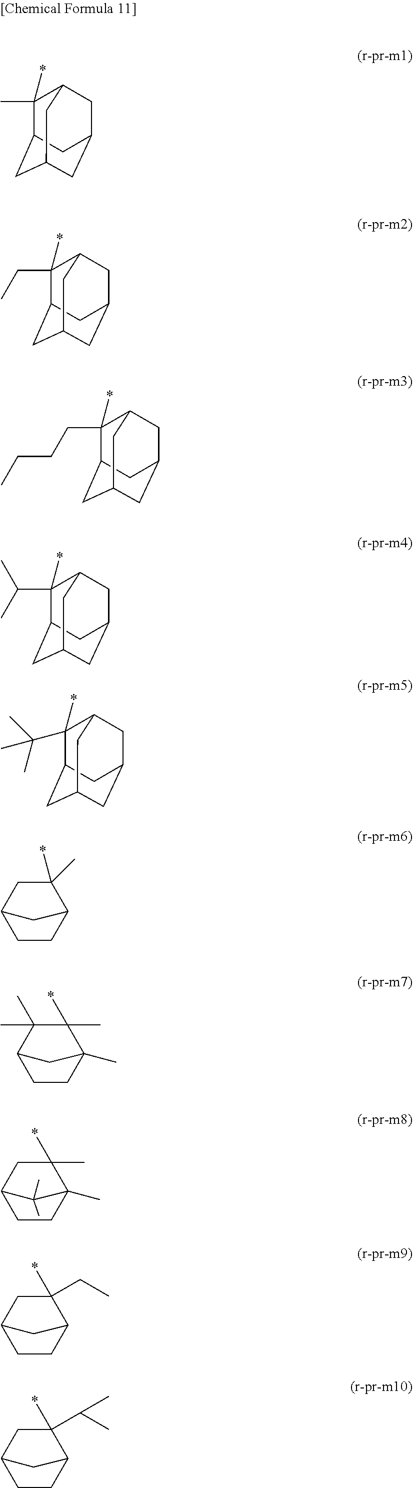

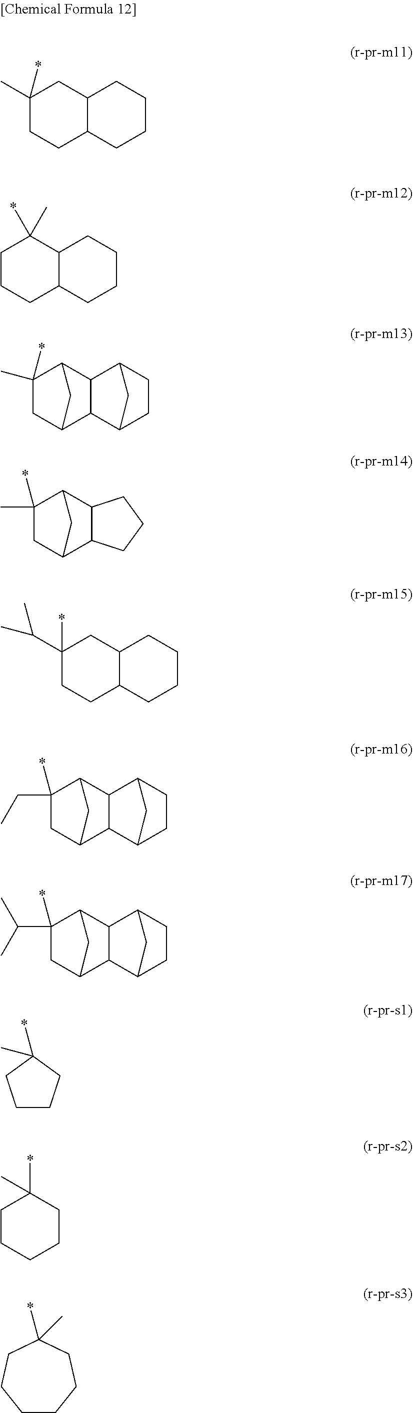

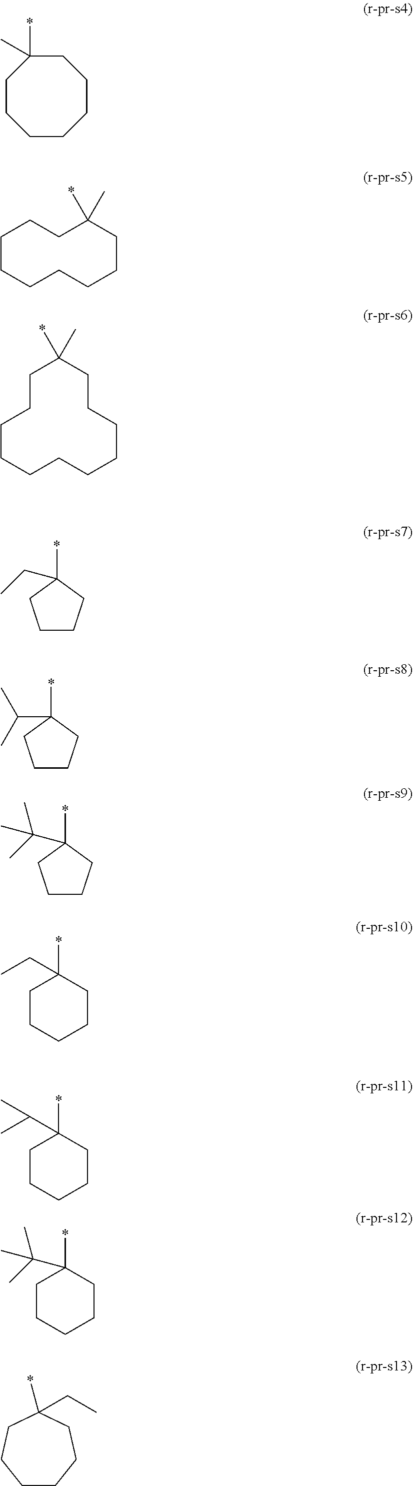

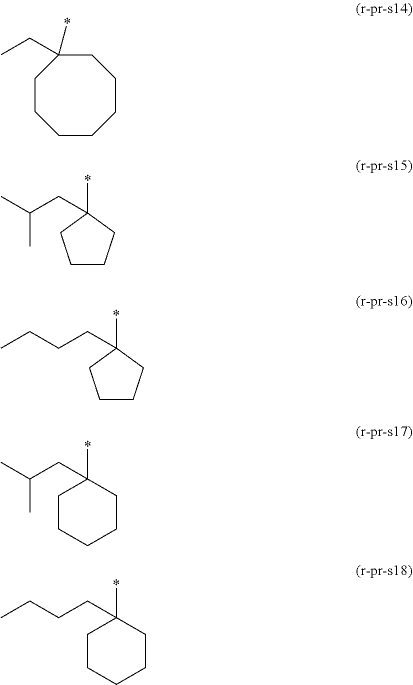

Specific examples of the formula (a1-r2-2)′ are shown below. * indicates a bonding site.

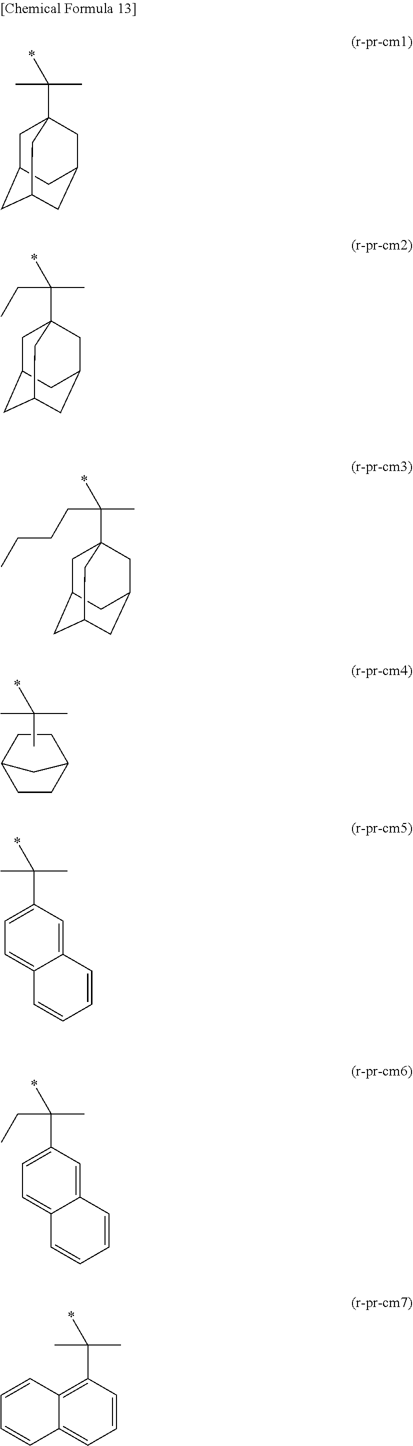

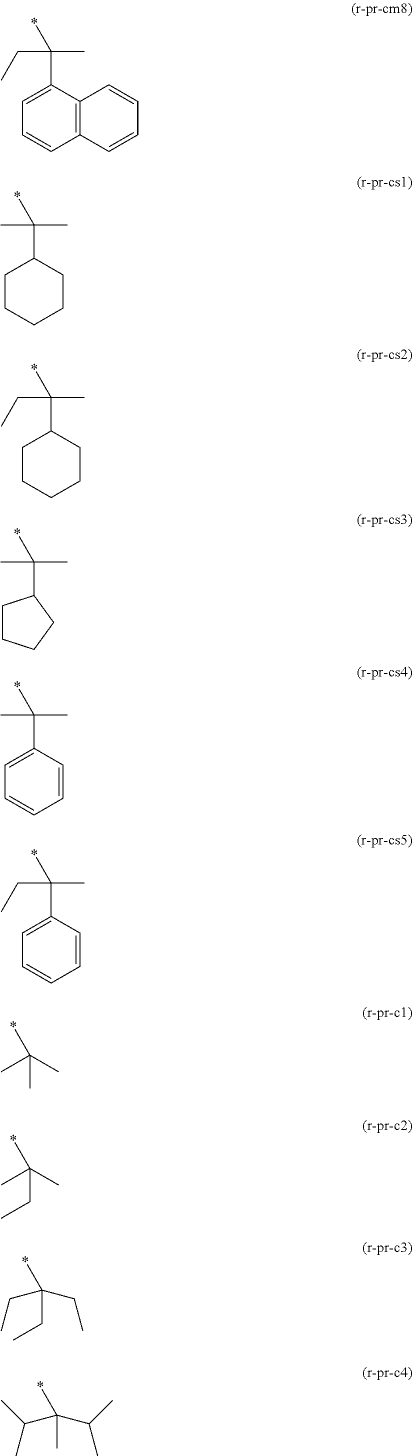

Examples of the acid dissociable group for protecting a hydroxy group as a polar group include the acid dissociable group represented by general formula (a1-r-3)′ shown below (hereafter, for convenience, referred to as “tertiary alkyloxycarbonyl-type acid dissociable group”).

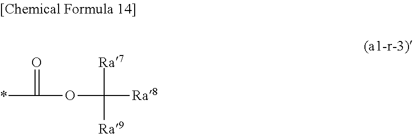

In the formula, Ra′⁷ to Ra′⁹ each independently represents an alkyl group; and * indicates the bonding site.

In the formula (a1-r-3)′, Ra′⁷ to Ra′⁹ is preferably an alkyl group of 1 to 5 carbon atoms, and more preferably an alkyl group of 1 to 3 carbon atoms.

Further, the total number of carbon atoms within the alkyl group is preferably 3 to 7, more preferably 3 to 5, and most preferably 3 or 4.

Examples of the structural unit (a1)′ include a structural unit derived from an acrylate ester which may have the hydrogen atom bonded to the carbon atom on the α-position substituted with a substituent and contains an acid decomposable group which exhibits increased polarity by the action of acid; a structural unit derived from hydroxystyrene or a hydroxystyrene derivative in which at least a part of the hydrogen atom of the hydroxy group is protected with a substituent containing an acid decomposable group; and a structural unit derived from vinylbenzoic acid or a vinylbenzoic acid derivative in which at least a part of the hydrogen atom within —C(═O)—OH is protected with a substituent containing an acid decomposable group.

As the structural unit (a1)′, a structural unit derived from an acrylate ester which may have the hydrogen atom bonded to the carbon atom on the α-position substituted with a substituent is preferable.

As the structural unit (a1)′, a structural unit represented by formula (a1-1)′ or (a1-2)′ shown below is preferable.

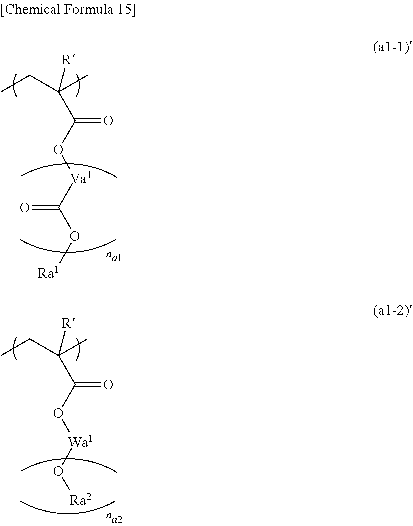

In the formula, R′ represents a hydrogen atom, an alkyl group of 1 to 5 carbon atoms or a halogenated alkyl group of 1 to 5 carbon atoms; Va¹ represents a divalent hydrocarbon group which may contain an ether bond, an urethane bond or an amide bond; each nₐ₁ represents an integer of 0 to 2; Ra¹ represents an acid dissociable group represented by the aforementioned formula (a1-r-1)′ or (a1-r-2)′; Wa¹ represents a hydrocarbon group having a valency of nₐ₂+1; nₐ₂ represents an integer of 1 to 3; and Ra² represents an acid dissociable group represented by the aforementioned formula (a1-r-1)′ or (a1-r-3)′.

In formula (a1-1)′, as the alkyl group of 1 to 5 carbon atoms for R, a linear or branched alkyl group of 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group and a neopentyl group. The halogenated alkyl group of 1 to 5 carbon atoms represented by R is a group in which part or all of the hydrogen atoms of the aforementioned alkyl group of 1 to 5 carbon atoms have been substituted with halogen atoms. Examples of the halogen atom include a fluorine atom, a chlorine atom, a bromine atom and an iodine atom, and a fluorine atom is particularly desirable.

As R′, a hydrogen atom, an alkyl group of 1 to 5 carbon atoms or a fluorinated alkyl group of 1 to 5 carbon atoms is preferable, and a hydrogen atom or a methyl group is particularly desirable in terms of industrial availability.

The hydrocarbon group for Va¹ may be either an aliphatic hydrocarbon group or an aromatic hydrocarbon group. An “aliphatic hydrocarbon group” refers to a hydrocarbon group that has no aromaticity. The aliphatic hydrocarbon group as the divalent hydrocarbon group for Va¹ may be either saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

Further examples of Va^{l} include a group in which the aforementioned divalent linking group has bonded thereto an ether bond, a urethane bond or an amide bond.

The linear or branched aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

As examples of the hydrocarbon group containing a ring in the structure thereof, an alicyclic hydrocarbon group (a group in which two hydrogen atoms have been removed from an aliphatic hydrocarbon ring), a group in which the alicyclic hydrocarbon group is bonded to the terminal of the aforementioned chain-like aliphatic hydrocarbon group, and a group in which the alicyclic group is interposed within the aforementioned linear or branched aliphatic hydrocarbon group, can be given. The linear or branched aliphatic hydrocarbon group is the same as defined above.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The aromatic hydrocarbon group is a hydrocarbon group having an aromatic ring.

The aromatic hydrocarbon group as the divalent hydrocarbon group for Va¹ preferably has 3 to 30 carbon atoms, more preferably 5 to 30, still more preferably 5 to 20, still more preferably 6 to 15, and most preferably 6 to 10. Here, the number of carbon atoms within a substituent(s) is not included in the number of carbon atoms of the aromatic hydrocarbon group.

Examples of the aromatic ring contained in the aromatic hydrocarbon group include aromatic hydrocarbon rings, such as benzene, biphenyl, fluorene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hydrocarbon group include a group in which two hydrogen atoms have been removed from the aforementioned aromatic hydrocarbon ring (arylene group); and a group in which one hydrogen atom has been removed from the aforementioned aromatic hydrocarbon ring (aryl group) and one hydrogen atom has been substituted with an alkylene group (such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atom, more preferably 1 or 2, and most preferably 1.

In the aforementioned formula (a1-2)′, the hydrocarbon group for Wa¹ having a valency of nₐ₂+1 may be either an aliphatic hydrocarbon group or an aromatic hydrocarbon group. The aliphatic cyclic group refers to a hydrocarbon group that has no aromaticity, and may be either saturated or unsaturated, but is preferably saturated. Examples of the aliphatic hydrocarbon group include a linear or branched aliphatic hydrocarbon group, an aliphatic hydrocarbon group containing a ring in the structure thereof, and a combination of the linear or branched aliphatic hydrocarbon group and the aliphatic hydrocarbon group containing a ring in the structure thereof. As the specific examples thereof, the same groups as those described above for Va¹ in the aforementioned formula (a1-1)′ can be mentioned.

The valency of nₐ₂+1 is preferably divalent, trivalent or tetravalent, and divalent or trivalent is more preferable.

As the structural unit represented by formula (a1-2)′, a structural unit represented by general formula (a1-2-01)′ shown below is particularly desirable.

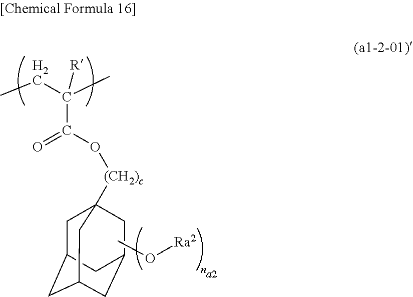

In the formula (a1-2-01)′, Ra² represents an acid dissociable group represented by the aforementioned formula (a1-r-1)′ or (a1-r-3)′; nₐ₂ is an integer of 1 to 3, preferably 1 or 2, and more preferably 1; c is an integer of 0 to 3, preferably 0 or 1, and more preferably 1; R′ is the same as defined above.

Specific examples of the structural units (a1-1)′ and (a1-2)′ are shown below. In the formulae shown below. R^{α} represents a hydrogen atom, a methyl group or a trifluoromethyl group.

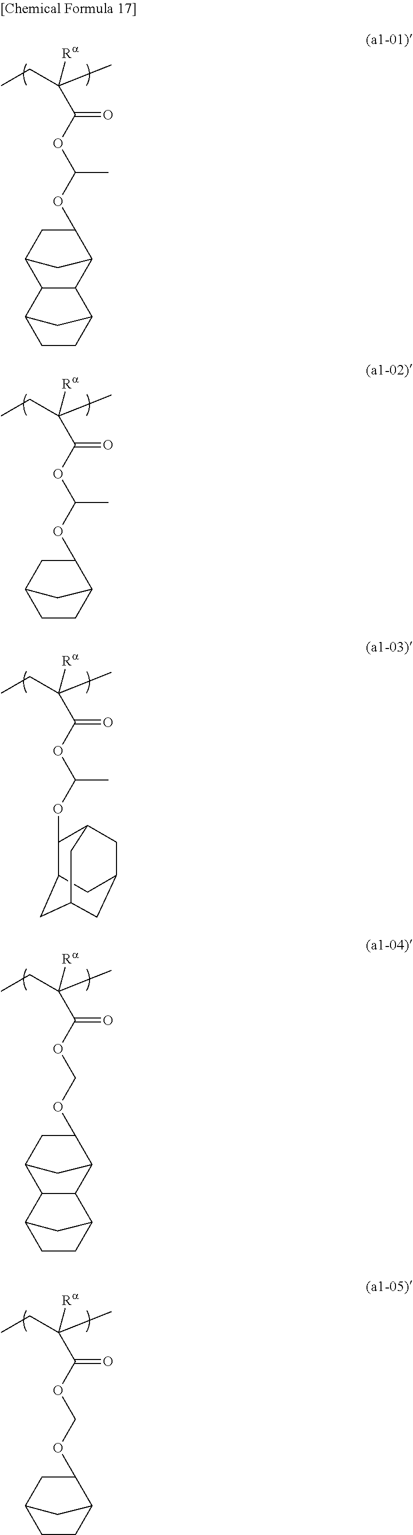

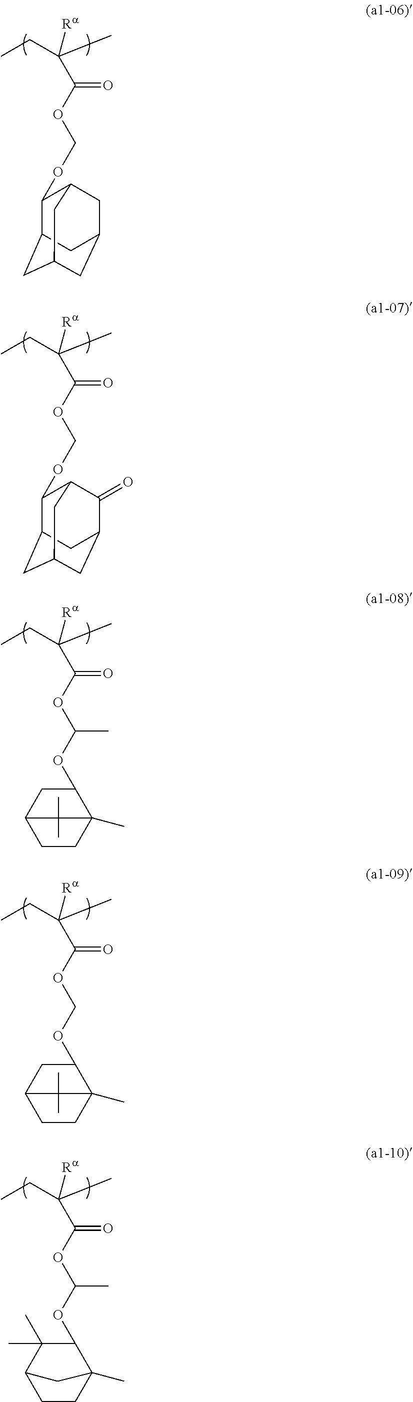

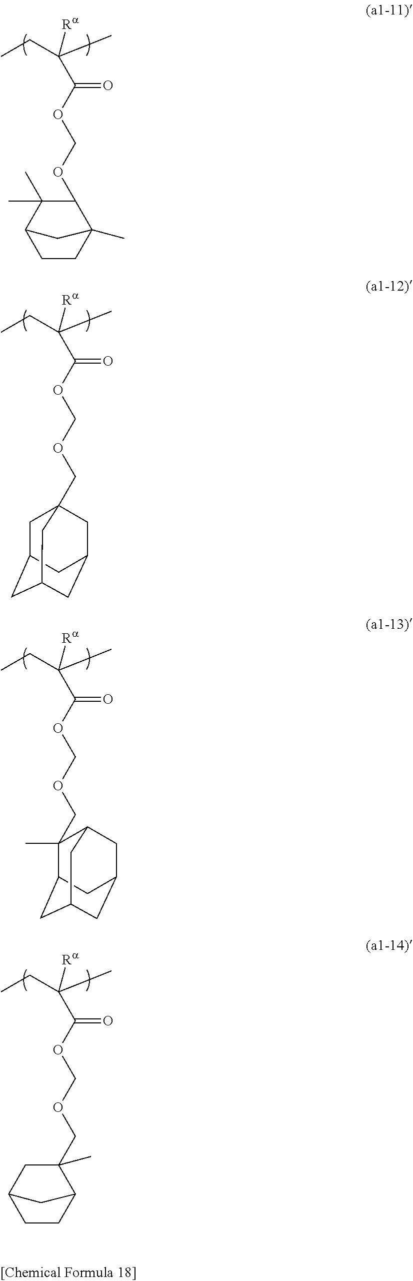

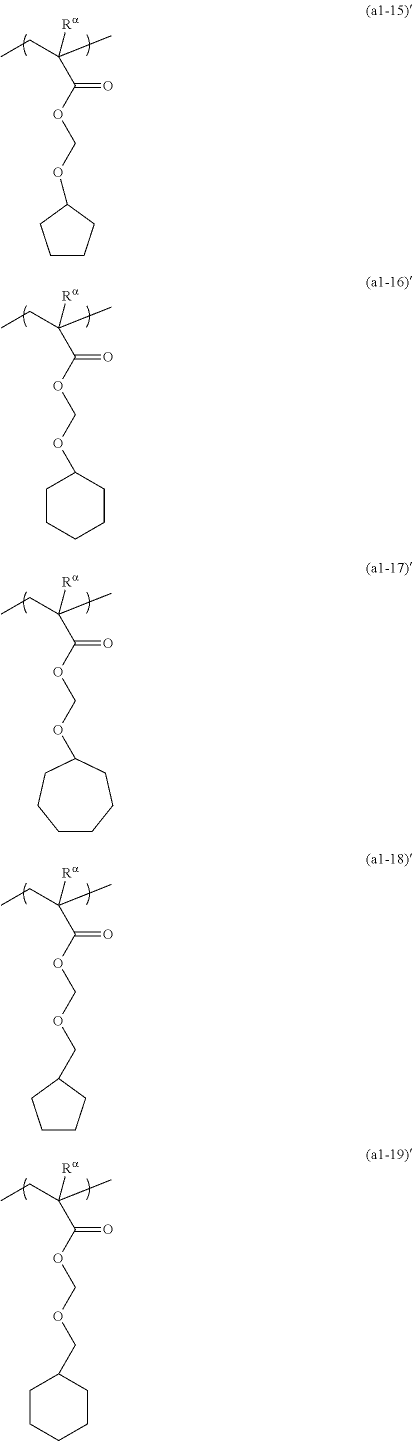

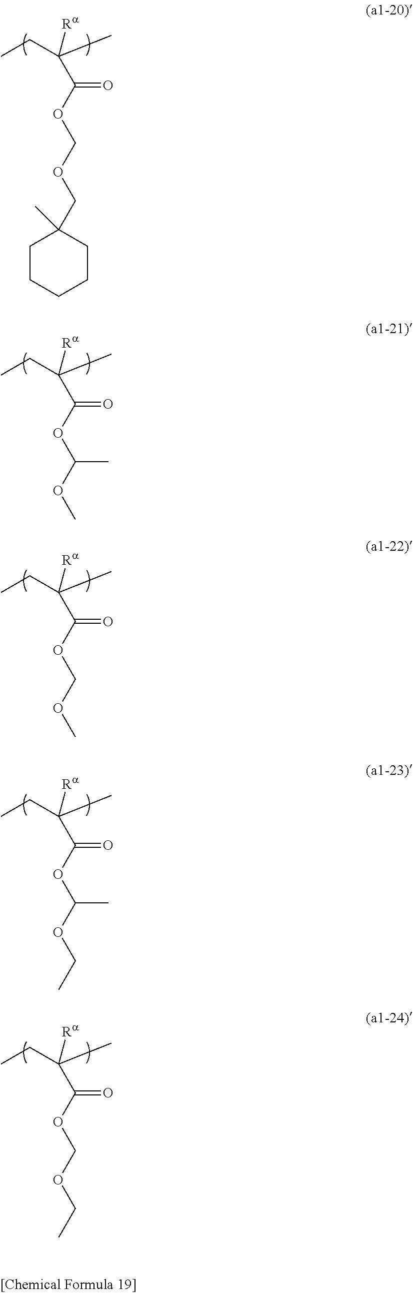

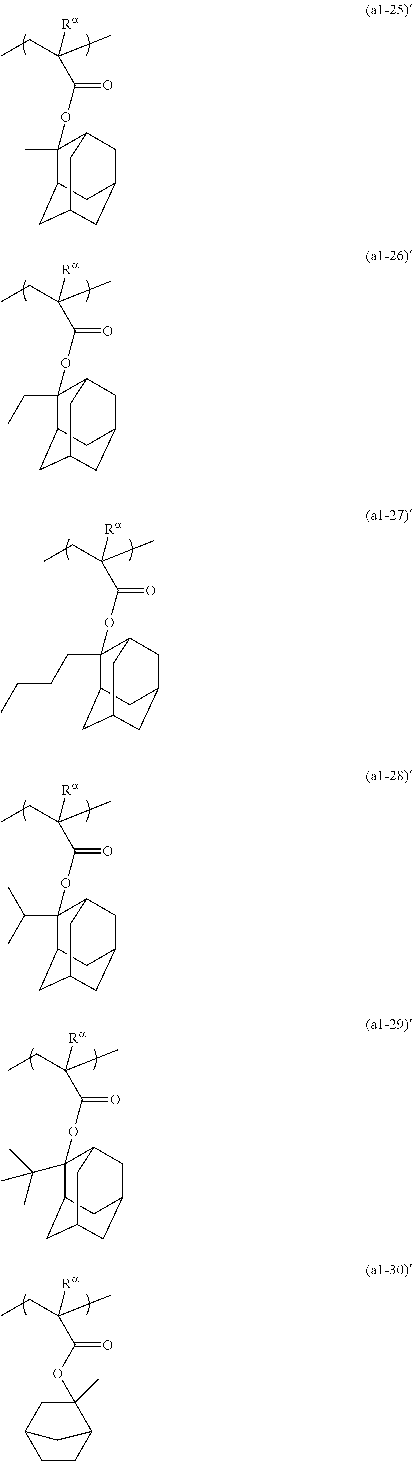

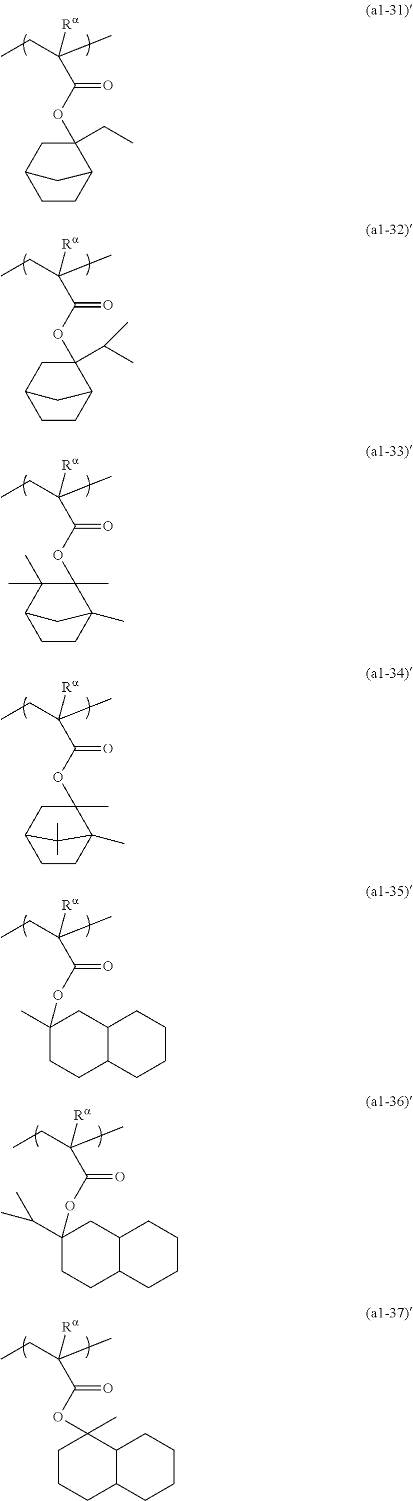

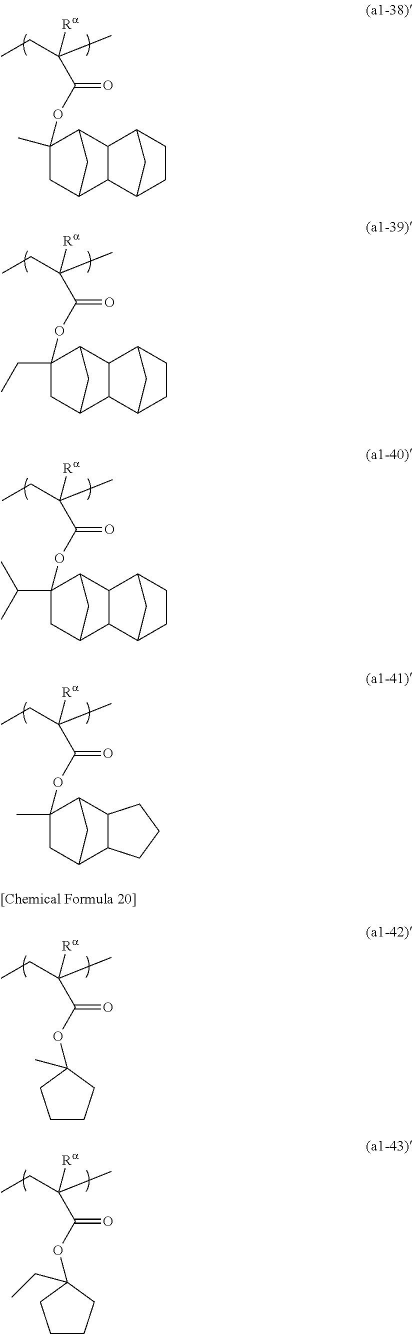

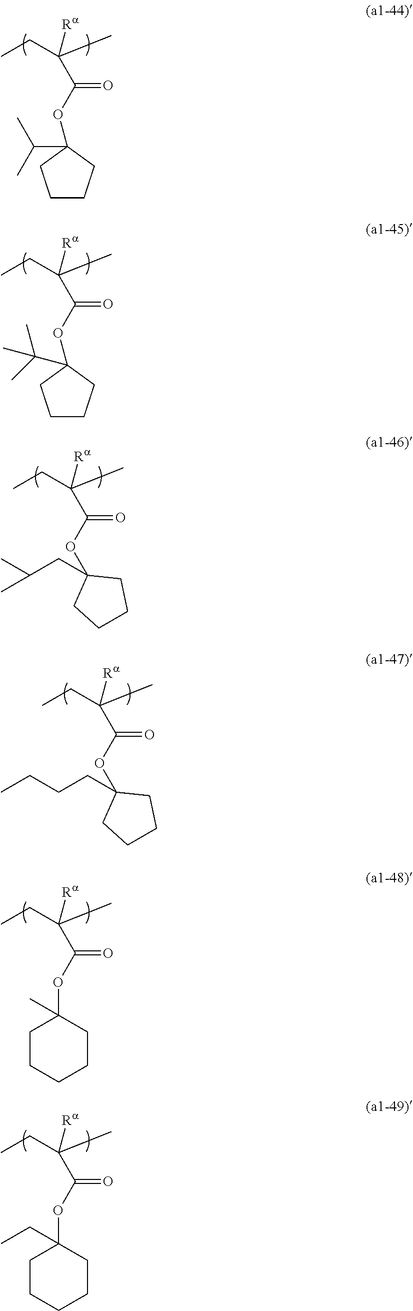

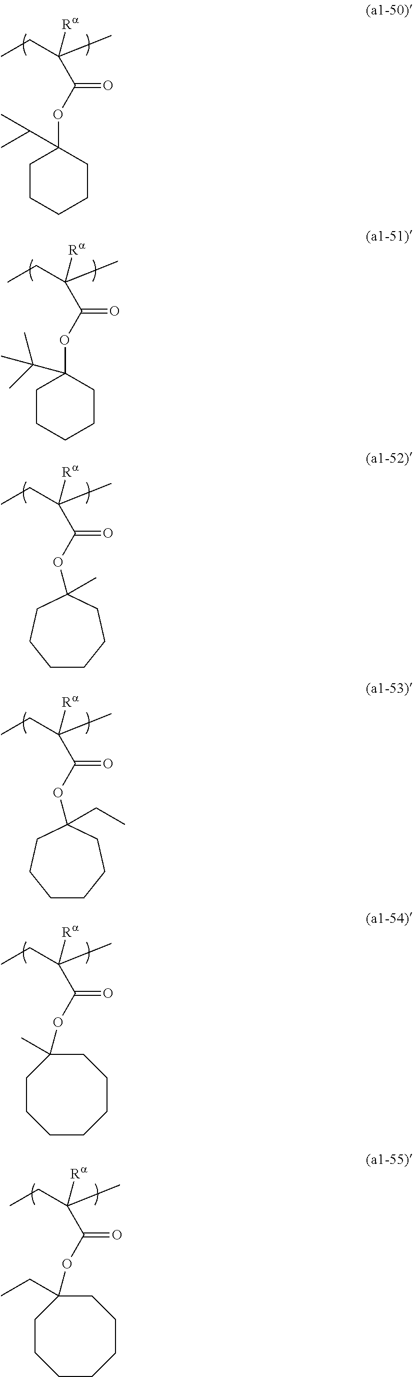

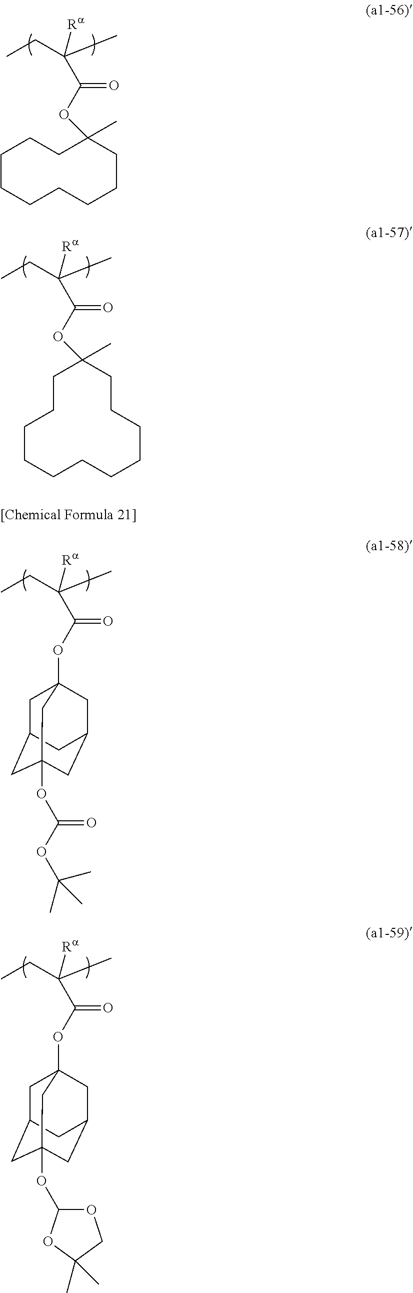

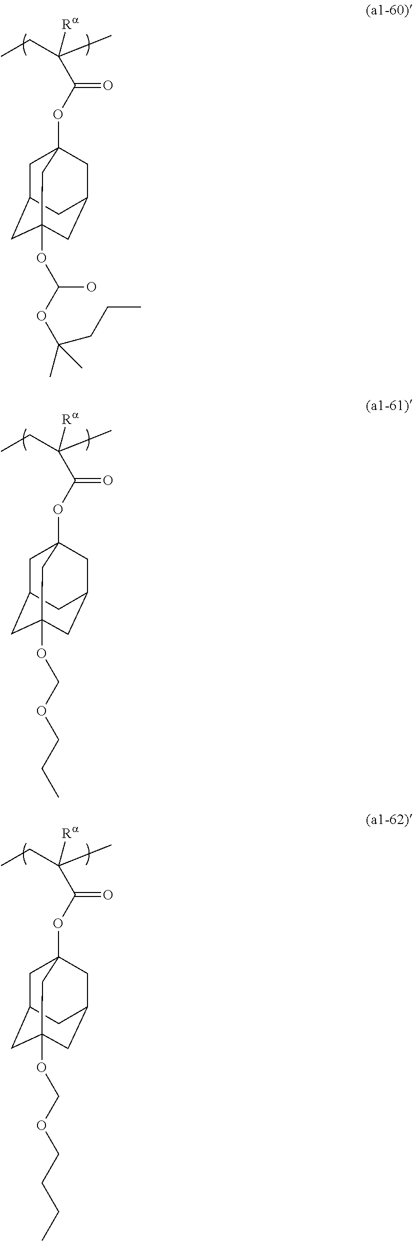

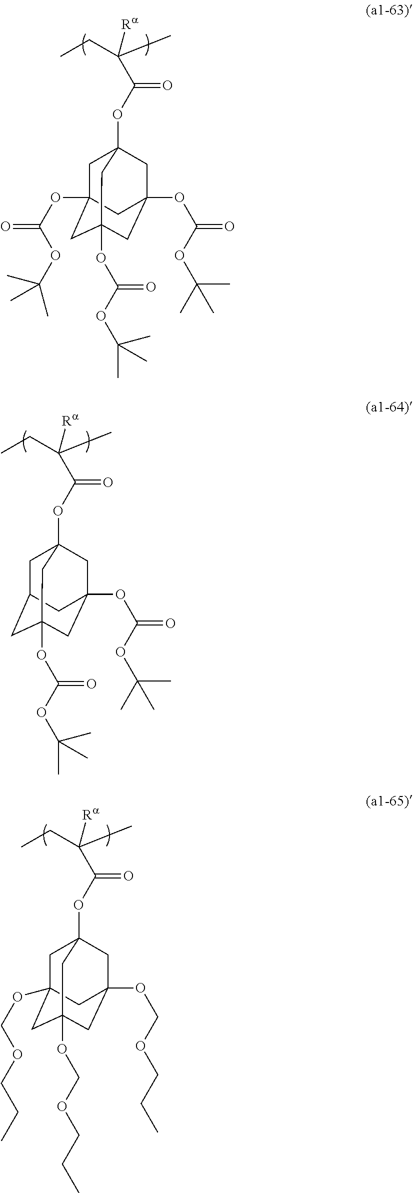

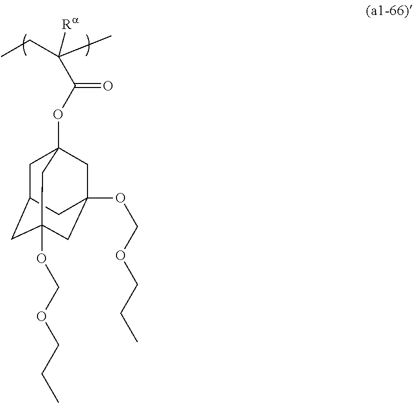

In the component (A2), the amount of the structural unit (a1)′ based on the combined total of all structural units constituting the component (A2) is preferably 20 to 80 mol %, more preferably 20 to 75 mol %, and still more preferably 25 to 70 mol %. By ensuring the lower limit, various lithography properties such as sensitivity, resolution and LWR may be improved. On the other hand, when the amount of the structural unit (a1)′ is no more than the upper limit of the above-mentioned range, a good balance can be achieved with the other structural units.

(Structural Unit (a2)′)

In the present embodiment, the base component may include a structural unit (a2)′ having an —SO₂— containing cyclic group, a lactone-containing cyclic group, a carbonate-containing cyclic group or any other heterocyclic group.

When the component (A2) is used for forming a photoresist film, the structural unit (a2)′ containing an —SO₂— containing cyclic group, a lactone-containing cyclic group, a carbonate-containing cyclic group or any other heterocyclic group is effective in improving the adhesion between the photoresist film and the substrate.

The aforementioned structural unit (a1)′ which contains an —SO₂— containing cyclic group, a lactone-containing cyclic group, a carbonate-containing cyclic group or any other heterocyclic group falls under the definition of the structural unit (a2)′; however, such a structural unit is regarded as a structural unit (a1)′, and does not fall under the definition of the structural unit (a2)′.

The structural unit (a2)′ is preferably a structural unit represented by general formula (a2-1)′ shown below.

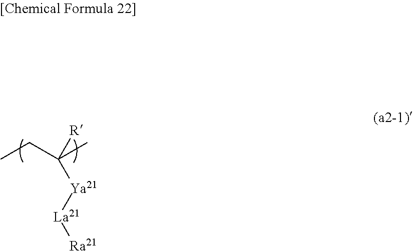

In the formula, R′ represents a hydrogen atom, an alkyl group of 1 to 5 carbon atoms, a halogenated alkyl group of 1 to 5 carbon atoms, a hydroxyalkyl group, an alkoxy group; Ya²¹ represents a single bond or a divalent linking group; La²¹ represents —O—, —COO—, —CON(R′)—, —OCO—, —CONHCO— or —CONHCS—; and R′ represents a hydrogen atom or a methyl group, provided that, when La²¹ represents —O—, Ya²¹ does not represent —CO—; and Ra²¹ represents an —SO₂— containing cyclic group, a lactone-containing cyclic group, a carbonate-containing cyclic group or any other heterocyclic group.

In formula (a2-1)′, Ra²¹ is preferably an —SO₂— containing cyclic group, a lactone-containing cyclic group, a heterocyclic group or a carbonate-containing cyclic group.

An “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂-containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable. More specific examples of the —SO₂— containing cyclic group include groups represented by general formulae (a5-r-1)′ to (a5-r-4)′ shown below.

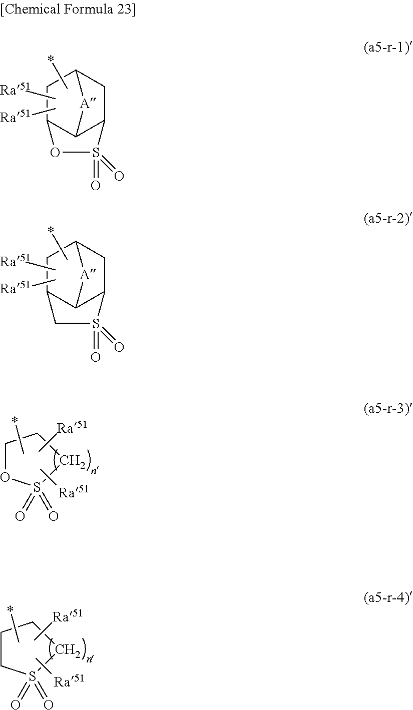

In the formulae, each Ra′⁵¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; and n′ represents an integer of 0 to 2; and * indicates the bonding site.

In general formulae (a5-r-1)′ to (a5-r-4)′, A″ is the same as defined for A″ in general formulae (a2-r-1)′ to (a2-r-7)′ described later. The alkyl group, alkoxy group, halogen atom, halogenated alkyl group, —COOR″, —OC(═O)R″ and hydroxyalkyl group for Ra′⁵¹ are the same as defined for Ra′²¹ in general formulae (a2-r-1)′ to (a2-r-7)′ described later.

Specific examples of the groups represented by the aforementioned general formulae (a5-r-1)′ to (a5-r-4)′ are shown below. In the formulae shown below, “Ac” represents an acetyl group. * indicates a bonding site.

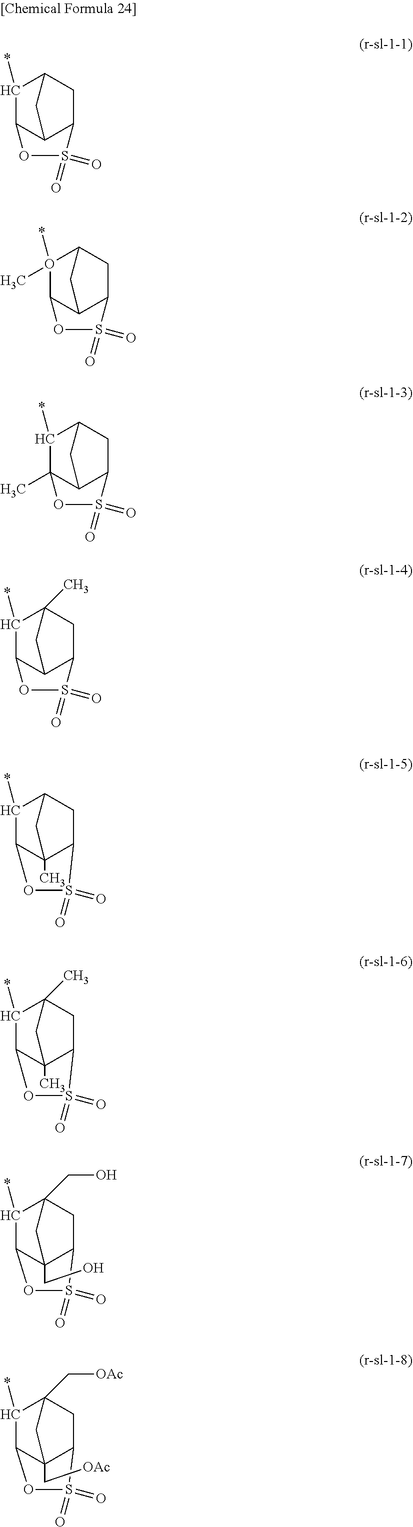

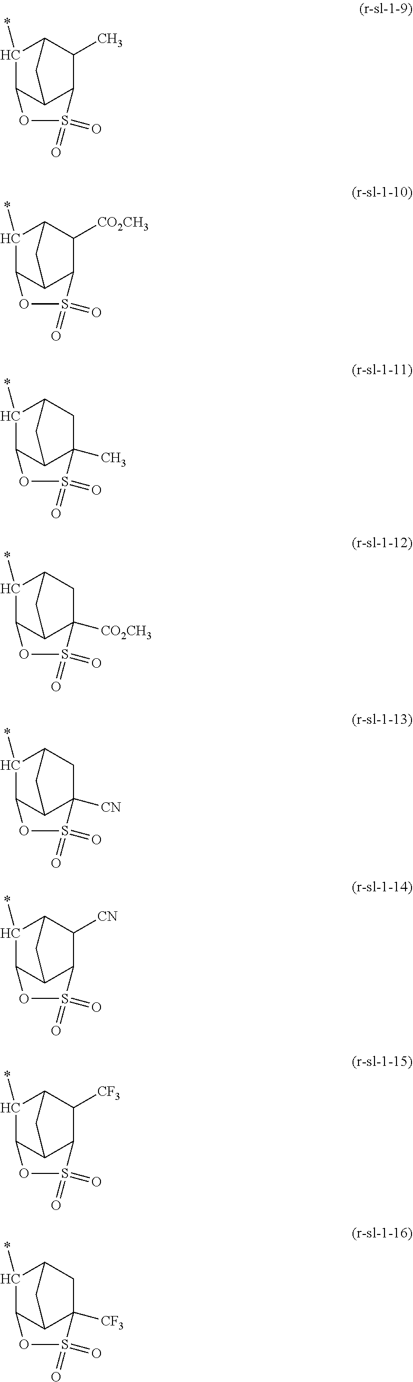

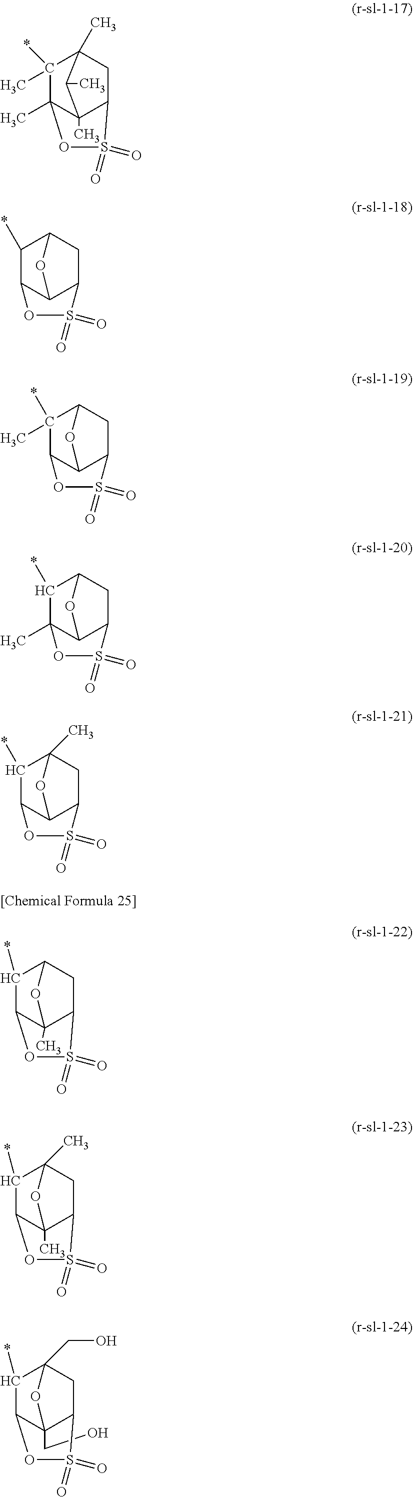

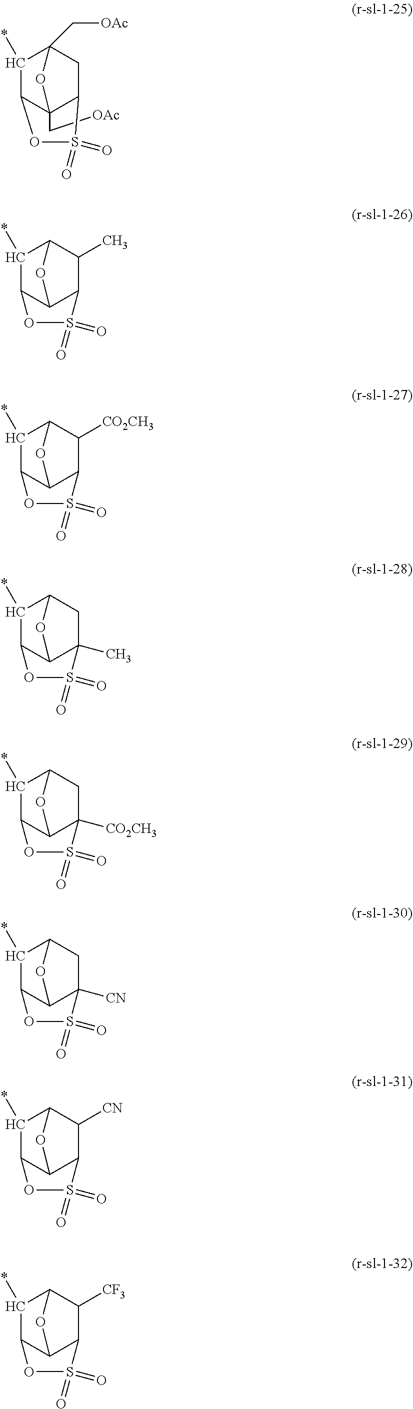

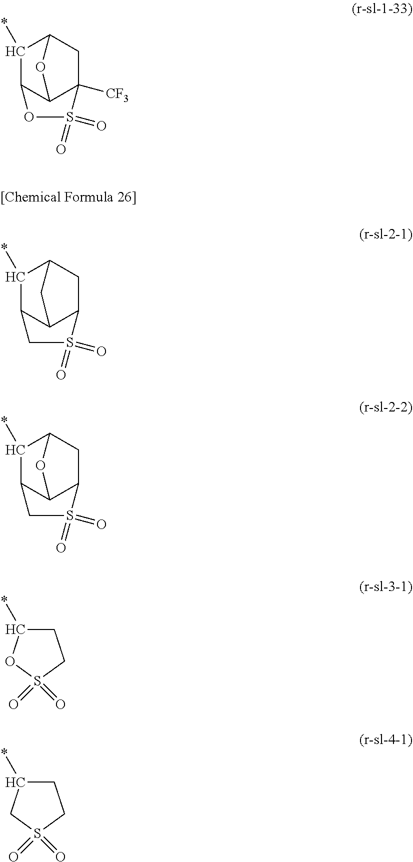

In the preset embodiment, in the case where the structural unit (a2)′ contains an —SO₂— containing cyclic group, the —SO₂— containing cyclic group is not particularly limited as long as the acrylate ester monomer containing the —SO₂— containing cyclic group exhibits a log P value of less than 1.2. Among the above examples, a group represented by the aforementioned formula (a5-r-1)′ is preferable, at least one member selected from the group consisting of the aforementioned formulae (r-s1-1-1), (r-s1-1-18), (r-s1-3-1) and (r-s1-4-1) is more preferable, and a group represented by the aforementioned formula (r-s1-1-1) is most preferable.

The term “lactone-containing cyclic group” refers to a cyclic group including a ring containing a —O—C(═O)— structure (lactone ring). The term “lactone ring” refers to a single ring containing a —O—C(O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

As the lactone-containing cyclic group, there is no particular limitation, and an arbitrary group may be used. Specific examples include groups represented by general formulas (a2-r-1)′ to (a2-r-7)′ shown below. * indicates a bonding site.

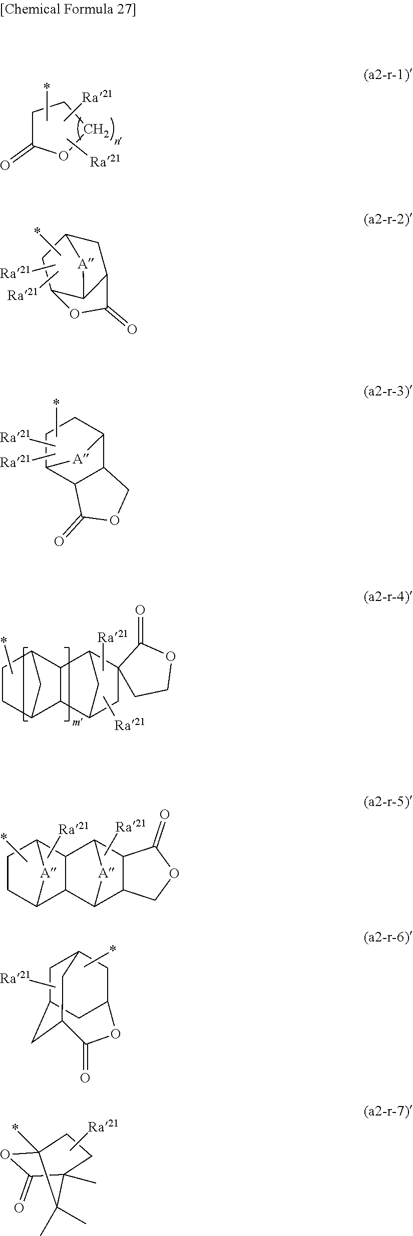

In the formulae, each Ra′²¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; n′ represents an integer of 0 to 2; and m′ represents 0 or 1.

In general formulae (a2-r-1)′ to (a2-r-7)′ above, A″ represents an oxygen atom (—O—), a sulfur atom (—S—) or an alkylene group of 1 to 5 carbon atoms which may contain an oxygen atom or a sulfur atom. As the alkylene group of 1 to 5 carbon atoms for A″, a linear or branched alkylene group is preferable, and examples thereof include a methylene group, an ethylene group, an n-propylene group and an isopropylene group. Examples of alkylene groups that contain an oxygen atom or a sulfur atom include the aforementioned alkylene groups in which —O— or —S— is bonded to the terminal of the alkylene group or present between the carbon atoms of the alkylene group. Specific examples of such alkylene groups include —O—CH₂—, —CH₂—O—CH₂—, —S—CH₂— and —CH₂—S—CH₂—. As A″, an alkylene group of 1 to 5 carbon atoms or —O— is preferable, more preferably an alkylene group of 1 to 5 carbon atoms, and most preferably a methylene group. Each Ra′²¹ independently represents an alkyl group, an alkoxy group, a halogen atom, a halogenated alkyl group, —COOR″, —OC(═O)R″, a hydroxyalkyl group or a cyano group.

The alkyl group for Ra′²¹ is preferably an alkyl group of 1 to 5 carbon atoms.

The alkoxy group for Ra′²¹ is preferably an alkoxy group of 1 to 5 carbon atoms. The alkoxy group is preferably a linear or branched alkoxy group. Specific examples of the alkoxy groups include the aforementioned alkyl groups for Ra′²¹ having an oxygen atom (—O—) bonded thereto.

As examples of the halogen atom for Ra′²¹, a fluorine atom, chlorine atom, bromine atom and iodine atom can be given. Among these, a fluorine atom is preferable.

Examples of the halogenated alkyl group for Ra′²¹ include groups in which part or all of the hydrogen atoms within the aforementioned alkyl group for Ra′²¹ has been substituted with the aforementioned halogen atoms. As the halogenated alkyl group, a fluorinated alkyl group is preferable, and a perfluoroalkyl group is particularly desirable.

Specific examples of the groups represented by the aforementioned general formulae (a2-r-1)′ to (a2-r-7)′ are shown below. * indicates a bonding site.

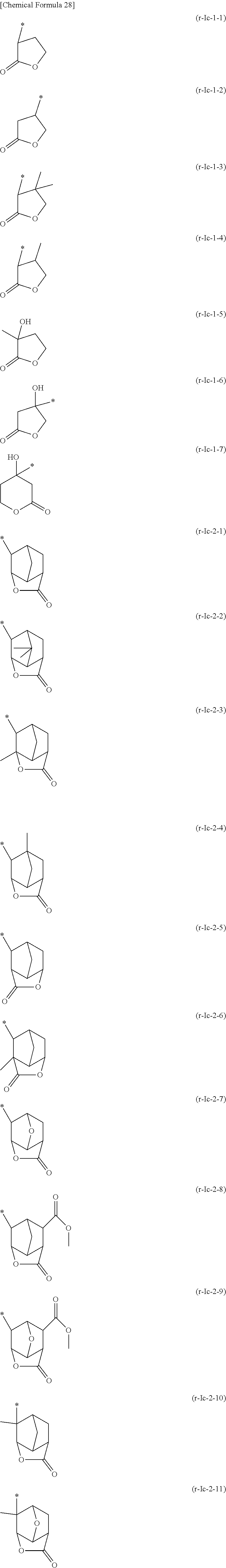

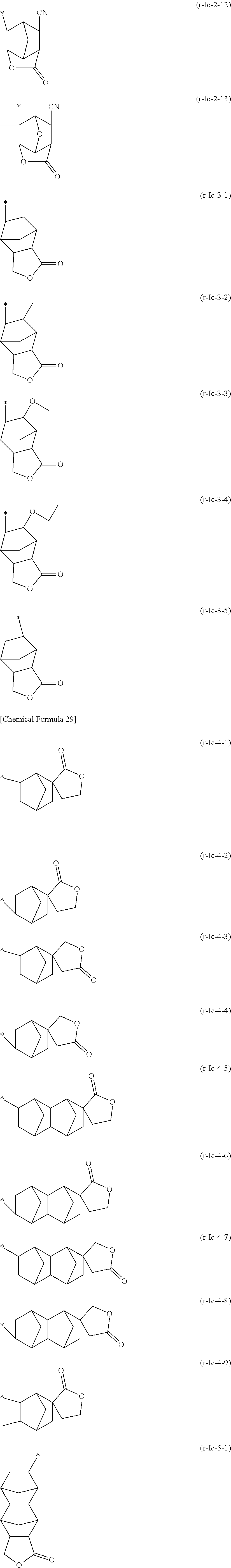

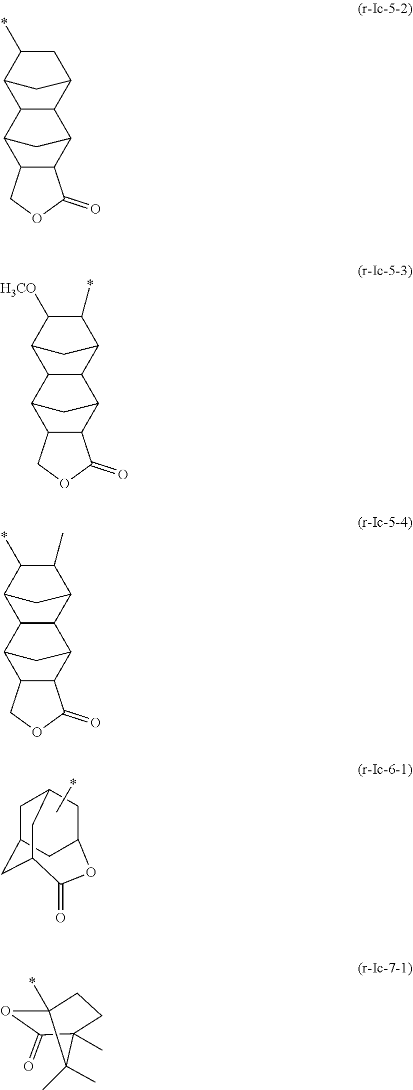

In the present embodiment, the structural unit (a2)′ preferably has a group represented by the aforementioned formula (a2-r-1)′ or (a2-r-2)′, and more preferably a group represented by the aforementioned chemical formula (r-1c-1-1)′ or (r-1c-2-7)′.

The term “carbonate-containing cyclic group” refers to a cyclic group including a ring containing a —O—C(═O)—O— structure (carbonate ring). The term “carbonate ring” refers to a single ring containing a —O—C(═O)—O— structure, and this ring is counted as the first ring. A carbonate-containing cyclic group in which the only ring structure is the carbonate ring is referred to as a monocyclic group, and groups containing other ring structures are described as polycyclic groups regardless of the structure of the other rings. The carbonate-containing cyclic group may be either a monocyclic group or a polycyclic group.

Specific examples include groups represented by general formulas (ax3-r-1)′ to (ax3-r-3)′ shown below. * indicates a bonding site.

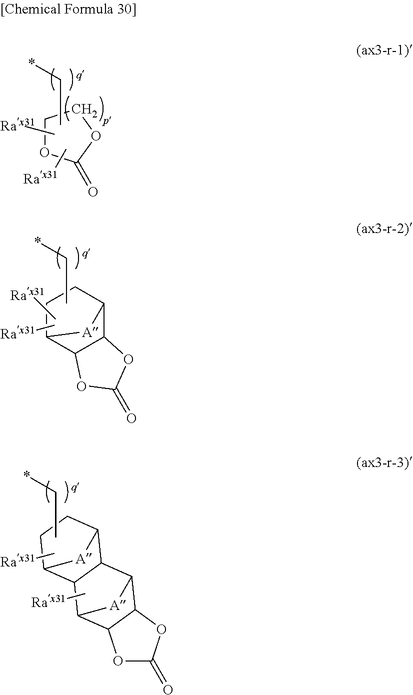

In the formulae, each Ra′^{x31} independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; and q′ represents 0 or 1.

In general formulae (ax3-r-1)′ to (ax3-r-3)′, specific examples of A″ is the same as defined for A″ in general formulae (a2-r-1)′ to (a2-r-7)′. Examples of the alkyl group, alkoxy group, halogen atom, halogenated alkyl group, —COOR″, —OC(═O)R″ and hydroxyalkyl group for Ra′^{x31} include the same groups as those described above in the explanation of Ra′²¹ in the general formulas (a2-r-1) to (a2-r-7).

Specific examples of the groups represented by the aforementioned general formulae (ax3-r-1)′ to (ax3-r-3)′ are shown below. * indicates a bonding site.

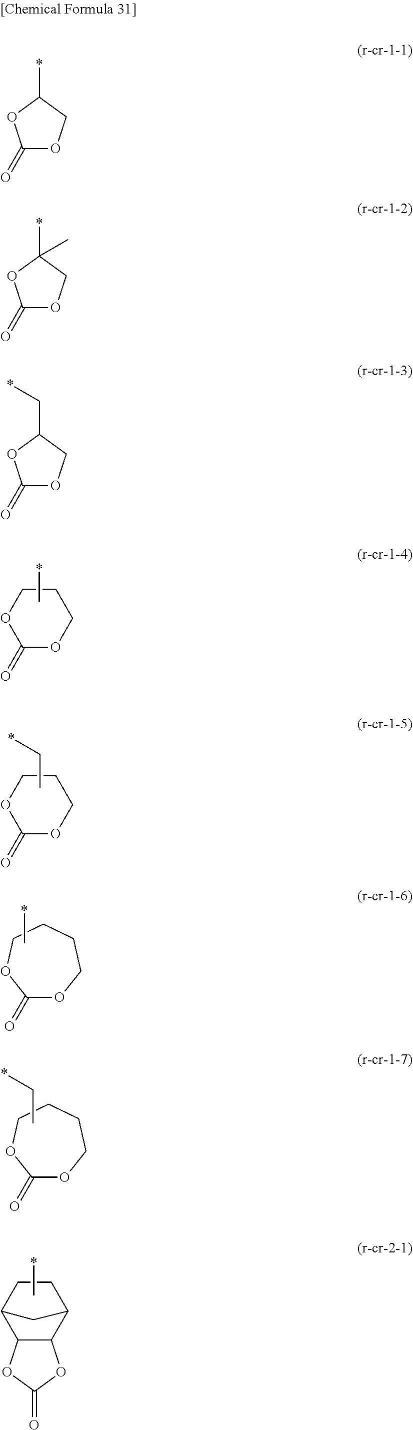

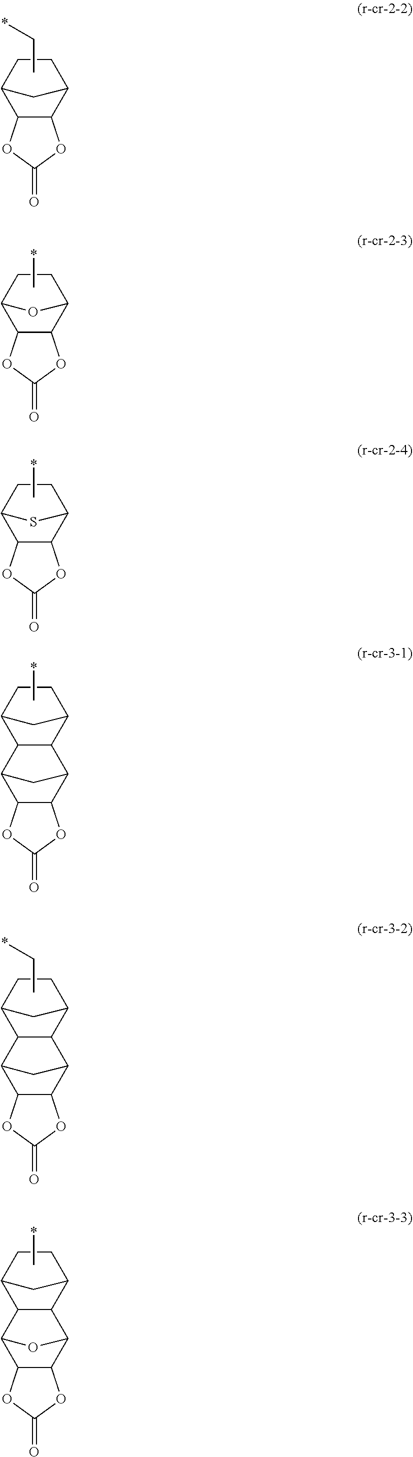

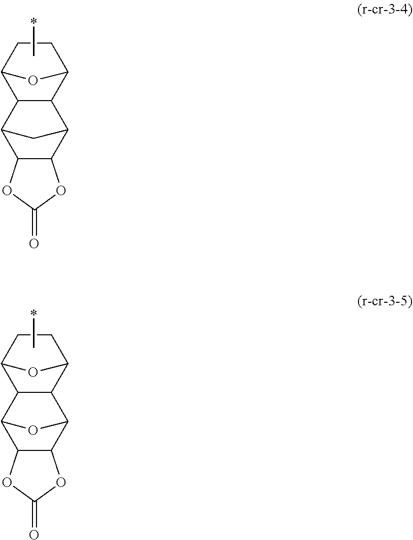

A “heterocyclic group” refers to a cyclic group containing, in addition to carbon, 1 or more atoms other than carbon. Examples of the heterocyclic group include heterocyclic groups represented by the aforementioned formulae (r-hr-1) to (r-hr-16) and nitrogen-containing heterocyclic groups. Examples of the nitrogen-containing heterocyclic groups include cycloalkyl groups of 3 to 8 carbon atoms which may be substituted with 1 or 2 oxo groups. Preferable examples of the cycloalkyl group include 2,5-dioxopyrrolidine and 2,6-dioxopiperidine. * indicates a bonding site.

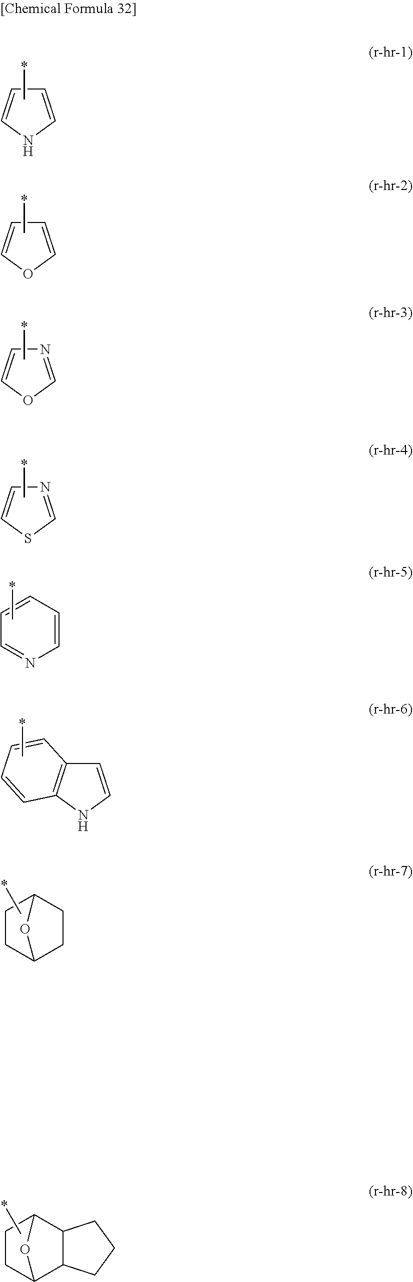

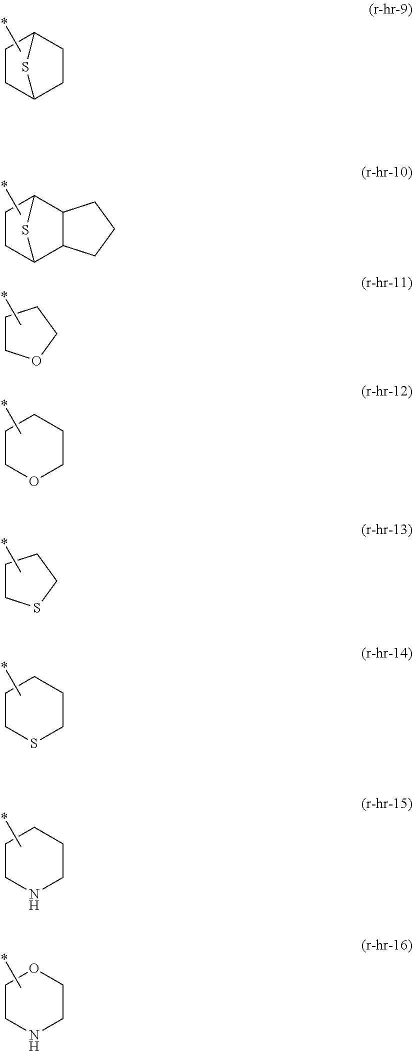

Specific examples of structural unit (a2)′ having a lactone-containing cyclic group are shown below. In the formulae shown below, R^{α} represents a hydrogen atom, a methyl group or a trifluoromethyl group.

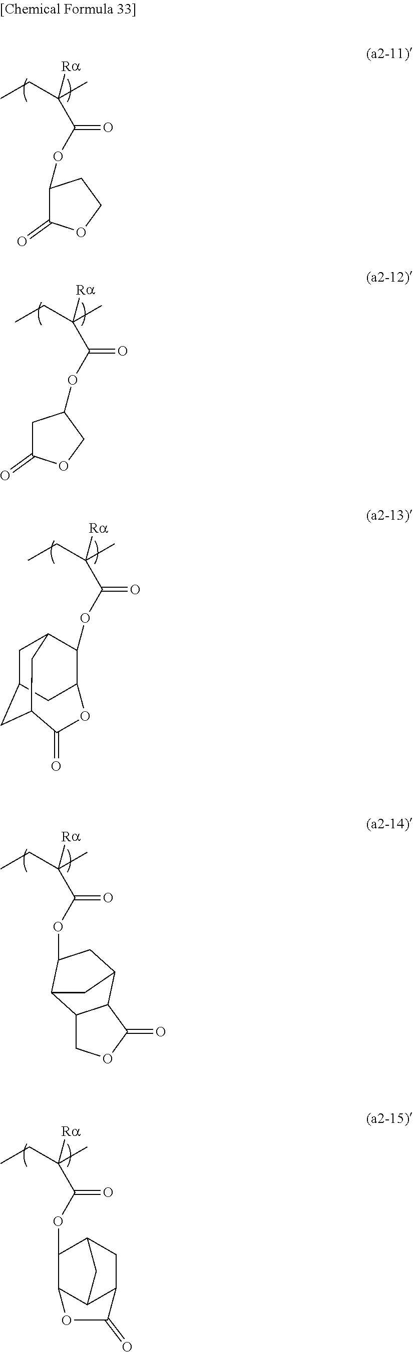

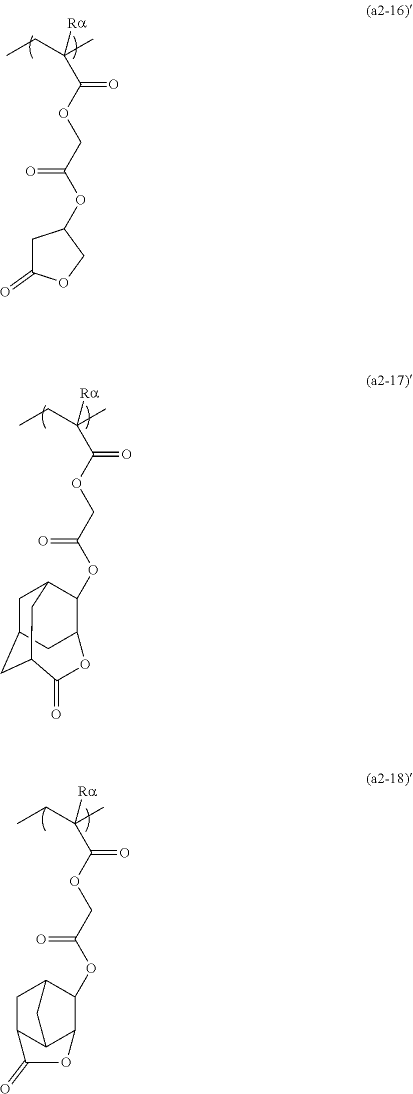

As the structural unit (a2)′ contained in the component (A2), 1 kind of structural unit may be used, or 2 or more kinds of structural units may be used.

When the component (A2) contains the structural unit (a2)′, the amount of the structural unit (a2)′ based on the combined total of all structural units constituting the component (A2) is preferably 1 to 80 mol %, more preferably 5 to 70 mol %, still more preferably 10 to 65 mol %, and most preferably 10 to 60 mol %. When the amount of the structural unit (a2)′ is at least as large as the lower limit of the above-mentioned range, the effect of using the structural unit (a2)′ may be satisfactorily achieved. On the other hand, when the amount of the structural unit (a2)′ is no more than the upper limit of the above-mentioned range, a good balance may be achieved with the other structural units, and various lithography properties and pattern shape may be improved.

(Structural Unit (a3)′)

The structural unit (a3)′ is a structural unit containing a polar group-containing aliphatic hydrocarbon group (provided that the structural units that fall under the definition of structural units (a1)′ and (a2)′ are excluded).

When the component (A2) includes the structural unit (a3)′, it is presumed that the hydrophilicity of the component (A2) is enhanced, thereby contributing to improvement in resolution.

Examples of the polar group include a hydroxyl group, cyano group, carboxyl group, or hydroxyalkyl group in which part of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and cyclic aliphatic hydrocarbon groups (cyclic groups). These cyclic groups can be selected appropriately from the multitude of groups that have been proposed for the resins of photoresist compositions designed for use with ArF excimer lasers. The cyclic group is preferably a polycyclic group, more preferably a polycyclic group of 7 to 30 carbon atoms.

Of the various possibilities, structural units derived from an acrylate ester that include an aliphatic polycyclic group that contains a hydroxyl group, cyano group, carboxyl group or a hydroxyalkyl group in which part of the hydrogen atoms of the alkyl group have been substituted with fluorine atoms are particularly desirable. Examples of polycyclic groups include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

As the structural unit (a3)′, there is no particular limitation as long as it is a structural unit containing a polar group-containing aliphatic hydrocarbon group, and an arbitrary structural unit may be used.

The structural unit (a3)′ is preferably a structural unit derived from an acrylate ester which may have the hydrogen atom bonded to the carbon atom on the α-position substituted with a substituent and contains a polar group-containing aliphatic hydrocarbon group.

When the aliphatic hydrocarbon group within the polar group-containing aliphatic hydrocarbon group is a linear or branched hydrocarbon group of 1 to 10 carbon atoms, the structural unit (a3)′ is preferably a structural unit derived from a hydroxyethyl ester of acrylic acid. On the other hand, when the hydrocarbon group is a polycyclic group, a structural unit represented by any one of formulae (a3-1)′ to (a3-5)′ shown below are preferable, and a structural unit represented by formula (a3-1)′ shown below is more preferable.

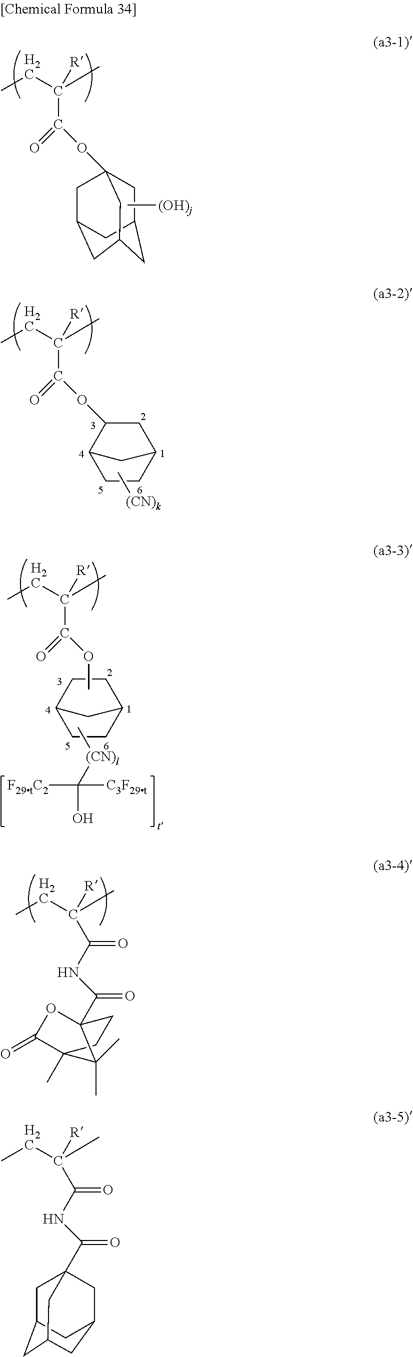

In the formulas, R′ is the same as defined above; j is an integer of 1 to 3; k is an integer of 1 to 3; t′ is an integer of 1 to 3; 1 is an integer of 1 to 5; and s is an integer of 1 to 3.

In formula (a3-1)′, j is preferably 1 or 2, and more preferably 1. When j is 2, it is preferable that the hydroxyl groups be bonded to the 3rd and 5th positions of the adamantyl group. When j is 1, it is preferable that the hydroxyl group be bonded to the 3rd position of the adamantyl group.

j is preferably 1, and it is particularly desirable that the hydroxyl group be bonded to the 3rd position of the adamantyl group.

In formula (a3-2)′, k is preferably 1. The cyano group is preferably bonded to the 5th or 6th position of the norbornyl group.

In formula (a3-3)′, t′ is preferably 1. l is preferably 1. s is preferably 1. Further, it is preferable that a 2-norbornyl group or 3-norbornyl group be bonded to the terminal of the carboxy group of the acrylic acid. The fluorinated alkyl alcohol is preferably bonded to the 5th or 6th position of the norbornyl group.

As the structural unit (a3)′ contained in the component (A2), 1 kind of structural unit may be used, or 2 or more kinds of structural units may be used.

The amount of the structural unit (a3)′ within the component (A2) based on the combined total of all structural units constituting the component (A2) is preferably 5 to 50 mol %, more preferably 5 to 40 mol %, and still more preferably 5 to 25 mol %.

When the amount of the structural unit (a3)′ is at least as large as the lower limit of the above-mentioned range, the effect of using the structural unit (a3)′ may be satisfactorily achieved. On the other hand, when the amount of the structural unit (a3)′ is no more than the upper limit of the above preferable range, a good balance may be achieved with the other structural units.

The component (A2) may also include a structural unit (a4)′ which is other than the above-mentioned structural units (a1)′, (a2)′ and (a3)′.

(Structural Unit (a4)′)

The structural unit (a4)′ is a structural unit containing an acid non-dissociable cyclic group. When the component (A2) includes the structural unit (a4)′, dry etching resistance of the resist pattern to be formed is improved. Further, the hydrophobicity of the component (A2) may be further improved. Particularly in an organic solvent developing process, it is considered that the increase in the hydrophobicity contributes to improvement in resolution, shape of the photoresist pattern, and the like.

An “acid non-dissociable, aliphatic cyclic group” in the structural unit (a4)′ refers to a cyclic group which is not dissociated by the action of the acid (e.g., acid generated from a structural unit which generates acid upon exposure or acid generated from the component (B)) upon exposure, and remains in the structural unit.

As the structural unit (a4)′, a structural unit which contains a non-acid-dissociable aliphatic cyclic group, and is also derived from an acrylate ester is preferable. As the cyclic group, those exemplified above in the structural unit (a1)′ may be used, and any of the multitude of conventional polycyclic groups used within the resin component of photoresist compositions for ArF excimer lasers or KrF excimer lasers (and particularly for ArF excimer lasers) may be used.

As the aliphatic polycyclic group, at least one member selected from amongst a tricyclodecyl group, an adamantyl group, a tetracyclododecyl group, an isobornyl group, and a norbornyl group is particularly desirable in consideration of industrial availability and the like. These polycyclic groups may be substituted with a linear or branched alkyl group of 1 to 5 carbon atoms.

Specific examples of the structural unit (a4)′ include units with structures represented by general formulas (a4-1)′ to (a4-7)′ shown below.

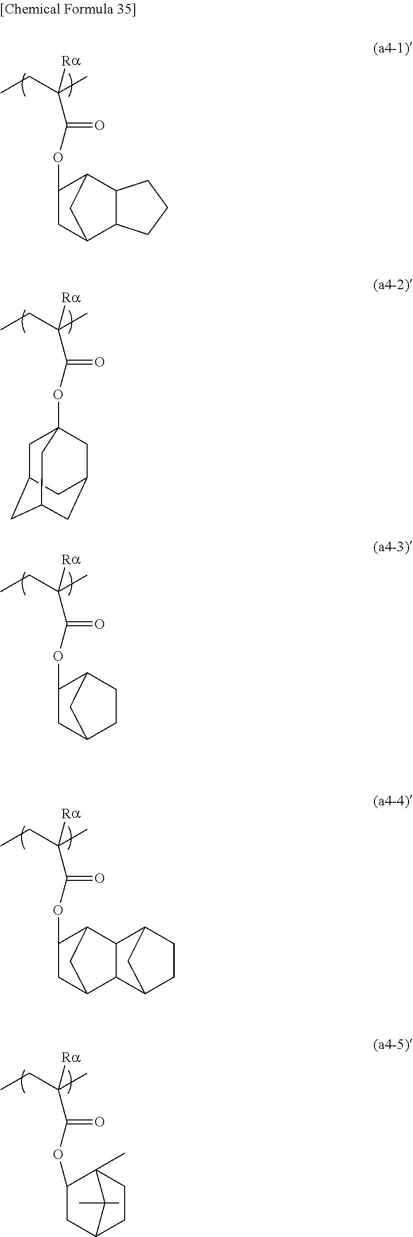

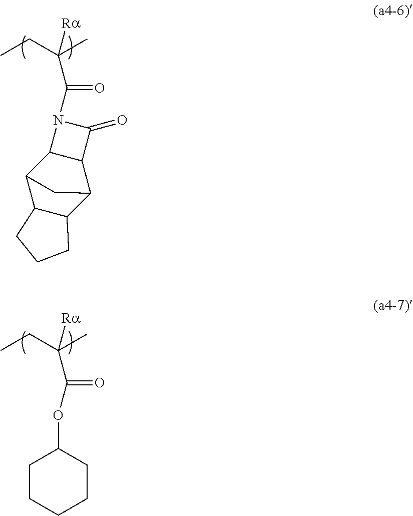

In the formulae, R^{α} represents a hydrogen atom, a methyl group or a trifluoromethyl group.

As the structural unit (a4)′ contained in the component (A2), 1 kind of structural unit may be used, or 2 or more kinds of structural units may be used.

When the structural unit (a4)′ is included in the component (A2), the amount of the structural unit (a4)′ based on the combined total of all the structural units that constitute the component (A2) is preferably within the range from 1 to 30 mol %, and more preferably from 10 to 20 mol %.

The component (A2) is preferably a copolymer having the structural units (a1)′, (a2)′ and (a3)′.

The component (A2) may be obtained, for example, by a conventional radical polymerization or the like of the monomers corresponding with each of the structural units, using a radical polymerization initiator such as azobisisobutyronitrile (AIBN) or dimethyl 2,2′-azobis(isobutyrate).

In the polymerization of the component (A2), a chain transfer agent such as HS—CH₂—CH₂—CH₂—C(CF₃)₂—OH may be used to introduce a —C(CF₃)₂—OH group at the terminal(s) of the polymer. Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

In the present invention, the weight average molecular weight (Mw) (the polystyrene equivalent value determined by gel permeation chromatography) of the component (A2) is not particularly limited, but is preferably 1,000 to 50,000, more preferably 1,500 to 30,000, and most preferably 2,000 to 20,000. When the Mw of the component (A2) is no more than the upper limit of the above-mentioned range, the photoresist composition exhibits a satisfactory solubility in a photoresist solvent. On the other hand, when the Mw of the component (A2) is at least as large as the lower limit of the above-mentioned range, dry etching resistance and the cross-sectional shape of the resist pattern becomes satisfactory.

As the component (A2), one type may be used alone, or two or more types may be used in combination.

In the component (A), the amount of the component (A2) based on the total weight of the component (A) is preferably 25% by weight or more, more preferably 50% by weight or more, still more preferably 75% by weight or more, and may be even 100% by weight. When the amount of the component (A2) is 25% by weight or more, various lithography properties are improved.

[Resin (A3)]

In the present embodiment, as the component (A) of the photoresist composition, a resin (A3) (hereafter, sometimes referred to as “component (A3)”) having a structural unit derived from a novolak resin may be used. The novolak resin is not particularly limited and is arbitrarily selected from those conventionally proposed as those which can be usually used in photoresist compositions. Preferable examples thereof include a novolak resin obtained by subjecting an aromatic hydroxy compound and an aldehyde and/or ketone to a condensation reaction.

Examples of aromatic hydroxy compounds usable in the synthesis of a novolak resin include phenol; cresols such as m-cresol, p-cresol and o-cresol; xylenols such as 2,3-xylenol, 2,5-xylenol, 3,5-xylenol and 3,4-xylenol; alkylphenols such as m-ethylphenol, p-ethylphenol, o-ethylphenol, 2,3,5-trimethylphenol, 2,3,5-triethylphenol, 4-tert-butylphenol, 3-tert-butylphenol, 2-tert-butylphenol, 2-tert-butyl-4-methylphenol, and 2-tert-butyl-5-methylphenol; alkoxyphenols such as p-methoxyphenol, m-methoxyphenol, p-ethoxyphenol, m-ethoxyphenol, p-propoxyphenol and m-propoxyphenol; isopropenylphenols such as o-isopropenylphenol, p-isopropenylphenol, 2-methyl-4-isopropenylphenol, and 2-ethyl-4-isopropenylphenol; arylphenols, such as phenylphenol; polyhydroxyphenols such as 4,4′-dihydroxybiphenyl, bisphenol A, resorcinol, hydroquinone and pyrogallol. These compounds can be used either alone, or in combinations of two or more different compounds.

Examples of aldehydes usable in the synthesis of a novolak resin include formaldehyde, paraformaldehyde, trioxane, acetaldehyde, propionaldehyde, butyraldehyde, trimethylacetaldehyde, acrolein, crotonaldehyde, cyclohexanaldehyde, furfural, furylacrolein, benzaldehyde, terephthalaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-methylbenzaldehyde, m-methylbenzaldehyde, p-methylbenzaldehyde, o-chlorobenzaldehyde, m-chlorobenzaldehyde, p-chlorobenzaldehyde, and cinnamic aldehyde. These compounds can be used either alone, or in combinations of two or more different compounds.

Of these aldehydes, formaldehyde is preferably used in terms of availability. In particular, in terms of heat resistance, it is preferable to use a combination of formaldehyde with a hydroxybenzaldehydes such as o-hydroxybenzaldehyde, m-hydroxybenzaldehyde or p-hydroxybenzaldehyde.

Examples of ketones usable in the synthesis of a novolak resin include acetone, methyl ethyl ketone, diethyl ketone, and diphenyl ketone. These compounds can be used either alone, or in combinations of two or more different compounds.

Further, any of the aforementioned aldehydes may be used in combination with any of the ketones. A novolak resin may be produced by subjecting the aromatic hydroxy compound and aldehydes and/or ketones to condensation reaction by a conventional method in the presence of an acidic catalyst. As the acidic catalyst, hydrochloric acid, sulfuric acid, formic acid, oxalic acid, paratoluenesulfonic acid, or the like may be used.

The weight average molecular weight (Mw) (the polystyrene equivalent value determined by gel permeation chromatography (GPC)) of the novolak resin, i.e., the component (A3) prior to being protected with acid dissociable dissolution inhibiting groups is preferably 2,000 to 50,000, more preferably 3,000 to 20,000, and still more preferably 4,000 to 15,000. When the weight average molecular weight is 2,000 or more, the coatability when the resin is dissolved in a solvent and coated on the support is good, and when it is 50,000 or less, the resolution is good.

In the present embodiment, it is preferable that the novolak resin has been subjected to a treatment for separating and removing low molecular weight substances. By such treatment, the heat resistance may be further improved.

Here, the low-molecular weight substance in the present specification includes, for example, among the monomers such as aromatic hydroxy compounds, aldehydes, and ketones used in the synthesis of the novolak resin, residual monomers remaining without being reacted, a dimer in which two molecules of the monomers are bonded, a trimer having three molecules bonded are included.

The method for fractionating the low molecular weight substance is not particularly limited, and for example, a method of purifying using an ion exchange resin, or a conventional method using a good solvent (alcohol or the like) and a poor solvent (water or he like) for the resin may be used. According to the former method, it is possible to remove the acid component and the metal component together with the low molecular weight substance.

The yield in the fractional removal treatment of such low molecular weight substances is preferably in the range of 50 to 95% by mass.

When the yield is 50% by mass or more, the difference in the dissolution rate between the exposed portions and the unexposed portions becomes large, and the resolution becomes satisfactory. On the other hand, when the yield is 95% by mass or less, the effect of conducting the fractional removal treatment may be satisfactorily achieved.

Further, the content of the low molecular weight substance having a weight average molecular weight of 500 or less is preferably 15% or less, more preferably 12% or less on the GPC chart. When the content is 15% or less, the effect of improving the heat resistance of the photoresist pattern is achieved, and also the effect of suppressing the amount of sublimate generated during the heat treatment is achieved.

In the component (A), the amount of the component (A3) based on the total weight of the component (A) is preferably 25% by weight or more, more preferably 50% by weight or more, still more preferably 75% by weight or more, and may be even 100% by weight. When the amount of the component (A3) is 25% by weight or more, various lithography properties are improved.

In the photoresist composition of the present invention, as the component (A), one type may be used, or two or more types of compounds may be used in combination.

In the photoresist composition according to the present embodiment, the component (A) preferably includes at least one member selected from the group consisting of the component (A1), the component (A2) and the component (A3), and more preferably the component (A1).

In the photoresist composition according to the present embodiment, the amount of the component (A) may be appropriately adjusted depending on the required properties of the photoresist to be formed, but the amount of the component (A) relative to 100 parts by weight of the component (S) described later is preferably 20 to 100 parts by weight, more preferably 40 to 80 parts by weight, and still more preferably 50 to 70 parts by weight.

<Acid Generator (B)>

The photoresist composition of the present embodiment may include, in addition to the component (A), an acid-generator component (hereafter, sometimes referred to as “component (B)”).

As the component (B), there is no particular limitation, and any of the known acid generators used in conventional photoresist compositions may be used.

Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators. Among these examples, it is preferable to use an onium salt acid generator.

As the onium salt acid generator, a compound represented by general formula (b-1) below (hereafter, sometimes referred to as “component (b-1)”), a compound represented by general formula (b-2) below (hereafter, sometimes referred to as “component (b-2)”) or a compound represented by general formula (b-3) below (hereafter, sometimes referred to as “component (b-3)”) may be mentioned.

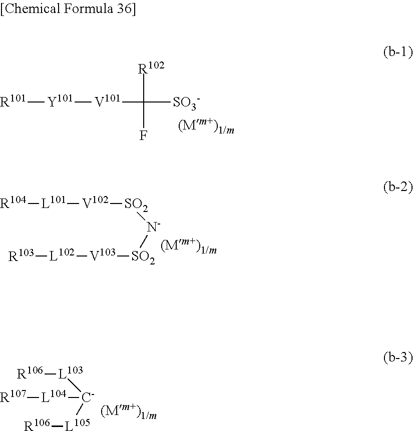

In the formulae, R¹⁰¹ and R¹⁰⁴ to R¹⁰⁸ each independently represents a halogen atom, a cyclic group which may have a substituent, a chain-like alkyl group which may have a substituent or a chain-like alkenyl group which may have a substituent, provided that R¹⁰⁴ and R¹⁰⁵ may be mutually bonded to form a ring; R¹⁰² represents a fluorine atom or a fluorinated alkyl group of 1 to 5 carbon atoms; Y¹⁰¹ represents a single bond or a divalent linking group containing an oxygen atom; V¹⁰¹ to V¹⁰³ each independently represents a single bond, an alkylene group or a fluorinated alkylene group; L¹⁰¹ and L¹⁰² each independently represents a single bond or an oxygen atom; L¹⁰³ to L¹⁰⁵ each independently represents a single bond, —CO— or —SO₂—; m represents an integer of 1 or more, and M′^{m+} represents an onium cation having a valency of m.

{Anion Moiety}

Anion Moiety of Component (b-1)

In the formula (b-1), R¹⁰¹ represents a halogen atom, a cyclic group which may have a substituent, a chain-like alkyl group which may have a substituent or a chain-like alkenyl group which may have a substituent.

Examples of the halogen atom include a fluorine atom, a chlorine atom, a bromine atom and an iodine atom, and a fluorine atom is preferable.

Cyclic group which may have a substituent:

The cyclic group is preferably a cyclic hydrocarbon group, and the cyclic hydrocarbon group may be either an aromatic hydrocarbon group or an aliphatic hydrocarbon group. An “aliphatic hydrocarbon group” refers to a hydrocarbon group that has no aromaticity. The aliphatic hydrocarbon group may be either saturated or unsaturated, but in general, the aliphatic hydrocarbon group is preferably saturated.

The aromatic hydrocarbon group for R¹⁰¹ is a hydrocarbon group having an aromatic ring. The aromatic hydrocarbon ring preferably has 3 to 30 carbon atoms, more preferably 5 to 30, still more preferably 5 to 20, still more preferably 6 to 15, and most preferably 6 to 10. Here, the number of carbon atoms within a substituent(s) is not included in the number of carbon atoms of the aromatic hydrocarbon group.

Specific examples of the aromatic ring contained in the aromatic hydrocarbon group for R¹⁰¹ include benzene, fluorene, naphthalene, anthracene, phenanthrene, biphenyl, or an aromatic hetero ring in which part of the carbon atoms constituting any one of these aromatic rings have been substituted with a hetero atom. Examples of the hetero atom within the aromatic hetero rings include an oxygen atom, a sulfur atom and a nitrogen atom.

Specific examples of the aromatic hydrocarbon group represented by R¹⁰¹ include a group in which one hydrogen atom has been removed from the aforementioned aromatic ring (i.e., an aryl group, such as a phenyl group or a naphthyl group), and a group in which one hydrogen of the aforementioned aromatic ring has been substituted with an alkylene group (e.g., an arylalkyl group such as a benzyl group, a phenethyl group, a 1-naphthylmethyl group, a 2-naphthylmethyl group, a 1-naphthylethyl group or a 2-naphthylethyl group). The alkylene group (alkyl chain within the arylalkyl group) preferably has 1 to 4 carbon atom, more preferably 1 or 2, and most preferably 1.

Examples of the cyclic aliphatic hydrocarbon group for R¹⁰¹ include aliphatic hydrocarbon groups containing a ring in the structure thereof.

Examples of the aliphatic hydrocarbon group containing a ring in the structure thereof include an alicyclic hydrocarbon group (a group in which 1 hydrogen atom has been removed from an aliphatic hydrocarbon ring); a group in which an alicyclic hydrocarbon group is bonded to a terminal of a linear or branched aliphatic hydrocarbon group; and a group in which an alicyclic hydrocarbon group is present between carbon atoms of a linear or branched aliphatic hydrocarbon group.

The alicyclic hydrocarbon group preferably has 3 to 20 carbon atoms, and more preferably 3 to 12 carbon atoms.

The alicyclic hydrocarbon group may be either a polycyclic group or a monocyclic group. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the polycyclic group preferably has 7 to 30 carbon atoms. Among polycycloalkanes, a polycycloalkane having a bridged ring polycyclic skeleton, such as adamantane, norbornane, isobornane, tricyclodecane or tetracyclodpdecane, and a polycycloalkane having a condensed ring polycyclic skeleton, such as a cyclic group having a steroid skeleton are preferable.

Among these examples, as the cyclic aliphatic hydrocarbon group for R¹⁰¹, a group in which one or more hydrogen atoms have been removed from a monocycloalkane or a polycycloalkane is preferable, a group in which one or more hydrogen atoms have been removed from a polycycloalkane is more preferable, an adamantyl group or a norbornyl group is still more preferable, and an adamantyl group is most preferable.

The linear or branched aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅].

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The cyclic hydrocarbon group for R¹⁰¹ may contain a hetero atom such as a heterocycle. Specific examples include lactone-containing cyclic groups represented by the aforementioned general formulae (a2-r-1)′ to (a2-r-7)′, the —SO₂— containing polycyclic groups represented by the aforementioned general formulae (a5-r-1)′ to (a5-r-2)′, and other heterocyclic groups represented by chemical formulae (r-hr-1)′ to (r-hr-16)′ shown below. * indicates a bonding site.

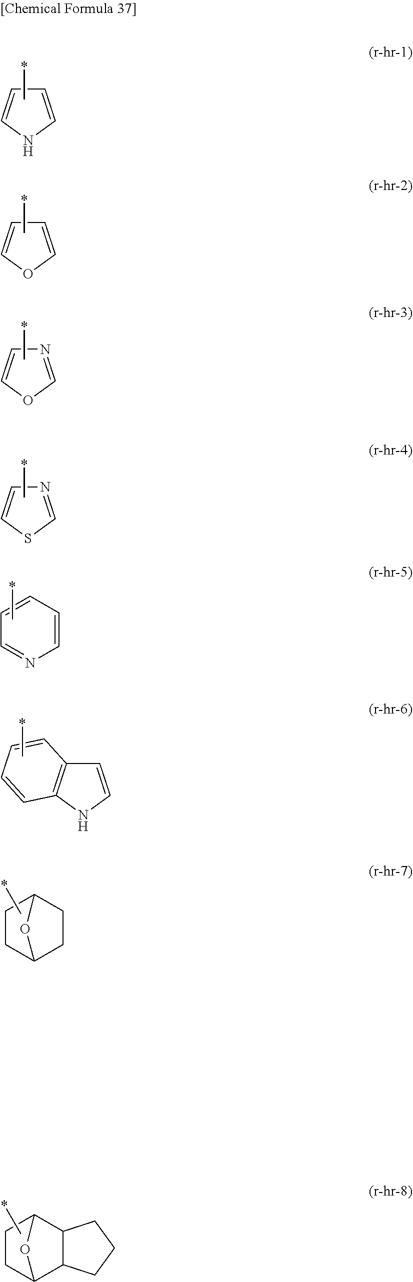

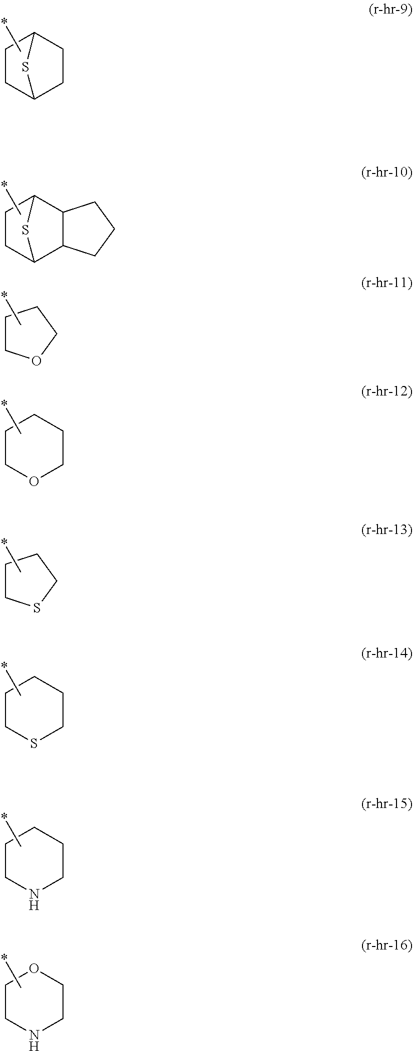

As the substituent for the cyclic group for R¹⁰¹, an alkyl group, an alkoxy group, a halogen atom, a halogenated alkyl group, a hydroxyl group, a carbonyl group, a nitro group or the like can be used.

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom for the substituent include a fluorine atom, a chlorine atom, a bromine atom and an iodine atom, and a fluorine atom is preferable.

Example of the aforementioned halogenated alkyl group includes a group in which a part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

The carbonyl group as the substituent is a group that substitutes a methylene group (—CH₂—) constituting the cyclic hydrocarbon group.

Chain alkyl group which may have a substituent:

The chain-like alkyl group for R¹⁰¹ may be linear or branched.

The linear alkyl group preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched alkyl group preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

Chain alkenyl group which may have a substituent:

The chain-like alkenyl group for R¹⁰¹ may be linear or branched, and preferably has 2 to 10 carbon atoms, more preferably 2 to 5 carbon atoms, still more preferably 2 to 4 carbon atoms, and most preferably 3 carbon atoms. Examples of linear alkenyl groups include a vinyl group, a propenyl group (an allyl group) and a butynyl group. Examples of branched alkenyl groups include a 1-methylvinyl group, a 2-methylvinyl group, a 1-methylpropenyl group and a 2-methylpropenyl group.

Among these examples, as the chain-like alkenyl group, a linear alkenyl group is preferable, a vinyl group or a propenyl group is more preferable, and a vinyl group is most preferable.

As the substituent for the chain-like alkyl group or alkenyl group for R¹⁰¹, an alkoxy group, a halogen atom, a halogenated alkyl group, a hydroxyl group, a carbonyl group, a nitro group, an amino group, a cyclic group for R¹⁰¹ or the like may be used.

Among these examples, R¹⁰¹ is preferably a cyclic group which may have a substituent or a chain-like alkyl group which may have a substituent, more preferably a cyclic group which may have a substituent, and still more preferably a cyclic hydrocarbon group which may have a substituent.

Among these examples, a phenyl group, a naphthyl group, a group in which one or more hydrogen atoms have been removed from a polycycloalkane, a lactone-containing cyclic group represented by any one of the aforementioned formulae (a2-r-1)′ to (a2-r-7)′, an —SO₂— containing polycyclic group represented by any one of the aforementioned general formulae (a5-r-1)′ and (a5-r-2)′ is preferable, and a group in which one or more hydrogen atoms have been removed from a polycycloalkane or an —SO₂— containing polycyclic group represented by any one of the aforementioned general formulae (a5-r-1)′ to (a5-r-2)′ is more preferable.

In formula (b-1), Y¹⁰¹ represents a single bond or a divalent linking group containing an oxygen atom.

In the case where Y¹⁰¹ is a divalent linking group containing an oxygen atom, Y¹⁰¹ may contain an atom other than an oxygen atom. Examples of atoms other than an oxygen atom include a carbon atom, a hydrogen atom, a sulfur atom and a nitrogen atom.

Examples of divalent linking groups containing an oxygen atom include non-hydrocarbon, oxygen atom-containing linking groups such as an oxygen atom (an ether bond; —O—), an ester bond (—C(═O)—O—), an oxycarbonyl group (—O—C(═O)—), an amido bond (—C(═O)—NH—), a carbonyl group (—C(═O)—) and a carbonate bond (—O—C(═O)—O—); and combinations of the aforementioned non-hydrocarbon, hetero atom-containing linking groups with an alkylene group. Furthermore, the combinations may have a sulfonyl group (—SO₂—) bonded thereto. Examples of the divalent linking group containing an oxygen atom include divalent linking groups represented by general formula (y-a1-1) to (y-a1-7) shown below.

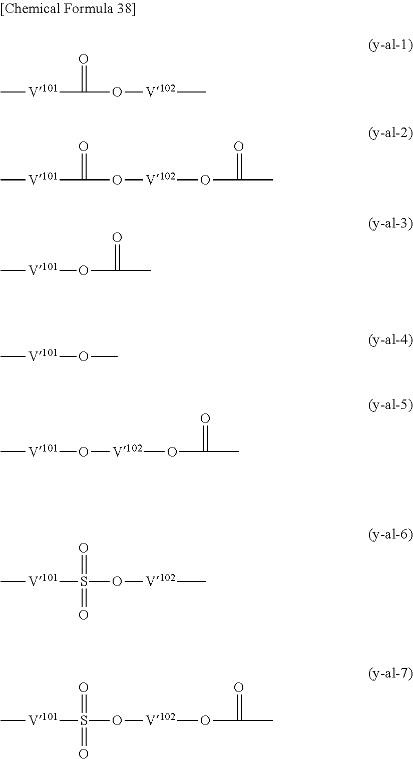

In the formulae, V′¹⁰¹ represents a single bond or an alkylene group of 1 to 5 carbon atoms; V′¹⁰² represents a divalent saturated hydrocarbon group of 1 to 30 carbon atoms.

The divalent saturated hydrocarbon group for V′¹⁰² is preferably an alkylene group of 1 to 30 carbon atoms, more preferably an alkylene group of 1 to 10 carbon atoms, and still more preferably an alkylene group of 1 to 5 carbon atoms.

The alkylene group for V′¹⁰¹ and V′¹⁰² may be a linear alkylene group or a branched alkylene group, and a linear alkylene group is preferable.

Specific examples of the alkylene group for V′¹⁰¹ and V′¹⁰² include a methylene group [—CH₂—]; an alkylmethylene group, such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group, such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group, such as —CH(CH₃)CH₂CH₂—, or —CH₂CH(CH₃)CH₂—; a tetramethylene group [—CH₂CH₂CH₂CH₂—]; an alkyltetramethylene group, such as —CH(CH₃)CH₂CH₂CH₂—, or —CH₂CH(CH₃)CH₂CH₂—; and a penamethylene group [—CH₂CH₂CH₂CH₂CH₂—].

Further, part of methylene group within the alkylene group for V′¹⁰¹ and V′¹⁰² may be substituted with a divalent aliphatic cyclic group of 5 to 10 carbon atoms. The aliphatic cyclic group is preferably a cyclohexylene group, a 1,5-adamantylene group or a 2,6-adamantylene group.

Y¹⁰¹ is preferably a divalent linking group containing an ether bond or a divalent linking group containing an ester bond, and groups represented by the aforementioned formulae (y-a1-1) to (y-a1-5) are preferable, and groups represented by the aforementioned formulae (y-a1-1) to (y-a1-3) are more preferable.

In formula (b-1), V¹⁰¹ represents a single bond, an alkylene group or a fluorinated alkylene group. The alkylene group and the fluorinated alkylene group for V¹⁰¹ preferably has 1 to 4 carbon atoms. Examples of the fluorinated alkylene group for V¹⁰¹ include a group in which part or all of the hydrogen atoms within the alkylene group for V¹⁰¹ have been substituted with fluorine. Among these examples, as V¹⁰¹, a single bond or a fluorinated alkylene group of 1 to 4 carbon atoms is preferable.

In formula (b-1), R¹⁰² represents a fluorine atom or a fluorinated alkyl group of 1 to 5 carbon atoms. R¹⁰² is preferably a fluorine atom or a perfluoroalkyl group of 1 to 5 carbon atoms, and more preferably a fluorine atom.

As a specific example of the anion moiety for the component (b-1), in the case where Y¹⁰¹ is a single bond, a fluorinated alkylsulfonate anion such as a trifluoromethanesulfonate anion or a perfluorobutanesulfonate anion can be mentioned; and in the case where Y¹⁰¹ represents a divalent linking group containing an oxygen atom, anions represented by formulae (an-1) to (an-3) shown below can be mentioned.

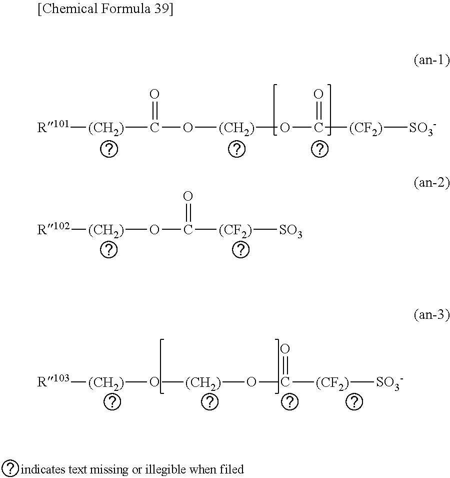

In the formulae, R″¹⁰¹ represents an aliphatic cyclic group which may have a substituent, a monovalent heterocyclic group represented by any of Formulae (r-hr-1) to (r-hr-6), or a chain-like alkyl group which may have a substituent; R″¹⁰² represents an aliphatic cyclic group which may have a substituent, a lactone-containing cyclic group represented by any of formulae (a2-r-1)′ to (a2-r-7)′, or a —SO₂— containing polycyclic group represented by any of formulae (a5-r-1)′ to (a5-r-2)′; R″¹⁰³ represents an aromatic cyclic group which may have a substituent, an aliphatic cyclic group which may have a substituent, or a chain-like alkenyl group which may have a substituent; each v″ independently represents an integer of 0 to 3; each q″ independently represents an integer of 1 to 20; t″ represents an integer of 1 to 3; and n″ represents 0 or 1.

As the aliphatic cyclic group for R″¹⁰¹, R″¹⁰² and R″¹⁰³ which may have a substituent, the same groups as the cyclic aliphatic hydrocarbon group for R¹⁰¹ described above are preferable. As the substituent, the same groups as those described above for substituting the cyclic aliphatic hydrocarbon group for R¹⁰¹ can be mentioned.

As the aromatic cyclic group for R″¹⁰³ which may have a substituent, the same groups as the aromatic hydrocarbon group for the cyclic hydrocarbon group represented by R¹⁰¹ described above are preferable. The substituent is the same as defined for the substituent for the aromatic hydrocarbon group represented by R′¹⁰¹.

As the chain-like alkyl group for R″¹⁰¹ which may have a substituent, the same groups as those described above for R¹⁰¹ are preferable. As the chain-like alkenyl group for R″¹⁰³ which may have a substituent, the same groups as those described above for R′¹⁰¹ are preferable.

Anion Moiety of Component (b-2)

In formula (b-2), R¹⁰⁴ and R¹⁰⁵ each independently represents a halogen atom, a cyclic group which may have a substituent, a chain-like alkyl group which may have a substituent or a chain-like alkenyl group which may have a substituent, and is the same as defined for R¹⁰¹ in formula (b-1). R′¹⁰⁴ and R¹⁰⁵ may be mutually bonded to form a ring.

As R¹⁰⁴ and R¹⁰⁵, a chain-like alkyl group which may have a substituent is preferable, and a linear or branched alkyl group or a linear or branched fluorinated alkyl group is more preferable.

The chain-like alkyl group preferably has 1 to 10 carbon atoms, more preferably 1 to 7 carbon atoms, and still more preferably 1 to 3 carbon atoms. The smaller the number of carbon atoms of the chain-like alkyl group for R¹⁰⁴ and R¹⁰⁵, the more the solubility in a photoresist solvent is improved. Further, in the chain-like alkyl group for R¹⁰⁴ and R¹⁰⁵, it is preferable that the number of hydrogen atoms substituted with fluorine atoms is as large as possible because the acid strength increases and the transparency to high energy radiation of 200 nm or less or electron beam is improved.

The fluorination ratio of the chain-like alkyl group is preferably from 70 to 100%, more preferably from 90 to 100%, and it is particularly desirable that the chain-like alkyl group be a perfluoroalkyl group in which all hydrogen atoms are substituted with fluorine atoms.

In formula (b-2), V¹⁰² and V¹⁰³ each independently represents a single bond, an alkylene group or a fluorinated alkylene group, and is the same as defined for V¹⁰¹ in formula (b-1).

In formula (b-2), L¹⁰¹ and L¹⁰² each independently represents a single bond or an oxygen atom.

Anion Moiety of Component (b-3)

In formula (b-3), R¹⁰⁶ to R¹⁰⁸ each independently represents a halogen atom, a cyclic group which may have a substituent, a chain-like alkyl group which may have a substituent or a chain-like alkenyl group which may have a substituent, and is the same as defined for R¹⁰¹ in formula (b-1).

L¹⁰³ to L¹⁰⁵ each independently represents a single bond, —CO— or —SO₂—.

{Cation Moiety}

In formulae (b-1), (b-2) and (b-3), m represents an integer of 1 or more, M′^{m+} represents an onium cation having a valency of m, preferably a sulfonium cation or an iodonium cation, and most preferably an organic cation represented by any one of the following formulae (ca-1) to (ca-4).

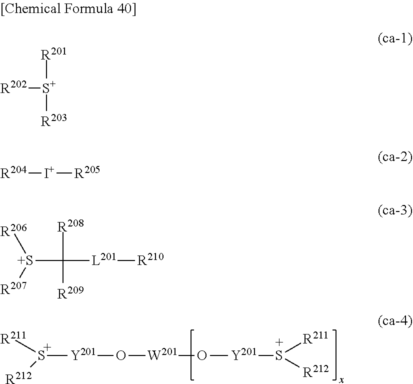

In the formulae, R²⁰¹ to R²⁰⁷, R²¹¹ and R²¹² each independently represents an aryl group, an alkyl group or an alkenyl group, provided that two of R²⁰¹ to R²⁰³, R²⁰⁶ and R²⁰⁷, or R²¹¹ and R²¹² may be mutually bonded to form a ring with the sulfur atom; R²⁰⁸ and R²⁰⁹ each independently represents a hydrogen atom or an alkyl group of 1 to 5 carbon atoms; R²¹⁰ represents an aryl group which may have a substituent, an alkyl group which may have a substituent, an alkenyl group which may have a substituent, or an —SO₂— containing cyclic group which may have a substituent; L²⁰¹ represents —C(═O)— or —C(═O)—O—; each Y²⁰¹ independently represents an arylene group, an alkylene group or an alkenylene group; x represents 1 or 2; and W²⁰¹ represents a linking group having a valency of (x+1).

As the aryl group for R²⁰¹ to R²⁰⁷ and R²¹¹ to R²¹², an unsubstituted aryl group of 6 to 20 carbon atoms can be mentioned, and a phenyl group or a naphthyl group is preferable.

The alkyl group for R²⁰¹ to R²⁰⁷, R²¹¹ and R²¹² is preferably a chain-like or cyclic alkyl group having 1 to 30 carbon atoms.

The alkenyl group for R²⁰¹ to R²⁰⁷ and R²¹¹ to R²¹² preferably has 2 to 10 carbon atoms.

Specific examples of the substituent which R²⁰¹ to R²⁰⁷ and R²¹⁰ to R²¹² may have include an alkyl group, a halogen atom, a halogenated alkyl group, a carbonyl group, a cyano group, an amino group, an aryl group, and groups represented by formulae (ca-r-1) to (ca-r-7) shown below.

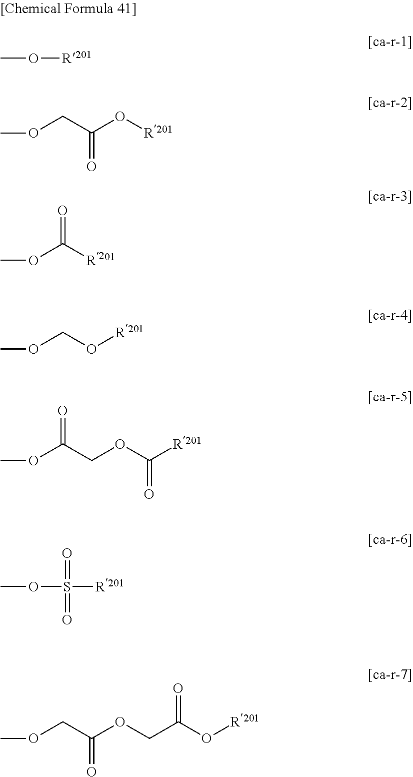

In the formulae, each R′²⁰¹ independently represents a hydrogen atom, a cyclic group which may have a substituent, a chain-like alkyl group which may have a substituent, or a chain-like alkenyl group which may have a substituent.

The cyclic group which may have a substituent, the chain-like alkyl group which may have a substituent, or the chain-like alkenyl group which may have a substituent represented by R′²⁰¹ is the same as defined for R¹⁰¹ in the aforementioned formula (b-1). In addition, as the cyclic group which may have a substituent, the chain-like alkyl group which may have a substituent represented by R′²⁰¹, the same groups as those described above for the acid dissociable group in the aforementioned structural unit (a1)′ may also be mentioned.

In the case where R²⁰¹ to R²⁰³, R²⁰⁶ and R²⁰⁷ or R²¹¹ and R²¹² are mutually bonded with the sulfur atom to form a ring, the groups may be bonded through a hetero atom such as a sulfur atom, an oxygen atom or a nitrogen atom, or a functional group such as a carbonyl group, —SO—, —SO₂—, —SO₃-, —COO—, —CONH— or —N(R_{N})—(R_{N} represents an alkyl group of 1 to 5 carbon atoms). The ring containing the sulfur atom in the skeleton thereof is preferably a 3 to 10-membered ring, and most preferably a 5 to 7-membered ring. Specific examples of the ring formed include a thiophene ring, a thiazole ring, a benzothiophene ring, a thianthrene ring, a benzothiophene ring, a dibenzothiophene ring, a 9H-thioxanthene ring, a thioxanthone ring, a phenoxathiin ring, a tetrahydrothiophenium ring, and a tetrahydrothiopyranium ring.

R²⁰⁸ and R²⁰⁹ each independently represents a hydrogen atom or an alkyl group of 1 to 5 carbon atoms, preferably a hydrogen atom or an alkyl group of 1 to 3 carbon atoms, and when R²⁰⁸ and R²⁰⁹ each represents an alkyl group, R²⁰⁸ and R²⁰⁹ may be mutually bonded to form a ring.

R²¹⁰ represents an aryl group which may have a substituent, an alkyl group which may have a substituent, an alkenyl group which may have a substituent, or an —SO₂— containing cyclic group which may have a substituent.

Examples of the aryl group for R²¹⁰ include an unsubstituted aryl group of 6 to 20 carbon atoms, and a phenyl group or a naphthyl group is preferable.

As the alkyl group for R²¹⁰, a chain-like or cyclic alkyl group having 1 to 30 carbon atoms is preferable.

The alkenyl group for R²¹⁰ preferably has 2 to 10 carbon atoms.

As the —SO₂— containing cyclic group for R²¹⁰ which may have a substituent, an “—SO₂— containing polycyclic group” is preferable, and a group represented by the aforementioned general formula (a5-r-1)′ is more preferable.

Each Y²⁰¹ independently represents an arylene group, an alkylene group or an alkenylene group.

Examples of the arylene group for Y²⁰¹ include groups in which one hydrogen atom has been removed from an aryl group given as an example of the aromatic hydrocarbon group for R¹⁰¹ in the aforementioned formula (b-1).

Examples of the alkylene group and alkenylene group for Y²⁰¹ include groups in which one hydrogen atom has been removed from the chain-like alkyl group or the chain-like alkenyl group given as an example of R¹⁰¹ in the aforementioned formula (b-1).

In the formula (ca-4), x represents 1 or 2.

W²⁰¹ represents a linking group having a valency of (x+1), i.e., a divalent or trivalent linking group.

As the divalent linking group for W²⁰¹, a divalent hydrocarbon group which may have a substituent is preferable, and as examples thereof, the same hydrocarbon groups (which may have a substituent) as those described above for Va¹ in the general formula (a1-1)′ may be mentioned. The divalent linking group for W²⁰¹ may be linear, branched or cyclic, and cyclic is more preferable. Among these, an arylene group having two carbonyl groups, each bonded to the terminal thereof is preferable. Examples of the arylene group include a phenylene group and a naphthylene group, and a phenylene group is particularly desirable.

As the trivalent linking group for W²⁰¹, a group in which one hydrogen atom has been removed from the aforementioned divalent linking group for W²⁰¹ and a group in which the divalent linking group has been bonded to another divalent linking group can be mentioned. The trivalent linking group for W²⁰¹ is preferably a group in which 2 carbonyl groups are bonded to an arylene group.

Specific examples of preferable cations represented by formula (ca-1) include cations represented by formulae (ca-1-1) to (ca-1-67) shown below.

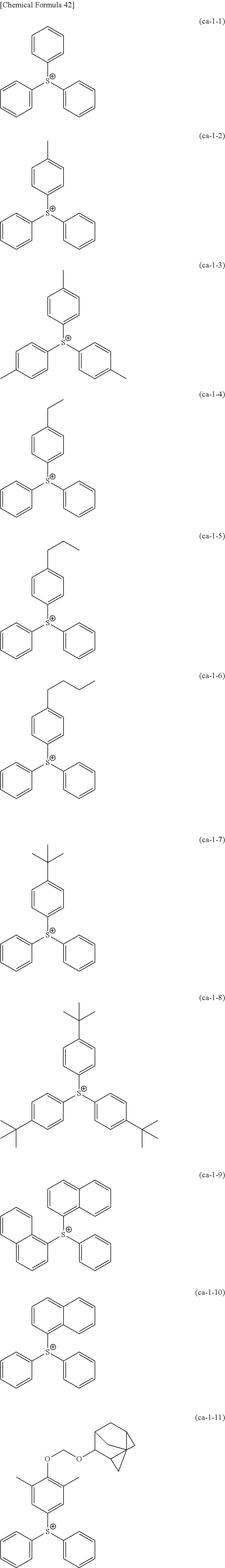

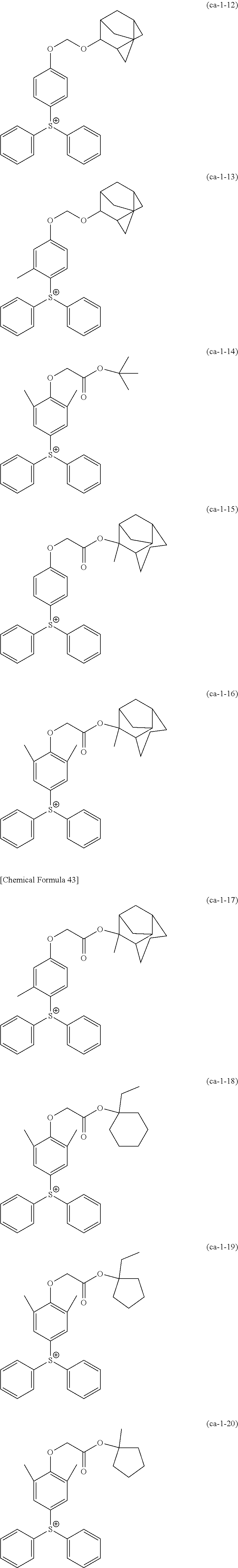

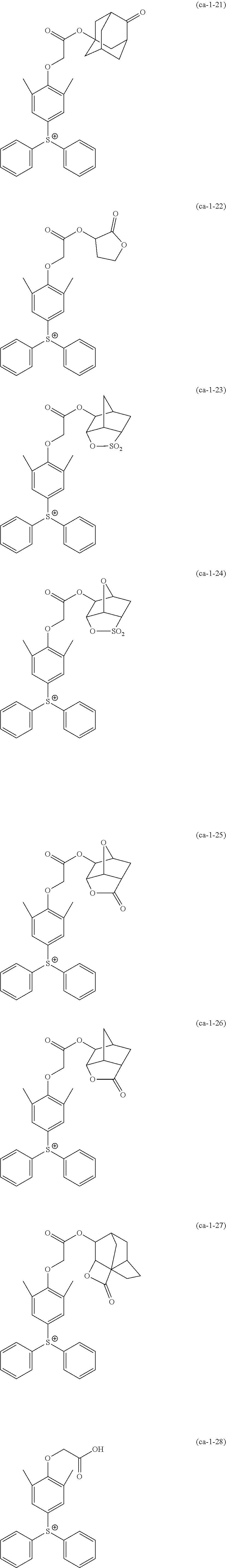

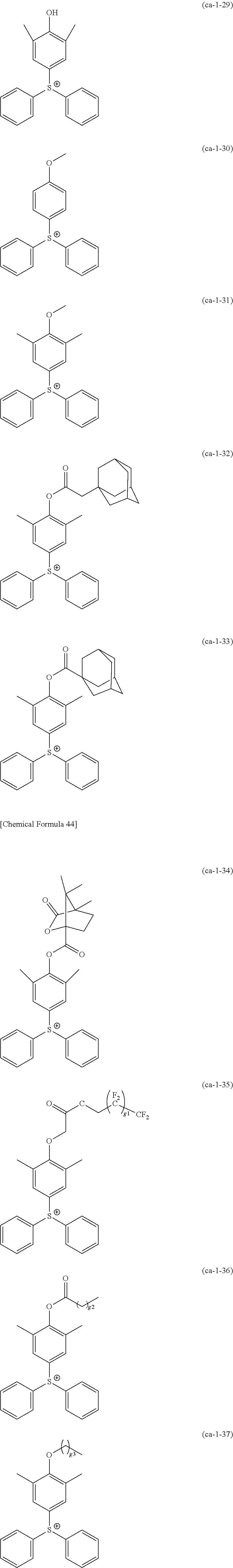

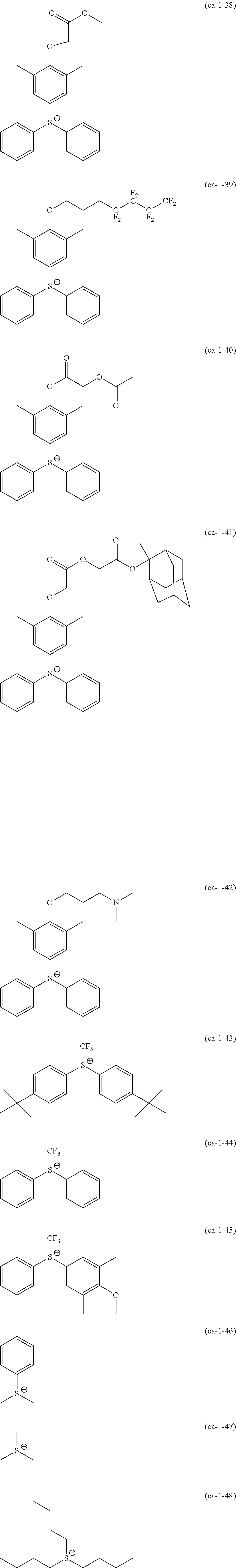

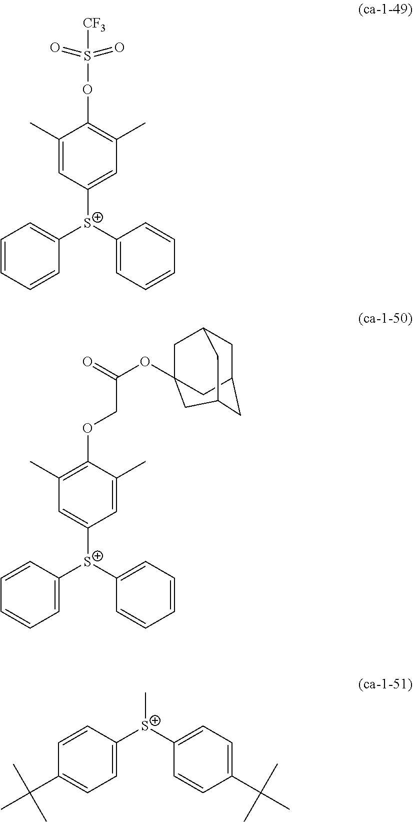

In the formulae, g1, g2 and g3 represent recurring numbers, wherein g1 is an integer of 1 to 5, g2 is an integer of 0 to 20, and g3 is an integer of 0 to 20.

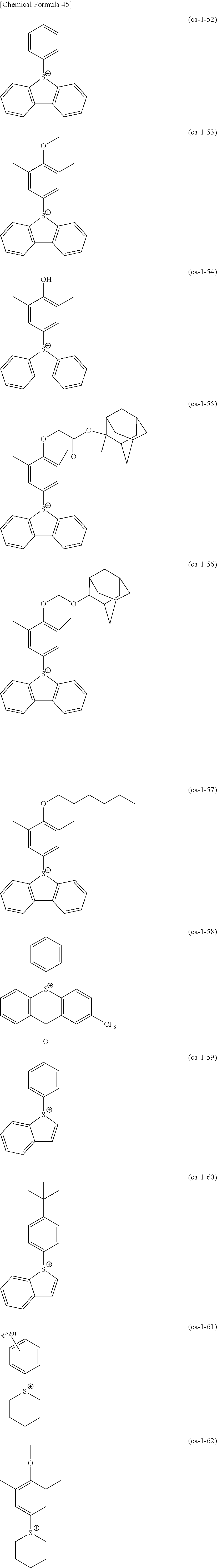

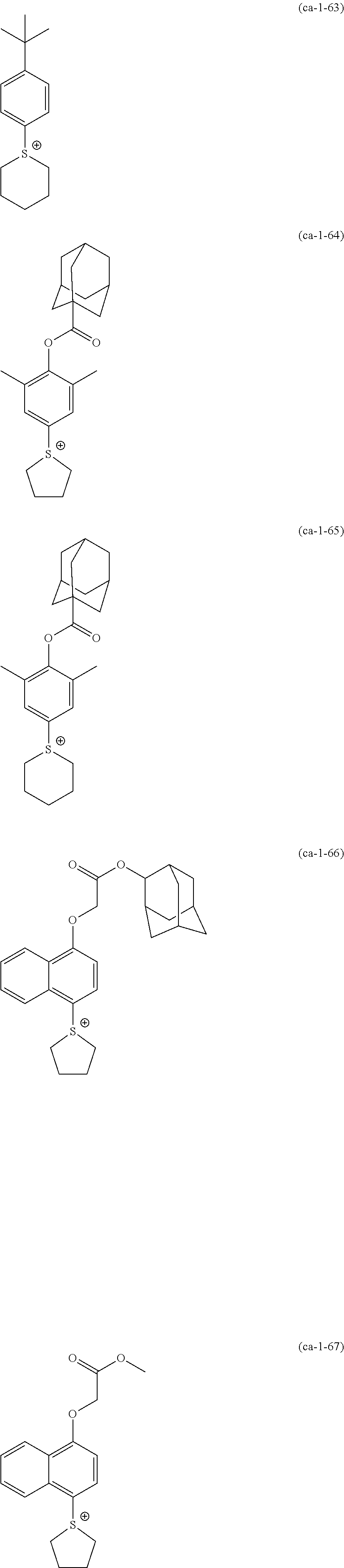

In the formulae, R″²⁰¹ represents a hydrogen atom or a substituent, and as the substituent, the same groups as those described above for substituting R²⁰¹ to R²⁰⁷ and R²¹⁰ to R²¹² may be mentioned.

Specific examples of preferable cations represented by the formula (ca-2) include a dihphenyliodonium cation and a bis(4-tert-butylphenyl)iodonium cation.

Specific examples of preferable cations represented by formula (ca-3) include cations represented by formulae (ca-3-1) to (ca-3-6) shown below.

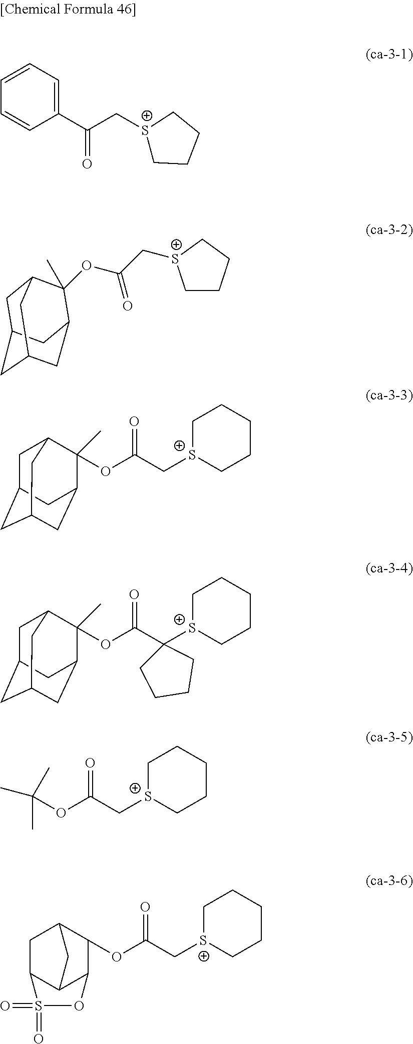 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

Specific examples of preferable cations represented by formula (ca-4) include cations represented by formulae (ca-4-1) and (ca-4-2) shown below.

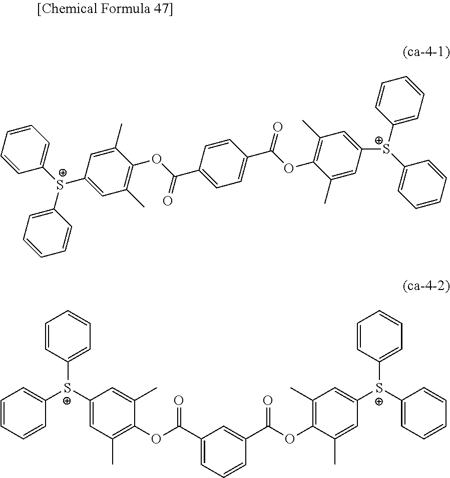 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

Among the above examples, as the cation moiety [(M′^{m+})_{1/m}], a cation represented by general formula (ca-1) is preferable, and a cation represented by any one of formulae (ca-1-1) to (ca-1-67) is more preferable.

As a preferable example of the component (B), a component (b-1) may be used. in particular, a component (b-1) in which, in the anion moiety, R¹⁰¹ is a halogen atom, each of V¹⁰¹ and L¹⁰¹ is a single bond, and R¹⁰² is a fluorine atom, and a cation represented by any of the aforementioned formulae (ca-1-1) to (ca-1-16) is combined may be used.

As the component (B), one kind of these acid generators may be used, or two or more kinds of acid generators may be used.

When the photoresist composition contains the component (B), the amount of the component (B) relative to 100 parts by weight of the component (S) described later is preferably 0.2 to 50 parts by weight, and more preferably 0.3 to 40 parts by weight.

When the amount of the component (B) is within the above-mentioned range, formation of a pattern may be conducted satisfactorily. Further, by virtue of the above-mentioned range, when the components of the photoresist composition are dissolved in an organic solvent, a homogeneous solution may be obtained and the storage stability becomes satisfactory.

<Additive (E)>

The photoresist composition of the present embodiment includes at least one additive (E) (hereafter, sometimes referred to as “component (E)”) in order to improve the properties of the photoresist composition. The component (E) is a component different from the components (A) and (B) described above, and is also a component different from the component described in the component (S) described later. In particular, the photoresist composition of the present embodiment contains a compound having one or more polar groups in order to satisfy good adhesion. When the photoresist composition contains a compound having one or more polar groups, the amount of solvent remaining in the photoresist layer during formation of the photoresist pattern is reduced, and the adhesion between the support and the photoresist pattern is improved.

In the compound having one or more polar groups, the polar group is preferably selected from a hydroxy group, an amino group, a mercapto group, a carboxy group and a sulfonic acid group, more preferably selected from a hydroxy group, an amino group and a carboxy group, and is most preferably a hydroxy group.

In terms of improving the adhesion to a support, the compound having one or more polar groups preferably has a molecular weight of 2,000 or less, more preferably a molecular weight of 1,500 or less, and still more preferably a molecular weight of 1,000 or less.

Further, in terms of improving the adhesion to a support, the compound having one or more polar groups is preferably a compound having one or more hydroxy groups. The compound having one or more hydroxy groups is preferably a compound represented by formula (1).

[Chemical Formula 48]

A(OH)ₚ (1)

In the formula, A represents a p-valent linear hydrocarbon group having 1 to 10 carbon atoms or a p-valent branched hydrocarbon group having 3 to 10 carbon atoms; and p represents an integer of 1 to 3.

In formula (1), the linear hydrocarbon group for A preferably has 2 to 8 carbon atoms, more preferably 4 to 6 carbon atoms.

In formula (1), the branched hydrocarbon group for A preferably has 4 to 8 carbon atoms, and more preferably 5 or 6 carbon atoms.

In formula (1), p is preferably 2 or 3, and more preferably 3.

As the compound represented by formula (1), in terms of improving the adhesion to a support, a compound represented by formula E1, E2 or E3 shown below is preferable.

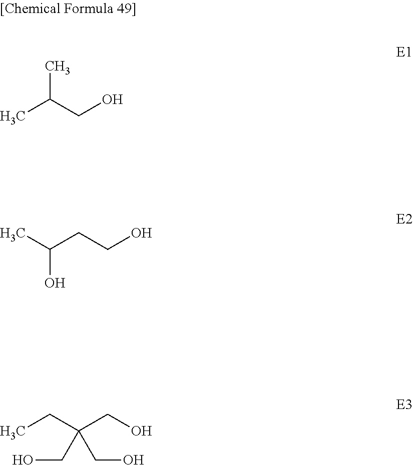

Alternatively, in the case where the compound having one or more polar groups is a compound having one or more amino groups, the compound having one or more amino groups is preferably a compound represented by formula (2) shown below.

[Chemical Formula 50]

B(NH₂)_{q} (2)

In the formula, B represents a q-valent linear hydrocarbon group having 1 to 10 carbon atoms or a q-valent branched hydrocarbon group having 3 to 10 carbon atoms; and q represents an integer of 1 to 3.

In formula (2), the linear hydrocarbon group for A preferably has 2 to 8 carbon atoms, more preferably 4 to 6 carbon atoms.

In formula (2), the branched hydrocarbon group for A preferably has 4 to 8 carbon atoms, and more preferably 5 or 6 carbon atoms.

In formula (2), q is preferably 2 or 3, and more preferably 3.

Further, in the case where the compound having one or more polar groups is a compound having one or more carboxy group, the compound having one or more carboxy group is preferably a compound represented by formula (3) shown below.

[Chemical Formula 51]

D(COOH)ᵣ (3)

In the formula, D represents a r-valent linear hydrocarbon group having 1 to 10 carbon atoms or a r-valent branched hydrocarbon group having 3 to 10 carbon atoms; and r represents an integer of 1 to 3.

In formula (3), the linear hydrocarbon group for D preferably has 2 to 8 carbon atoms, more preferably 4 to 6 carbon atoms.

In formula (3), the branched hydrocarbon group for D preferably has 4 to 8 carbon atoms, and more preferably 5 or 6 carbon atoms.

In formula (3), r is preferably 2 or 3, and more preferably 3.

As the component (E), one type may be used alone, or two or more types may be used in combination.

When the photoresist composition contains the component (E), the amount of the component (E) relative to 100 parts by weight of the component (S) is preferably 4 to 50 parts by weight, more preferably 5 to 30 parts by weight, and still more preferably 6 to 20 parts by weight. When the amount of the component (E) is within the above-mentioned range, the adhesion of the thick film photoresist later to a support is improved.

<Solvent (S)>

The photoresist composition of the present embodiment may be prepared by dissolving the materials for the photoresist composition in a solvent (hereafter, referred to as “component (S)”).

The component (S) may be any solvent which can dissolve the respective components to give a homogeneous solution, and any solvent can be appropriately selected from those which have been conventionally known as solvents for a photoresist composition.

Examples thereof include lactones such as y-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond such as ethylene glycol monoacetate, diethylene glycol monoacetate, propylene glycol monoacetate, or dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; dimethylsulfoxide (DMSO); and propylene carbonate.

As the component (S), 1 kind of solvent may be used, or 2 or more solvents may be used as a mixed solvent.

Among these examples, PGMEA, PGME, γ-butyrolactone, EL (ethyl lactate), cyclohexanone and propylene carbonate are preferable and PGMEA, PGME are more preferable.

The amount of the component (S) is not particularly limited, and is appropriately adjusted to a concentration which enables coating of a coating solution to a substrate. The component (S) is used in an amount such that the solid content of the photoresist composition becomes within the range from 30 to 70% by weight.

<Other Components>

The photoresist composition of the present embodiment may contain, in addition to the aforementioned components (A), (B), (E) and (S), a component (D) described below.

<Acid Diffusion Control Agent (D)>

The photoresist composition of the present embodiment may contain an acid diffusion control agent (D) (hereafter, referred to as “component (D)”). The component (D) is not particularly limited, and any compound may be appropriately selected and used from those conventionally known as acid diffusion control agents in photoresist compositions. The component (D) functions as an acid diffusion control agent, i.e., a quencher which traps the acid generated in the photoresist composition upon exposure.

The component (D) may be a photodecomposable base (D1) (hereafter, referred to as “component (D1)”) which is decomposed upon exposure and then loses the ability of controlling of acid diffusion, or a nitrogen-containing organic compound (D2) (hereafter, referred to as “component (D2)”) which does not fall under the definition of component (D1).

Component (D1)

When a photoresist pattern is formed using a photoresist composition containing the component (D1), the contrast between exposed portions and unexposed portions may be improved.

The component (D1) is not particularly limited, as long as it is decomposed upon exposure and then loses the ability of controlling of acid diffusion. As the component (D1), at least one compound selected from the group consisting of a compound represented by general formula (d1-1) shown below (hereafter, referred to as “component (d1-1)”), a compound represented by general formula (d1-2) shown below (hereafter, referred to as “component (d1-2)”) and a compound represented by general formula (d1-3) shown below (hereafter, referred to as “component (d1-3)”) is preferably used.

At exposed portions, the components (d1-1) to (d1-3) are decomposed and then lose the ability of controlling of acid diffusion (i.e., basicity), and therefore the components (d1-1) to (d1-3) cannot function as a quencher, whereas at unexposed portions, the components (d1-1) to (d1-3) functions as a quencher.

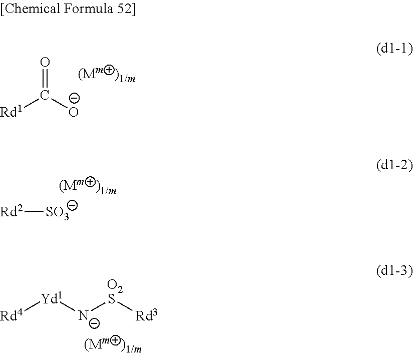

In the formulae, Rd¹ to Rd⁴ represent a cyclic group which may have a substituent, a chain-like alkyl group which may have a substituent or a chain-like alkenyl group which may have a substituent, provided that, the carbon atom adjacent to the sulfur atom within the Rd² in the formula (d1-2) has no fluorine atom bonded thereto; Yd′ represents a single bond or a divalent linking group; m represents an integer of 1 or more; and each M^{m+} independently represents an organic cation having a valency of m.

{Component (d1-1)}

Anion Moiety

In formula (d1-1), Rd¹ represents a cyclic group which may have a substituent, a chain-like alkyl group which may have a substituent or a chain-like alkenyl group which may have a substituent.

Among these, as the group for Rd¹, an aromatic hydrocarbon group which may have a substituent, an aliphatic cyclic group which may have a substituent and a chain-like alkyl group which may have a substituent are preferable. Examples of the substituent for these groups include a hydroxy group, an oxo group, an alkyl group, an aryl group, a fluorine atom, a fluorinated alkyl group, a lactone-containing cyclic group represented by any one of the aforementioned formulae (a2-r-1)′ to (a2-r-6)′, an ether bond, an ester bond, and a combination thereof. In the case where an ether bond or an ester bond is contained as a substituent, the substituent may be bonded through an alkylene group.

The aromatic hydrocarbon group is preferably a phenyl group or a naphthyl group.

Examples of the aliphatic cyclic group include groups in which one or more hydrogen atoms have been removed from a polycycloalkane such as adamantane, norbornane, isobornane, tricyclodecane or tetracyclododecane.

The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group.

In the case where the chain-like alkyl group is a fluorinated alkyl group having a fluorine atom or a fluorinated alkyl group, the fluorinated alkyl group preferably has 1 to 11 carbon atoms, more preferably 1 to 8 carbon atoms, and still more preferably 1 to 4 carbon atoms. The fluorinated alkyl group may contain an atom other than fluorine. Examples of the atom other than fluorine include an oxygen atom, a sulfur atom and a nitrogen atom.

As Rd¹, a fluorinated alkyl group in which part or all of the hydrogen atoms constituting a linear alkyl group have been substituted with fluorine atom(s) is preferable, and a fluorinated alkyl group in which all of the hydrogen atoms constituting a linear alkyl group have been substituted with fluorine atoms (i.e., a linear perfluoroalkyl group) is particularly desirable.

Specific examples of preferable anion moieties for the component (d1-1) are shown below.

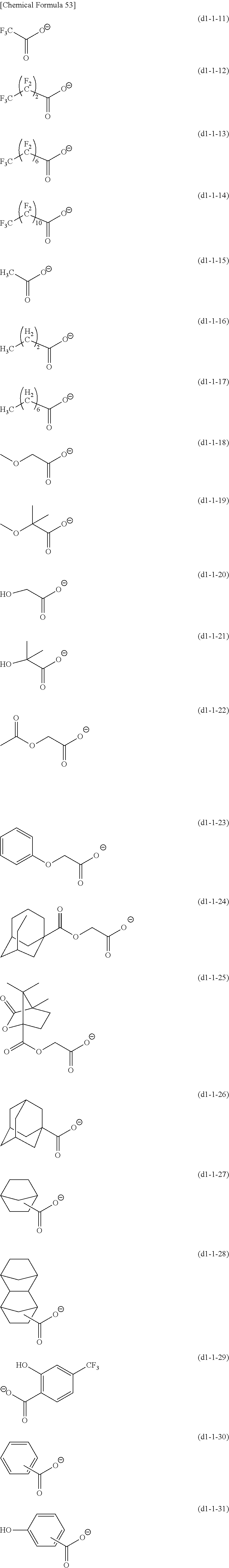

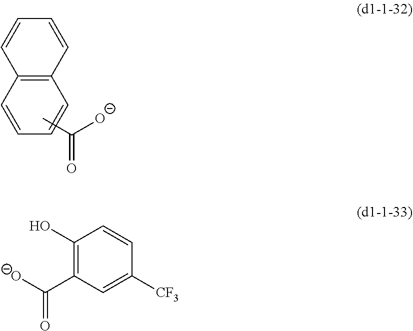

Cation Moiety

In formula (d1-1), M^{m+} represents an organic cation having a valency of m.

As the organic cation for M^{m+}, for example, the same cation moieties as those represented by the aforementioned formulae (ca-1) to (ca-4) are preferable, cation moieties represented by the aforementioned general formulae (ca-1) is preferable, and cation moieties represented by the aforementioned formulae (ca-1-1) to (ca-1-67) are still more preferable.

As the component (d1-1), one kind of compound may be used, or two or more kinds of compounds may be used in combination.

{Component (d1-2)}

Anion Moiety

In formula (d1-2), Rd² represents a cyclic group which may have a substituent, a chain-like alkyl group which may have a substituent or a chain-like alkenyl group which may have a substituent.

However, the carbon atom adjacent to the sulfur atom within Rd² group has no fluorine atom bonded thereto (i.e., the carbon atom adjacent to the sulfur atom within Rd2 group does not substituted with a fluorine atom). As a result, the anion of the component (d1-2) becomes an appropriately weak acid anion, thereby improving the quenching ability of the component (D).

As Rd², a chain-like alkyl group which may have a substituent or an aliphatic cyclic group which may have a substituent is preferable. The chain-like alkyl group preferably has 1 to 10 carbon atoms, and more preferably 3 to 10 carbon atoms. As the aliphatic cyclic group, a group in which one or more hydrogen atoms have been removed from adamantane, norbornane, isobornane, tricyclodecane, tetracyclododecane or camphor (which may have a substituent) is more preferable.

The hydrocarbon group for Rd² may have a substituent. As the substituent, the same groups as those described above for substituting the hydrocarbon group (e.g., aromatic hydrocarbon group, aliphatic cyclic group, chain-like alkyl group) for Rd¹ in the formula (d1-1) may be mentioned.

Specific examples of preferable anion moieties for the component (d1-2) are shown below.

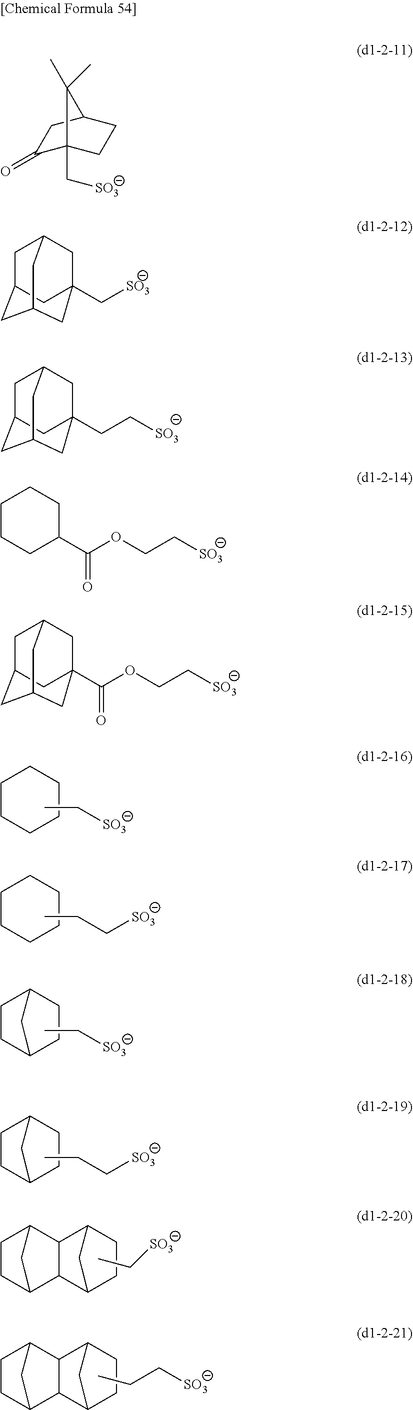

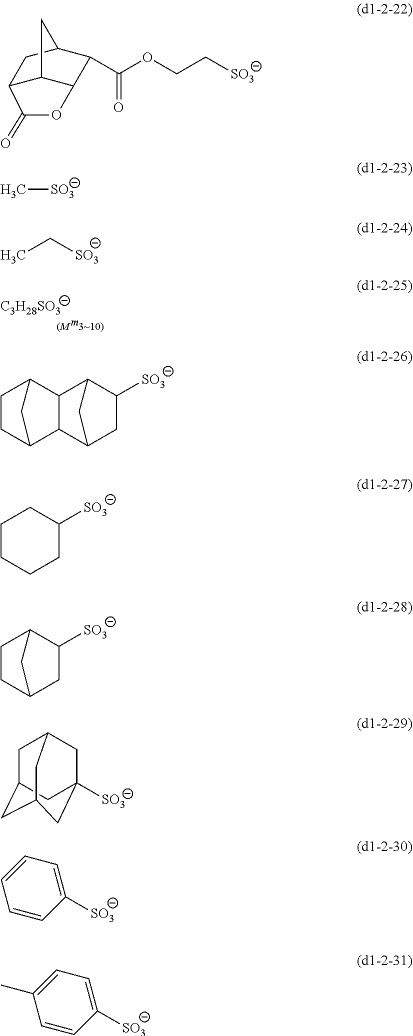

Cation Moiety

In formula (d1-2), M′ is an organic cation having a valency of m, and is the same as defined for M′ in the aforementioned formula (d1-1).

As the component (d1-2), one type of compound may be used, or two or more types of compounds may be used in combination.

{Component (d1-3)}

Anion Moiety

In formula (d1-3), Rd³ represents a cyclic group which may have a substituent, a chain-like alkyl group which may have a substituent or a chain-like alkenyl group which may have a substituent, and is preferably a cyclic group containing a fluorine atom, a chain-like alkyl group, or a chain-like alkenyl group. Among these examples, a fluorinated alkyl group is preferably, and the same fluorinated alkyl groups as those described above for Rd¹ are more preferable.

In formula (d1-3), Rd⁴ represents a cyclic group which may have a substituent, a chain-like alkyl group which may have a substituent or a chain-like alkenyl group which may have a substituent.

Among these, an alkyl group which may have substituent, an alkoxy group which may have substituent, an alkenyl group which may have substituent or a cyclic group which may have substituent is preferable.

The alkyl group for Rd⁴ is preferably a linear or branched alkyl group of 1 to 5 carbon atoms, and specific examples include a methyl group, an ethyl group, an n-propyl group, an isopropyl group, an n-butyl group, an isobutyl group, a tert-butyl group, a pentyl group, an isopentyl group, and a neopentyl group. Part of the hydrogen atoms within the alkyl group for Rd⁴ may be substituted with a hydroxy group, a cyano group or the like.

The alkoxy group for Rd⁴ is preferably an alkoxy group of 1 to 5 carbon atoms, and specific examples thereof include a methoxy group, an ethoxy group, an n-propoxy group, an iso-propoxy group, an n-butoxy group and a tert-butoxy group. Among these, a methoxy group and an ethoxy group are preferable.

As the alkenyl group for Rd⁴, a vinyl group, a propenyl group (an allyl group), a 1-methylpropenyl group and a 2-methylpropenyl group are preferable. These groups may have an alkyl group of 1 to 5 carbon atoms or a halogenated alkyl group of 1 to 5 carbon atoms as a substituent.

As the cyclic group for Rd⁴, an alicyclic group (e.g., a group in which one or more hydrogen atoms have been removed from a cycloalkane such as cyclopentane, cyclohexane, adamantane, norbornane, isobornane, tricyclodecane or tetracyclododecane) or an aromatic group (e.g., a phenyl group or a naphthyl group) is preferable. When Rd⁴ is an alicyclic group, the photoresist composition may be satisfactorily dissolved in an solvent, thereby improving the lithography properties. Alternatively, when Rd⁴ is an aromatic group, the resist composition exhibits an excellent photoabsorption efficiency in a lithography process using EUV or the like as the exposure source, thereby resulting in the improvement of the sensitivity and the lithography properties.

In formula (d1-3), Yd¹ represents a single bond or a divalent linking group. The divalent linking group for Yd¹ is not particularly limited, and examples thereof include a divalent hydrocarbon group (aliphatic hydrocarbon group, or aromatic hydrocarbon group) which may have a substituent and a divalent linking group containing a hetero atom.

As Yd¹, a carbonyl group, an ester bond, an amide bond, an alkylene group or a combination of these is preferable. As the alkylene group, a linear or branched alkylene group is more preferable, and a methylene group or an ethylene group is still more preferable.

Specific examples of preferable anion moieties for the component (d1-3) are shown below.

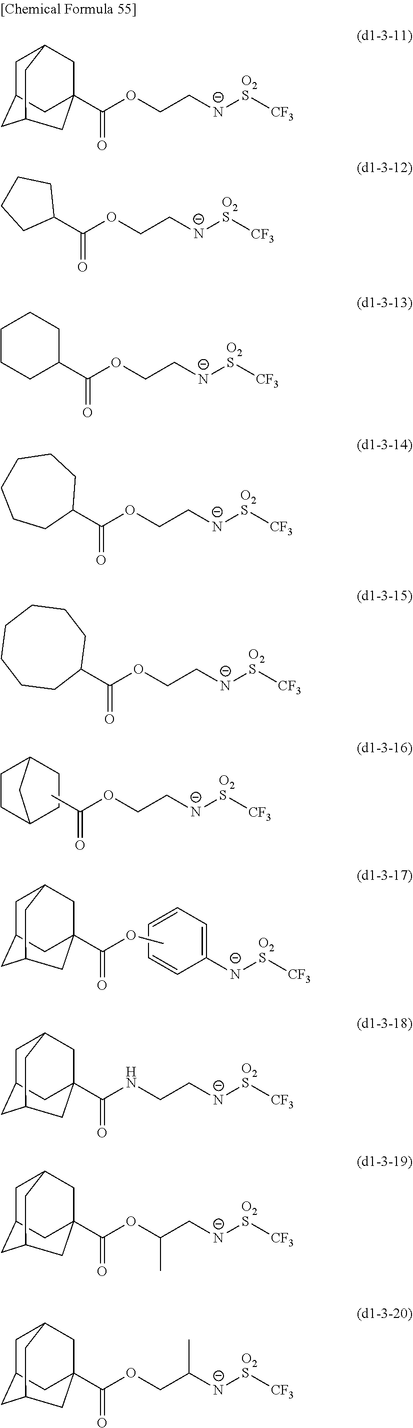

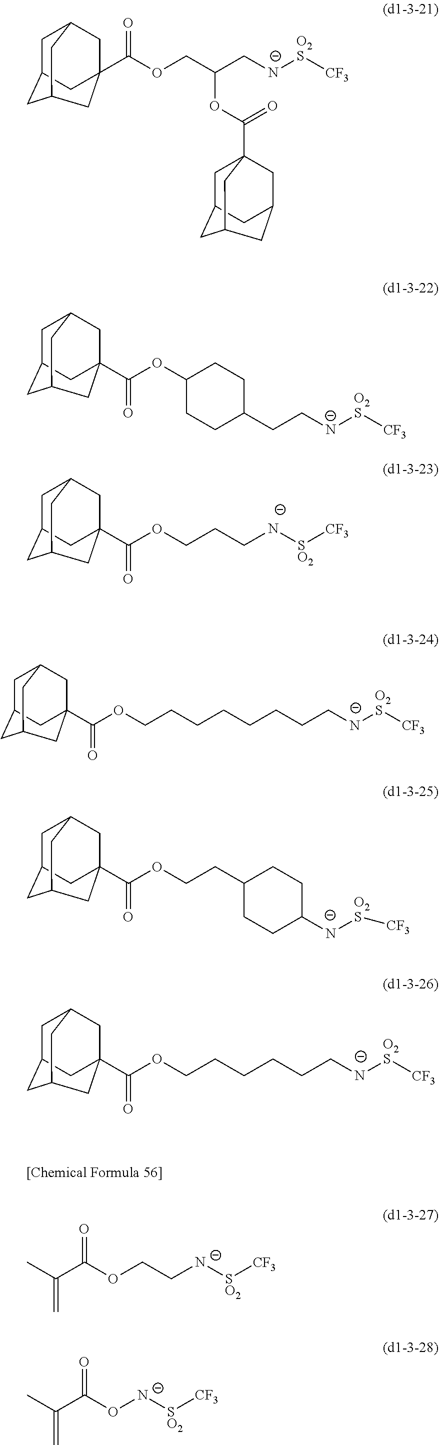

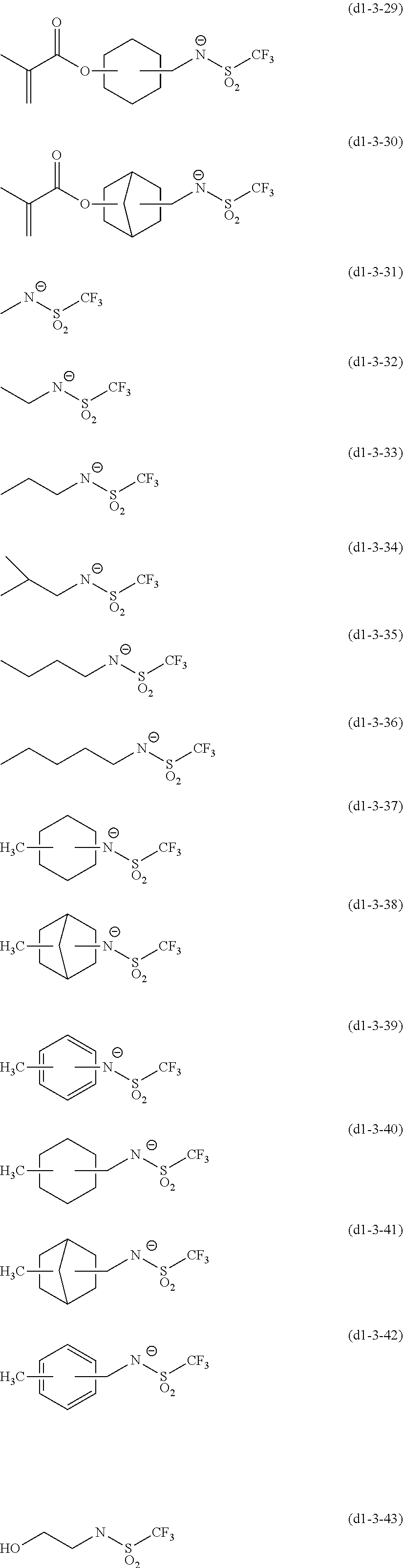

Cation Moiety

In formula (d1-3), M′ is an organic cation having a valency of m, and is the same as defined for M′ in the aforementioned formula (d1-1).

As the component (d1-3), one type of compound may be used, or two or more types of compounds may be used in combination.

As the component (D1), one type of the aforementioned components (d1-1) to (d1-3), or at least two types of the aforementioned components (d1-1) to (d1-3) can be used in combination.

Among these examples, as the component (D1), it is preferable to use at least the component (d1-1).

When the photoresist composition contains the component (D), the amount of the component (D) relative to 100 parts by weight of the component (S) is preferably 0.3 to 5 parts by weight, more preferably 0.5 to 4 parts by weight, and still more preferably 0.7 to 3 parts by weight.

When the amount of the component (D1) is at least as large as the lower limit of the above-mentioned range, good lithographic properties and good photoresist pattern shape may be more reliably obtained. On the other hand, when the amount of the component (D1) is no more than the upper limit of the above-mentioned range, sensitivity can be maintained at a satisfactory level, and through-put becomes excellent.

Production Method of Component (D1):

The production methods of the components (d1-1) and (d1-2) are not particularly limited, and the components (d1-1) and (d1-2) can be produced by conventional methods.

Further, the production method of the component (d1-3) is not particularly limited, and the component (d1-3) may be produced in the same manner as disclosed in US2012/0149916.

Component (D2)

The acid diffusion control component may contain a nitrogen-containing organic compound (D2) (hereafter, referred to as component (D2)) which does not fall under the definition of component (D1).

The component (D2) is not particularly limited, as long as it functions as an acid diffusion control agent, and does not fall under the definition of the component (D1). As the component (D2), any of the conventionally known compounds may be selected for use. Among these, an aliphatic amine or an aromatic amine is preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group having no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine Among these, trialkylamines of 5 to 10 carbon atoms are preferable, and tri-n-pentylamine and tri-n-octylamine are particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo [4.3.0]-5-nonene, 1,8-diazabicyclo [5.4.0]-7-undecene, hexamethylenetetramine, and 1,4-diazabicyclo [2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris [2-[2-(2-hydroxyethoxy)ethoxy]ethyl]amine and triethanolamine triacetate, and triethanolamine triacetate is preferable.

Further, as the component (D2), an aromatic amine may be used.

Examples of aromatic amines include 4-dimethylaminopyridine, pyrrole, indole, pyrazole, imidazole and derivatives thereof, tribenzylamine, 2,6-diisopropylaniline, N-tert-butoxycarbonylpyrrolidine and 2,4-diamino-6-phenyl-1,3,5-triazine. Among these examples, N-tert-butoxycarbonylpyrrolidine and 2,4-diamino-6-phenyl-1,3,5-triazine is preferable, and 2,4-diamino-6-phenyl-1,3,5-triazine is more preferable.

As the component (D2), one kind of compound may be used, or two or more kinds of compounds may be used in combination.

When the photoresist composition contains the component (D2), the component (D2) may be used in an amount of 0.005 to 3 parts by weight, relative to 100 parts by weight of the component (S). When the amount of the component (D2) is within the above-mentioned range, the shape of the photoresist pattern and the post exposure stability of the latent image formed by the pattern-wise exposure of the photoresist layer may be improved.

<Preparation of Photoresist Composition>

The preparation of the photoresist composition according to the present embodiment may be carried out by mixing and stirring the above-mentioned components in a usual manner, and, if necessary, dispersing and mixing using a disperser such as a dissolver, a homogenizer, or a three-roll mill. Furthermore, following mixing, the composition may also be filtered using a mesh, or a membrane filter or the like.

<<Method of Forming Thick Film Photoresist Pattern>>

A second aspect of the present invention is a method of forming a thick film photoresist pattern, including: using a thick film photoresist composition of the first aspect to form a thick film photoresist layer on a substrate; exposing the thick film photoresist layer; and developing the thick film photoresist layer to form a thick film photoresist pattern.

More specifically, the method of forming a thick film photoresist pattern includes a step of forming a thick film photoresist layer on a substrate using a photoresist composition which generates acid upon exposure and exhibits changed solubility in a developing solution by the action of acid; a step of exposing the thick film photoresist layer; and a step of patterning the exposed thick film photoresist film by development using a developing solution to form a thick film photoresist pattern.

The thickness of the photoresist film in the thick film photoresist layer is preferably 5 to 180 μm, and more preferably 10 to 150 μm.

The method for forming a thick film photoresist pattern according to the present embodiment may be performed, for example, as follows.

Firstly, a photoresist composition which generates acid upon exposure and exhibits changed solubility in a developing solution by the action of acid is applied to a substrate using a spinner or the like, and a bake treatment (post applied bake (PAB)) is conducted, for example, at a temperature of 80 to 150° C. for 40 to 120 seconds, preferably 60 to 90 seconds, to form a thick film photoresist layer.

As the photoresist composition, the photoresist composition according to the aforementioned aspect is used.

Then, the thick film photoresist layer is subjected to exposure through a mask having a predetermined pattern formed thereon (mask pattern) using an exposure apparatus such as an ArF exposure apparatus, a KrF exposure apparatus, an electron beam lithography apparatus or an EUV exposure apparatus, or patterning via direct irradiation with an electron beam without using a mask pattern.

Then, baking treatment (post exposure baking (PEB)) is conducted under temperature conditions of 80 to 150° C. for 40 to 120 seconds, and preferably 60 to 90 seconds.

Subsequently, the photoresist film which has been subjected to exposure and baking (PEB) is developed. The developing treatment is conducted using an alkali developing solution in the case of an alkali developing process, and a developing solution containing an organic solvent (organic developing solution) in the case of a solvent developing process.

After the developing treatment, it is preferable to conduct a rinse treatment. The rinse treatment is preferably conducted using pure water in the case of an alkali developing process, and a rinse solution containing an organic solvent in the case of a solvent developing process.

In the case of a solvent developing process, after the developing treatment or the rinsing, the developing solution or the rinse liquid remaining on the pattern can be removed by a treatment using a supercritical fluid.

After the developing treatment or the rinse treatment, drying is conducted. If desired, bake treatment (post bake) can be conducted following the developing. In this manner, a thick film photoresist pattern can be obtained.

In the present embodiment, the substrate is not specifically limited and a conventionally known substrate may be used. For example, substrates for electronic components, and such substrates having wiring patterns formed thereon may be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer photoresist method may be used.

The wavelength to be used for exposure is not particularly limited and the exposure can be conducted using radiation such as ArF excimer laser, KrF excimer laser, F₂ excimer laser, extreme ultraviolet rays (EUV), vacuum ultraviolet rays (VUV), electron beam (EB), X-rays, and soft X-rays. The photoresist composition of the present embodiment is effective to KrF excimer laser, ArF excimer laser, EB and EUV, and in particular to KrF excimer laser.

The exposure of the photoresist film can be either a general exposure (dry exposure) conducted in air or an inert gas such as nitrogen, or immersion exposure (immersion lithography).

In immersion lithography, the region between the photoresist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the photoresist film to be exposed. The refractive index of the immersion medium is not particularly limited as long as it satisfies the above-mentioned requirements.

Examples of this immersion medium which exhibits a refractive index that is larger than the refractive index of air but smaller than the refractive index of the photoresist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

In an alkali developing process, as the alkali developing solution used in the developing treatment, any conventional alkali developing may be appropriately selected which is capable of dissolving the aforementioned component (A) (component (A) prior to exposure). As an example of the alkali developing solution used in an alkali developing process, a 0.1 to 10% by weight aqueous solution of tetramethylammonium hydroxide (TMAH) may be given.

As the organic solvent contained in the organic developing solution used in a solvent developing process, any of the conventional organic solvents may be used which are capable of dissolving the component (A) (prior to exposure). Specific examples of the organic solvent include polar solvents such as ketone solvents, ester solvents, alcohol solvents, amide solvents and ether solvents, and hydrocarbon solvents.

If desired, the organic developing solution may have a conventional additive blended. Examples of the additive include surfactants. The surfactant is not particularly limited, and for example, an ionic or non-ionic fluorine and/or silicon surfactant may be used.

When a surfactant is added, the amount thereof based on the total amount of the organic developing solution is generally 0.001 to 5% by weight, preferably 0.005 to 2% by weight, and more preferably 0.01 to 0.5% by weight.

The developing treatment may be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

The rinse treatment using a rinse liquid (washing treatment) may be conducted by a conventional rinse method. Examples of the rinse method include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

### EXAMPLES

As follows is a description of examples of the present invention, although the scope of the present invention is by no way limited by these examples.

<Preparation of Photoresist Composition>

The components shown in the table shown below were mixed together and dissolved to obtain photoresist composition of each example.

TABLE 1

| | | Acid | Acid diffusion | | |
|---|---|---|---|---|---|
| | Resin | generator | control agent | Additive | Solvent |
| | (A) | (B) | (D) | (E) | (S) |
| Comparative | A1 | B1 | D1 | — | S1/S2(7/3) |
| Example 1 | [66.18] | [0.46] | [0.01] | | [100] |
| Comparative | A1 | B1 | D1 | E3 | S1/S2(7/3) |
| Example 2 | [63.05] | [0.44] | [0.01] | [3.15] | [100] |
| Example 1 | A1 | B1 | D1 | E3 | S1/S2(7/3) |
| | [60.20] | [0.42] | [0.01] | [6.02] | [100] |
| Example 2 | A1 | B1 | D1 | E3 | S1/S2(7/3) |
| | [57.60] | [0.40] | [0.01] | [8.64] | [100] |
| Example 3 | A1 | B1 | D1 | E3 | S1/S2(7/3) |
| | [55.22] | [0.39] | [0.01] | [11.05] | [100] |
| Example 4 | A1 | B1 | D1 | E3 | S1/S2(7/3) |
| | [53.02] | [0.37] | [0.01] | [13.26] | [100] |
| Example 5 | A1 | B1 | D1 | E3 | S1/S2(7/3) |
| | [50.99] | [0.36] | [0.01] | [15.30] | [100] |

In the table, the values in brackets [ ] indicate the amount (in terms of parts by weight) of the component added, relative to 100 parts by weight of the component (S).

Component (A): a resin represented by A1 shown below (the weight ratio of structural units: x/y/z=68/17/15; weight average molecular weight: 18,000)

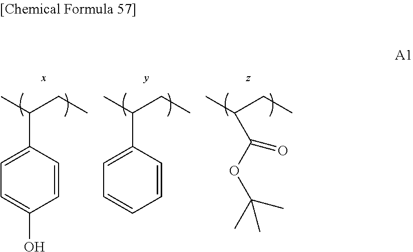

Component (B): an acid generator represented by B1 shown below

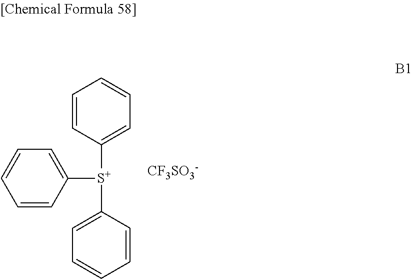

Component (D): an acid diffusion control agent represented by D1 shown below

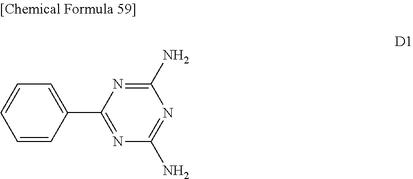 [SMILES: Nc1nc(N)nc(-c2ccccc2)n1]

Component (E): an additive represented by E3 shown below

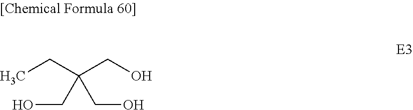

Component (S): a mixture of compounds represented by S1 and S2 shown below (weight ratio: S1/S2=7/3)

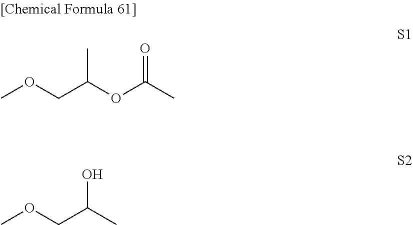

<Formation of Thick Film Photoresist Pattern>

On a 12-inch silicon wafer which had been subjected to hexadisilazane treatment at 180° C. for 70 seconds, an SiO₂ layer having a thickness of 135 nm was formed using spinner CLEAN TRACK ACT12 (manufactured by Tokyo Electron) to produce a support.

Then, the composition shown in Table 1 was applied to the support using a spinner, and was then subjected to post-applied bake (PAB) on a hot plate at a temperature of 150° C. for 70 seconds and dried, thereby forming a thick film photoresist layer having a film thickness of 14 μm.

Subsequently, the resist film was selectively exposed through a binary mask, using an immersion lithography KrF exposure apparatus (wavelength: 248 nm) NSR-S210D (manufactured by Nikon; NA (numerical aperture)=0.68, σ=0.83). Thereafter, a post-exposure bake (PEB) treatment was conducted at 120° C. for 50 seconds. Then, a solvent development was conducted at 23° C. for 30 seconds using butyl acetate, followed by a rinse treatment.

Further, alkali development was performed, once for 35 seconds and then for 10 seconds, with a 2.38 mass % tetramethylammonium hydroxide (TMAH) aqueous solution (NMD-3) at 23° C., and water rinse was performed for 15 seconds using pure water. In this matter, a thick film photoresist pattern was formed. The formed thick film photoresist pattern was subjected to a hard bake treatment at 110° C. for 60 seconds. The thick film photoresist pattern after the hard bake treatment was measured using CD-SEM (a scanning electron microscope manufactured by Hitachi; product name: CG-4000), after vacuum process for 600 seconds.

<Evaluation of Adhesion of Thick Film Photoresist Pattern>

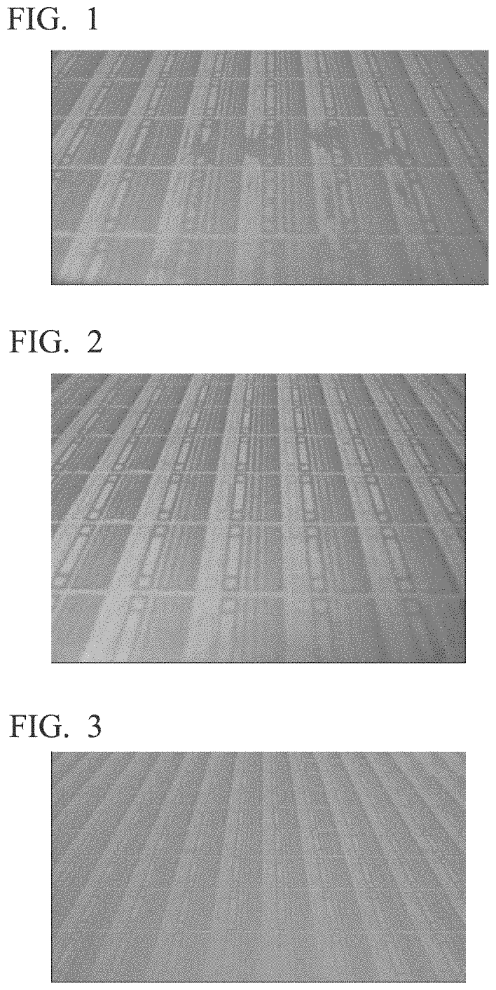

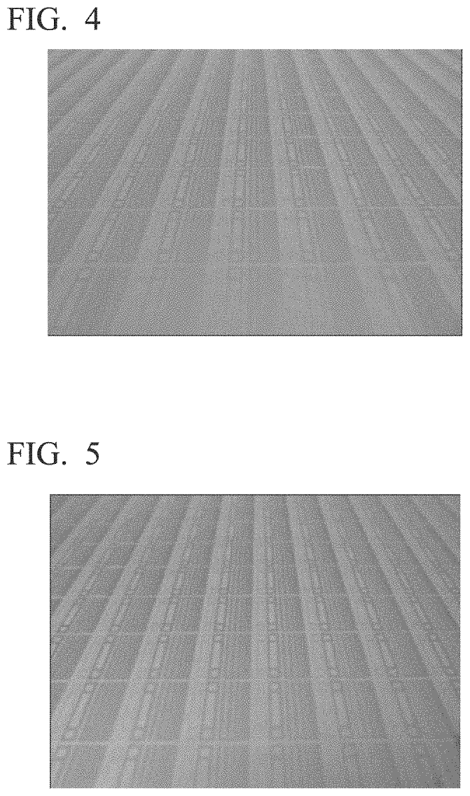

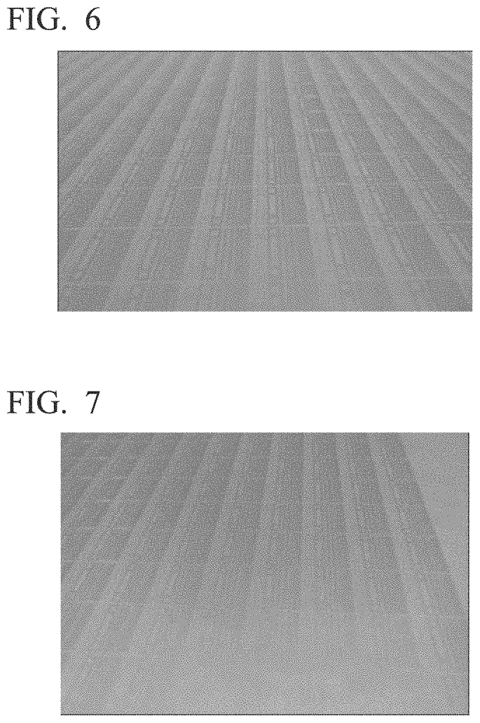

Using the photoresist compositions of Examples 1 to 5 and Comparative Examples 1 and 2, a tape Scotch 610-1PK (manufactured by 3M) was attached onto a thick film photoresist pattern formed on a support. After 10 seconds, the adhered tape was peeled off, and it was evaluated whether or not the thick film photoresist pattern was removed (FIGS. 1 to 7). The results are shown in Table 2. The less the thick film photoresist pattern was removed, the better the adhesion. The evaluation was conducted in accordance with the following criteria.

A: Resist pattern was not removed.

B: Resist pattern was slightly removed.

C: Resist pattern was removed.

TABLE 2

| | Degree of |
|---|---|
| | adhesion |
| Comparative | C |
| Example 1 | |
| Comparative | B |
| Example 2 | |
| Example 1 | A |
| Example 2 | A |
| Example 3 | A |
| Example 4 | A |
| Example 5 | A |

As shown in the above results, the thick film photoresist pattern formed using the photoresist composition of the present invention containing the additive of the present invention exhibited an effect of good adhesion.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A thick film photoresist composition for forming a thick film photoresist layer on a support, the photoresist composition comprising:
a resin (A) which exhibits changed solubility in a developing solution by the action of acid,
an acid generator (B) which generates acid by exposure,
an additive (E), and
a solvent (S),
wherein the additive (E) includes a compound having at least one polar group selected from the group consisting of a hydroxy group, an amino group, a mercapto group, a carboxy group and a sulfonic acid group, and
the amount of the additive (E), relative to 100 parts by weight of the solvent (S) is 5 to 30 parts by weight.

2. The photoresist composition according to claim 1, wherein the composition forms a thick film photoresist layer having a film thickness of 10 to 150 μm.

3. The photoresist composition according to claim 1, wherein the compound having at least one polar group is a compound having at least one hydroxy group.

4. The photoresist composition according to claim 3, wherein the compound having at least one hydroxy group is represented by the following formula (1):
A(OH)ₚ (1)
wherein A represents a p-valent linear hydrocarbon group having 1 to 10 carbon atoms or a p-valent branched hydrocarbon group having 3 to 10 carbon atoms; and p represents an integer of 1 to 3.

5. The photoresist composition according to claim 4, wherein, in formula (1), p is 3.

6. The photoresist composition according to claim 1, further comprising an acid diffusion control agent (D).

7. A method of forming a thick film photoresist pattern, comprising:
using the photoresist composition of claim 1 to form a thick film photoresist layer on a substrate;
exposing the thick film photoresist layer; and
developing the thick film photoresist layer to form a thick film photoresist pattern.
